(19) United States
(12) Patent Application Publication
(10) Pub. No.: US 2025/0210532 A1
(43) Pub. Date: Jun. 26, 2025

(54) SEMICONDUCTOR DEVICE

(71) Applicant: Rohm Co., Ltd., Kyoto-shi (JP)

(72) Inventors: Oji SATO, Kyoto-shi (JP); Daiki IKEDA, Kyoto-shi (JP); Kohei TANIKAWA, Kyoto-shi (JP)

(21) Appl. No.: 19/074,964

(22) Filed: Mar. 10, 2025

Related U.S. Application Data
(63) Continuation of application No. PCT/JP2023/030456, filed on Aug. 24, 2023.

(30) Foreign Application Priority Data
Sep. 13, 2022 (JP) 2022-145138
Feb. 2, 2023 (JP) 2023-014398

(51) Int. Cl. H01L 23/538; H01L 23/00; H01L 23/498; H01L 25/07

(52) U.S. Cl. CPC H01L 23/5385; H01L 23/49811; H01L 23/49894; H01L 23/5386; H01L 25/072; H01L 24/32; H01L 24/40; H01L 2224/32227; H01L 2224/40229; H01L 2924/13091; H01L 2924/35121

(57) ABSTRACT

A semiconductor device includes: a main substrate including a first main metal layer; a first semiconductor element supported by the main substrate; a first sub-substrate supported by the main substrate; and a sealing resin covering the first semiconductor element. The first sub-substrate includes a sub-insulating layer, and a first sub-metal layer and a second sub-metal layer that flank the sub-insulating layer in a thickness direction. The second sub-metal layer is electrically bonded to the first main metal layer, and the first sub-metal layer includes a region. The first sub-substrate further includes a connecting conductive portion that electrically connects the region and the second sub-metal layer.

### TECHNICAL FIELD

The present disclosure relates to a semiconductor device.

### BACKGROUND ART

Semiconductor devices incorporating power switching elements, such as metal oxide semiconductor field effect transistors (MOSFETs) and insulated gate bipolar transistors (IGBTs), have been conventionally known. Such semiconductor devices are mounted in various electronic devices, ranging from industrial devices to home appliances and information terminals, or even to vehicle-mount devices. JP-A-2021-190505 discloses a conventional semiconductor device (power module). The semiconductor device disclosed in JP-A-2021-190505 includes a semiconductor element, a main substrate, and a substrate. The main substrate has a metal layer. The semiconductor element is electrically bonded to the metal layer. A sub-substrate is supported by the main substrate. The semiconductor device disclosed in JP-A-2021-190505 also includes a support substrate (ceramic substrate). The support substrate supports the semiconductor element. The support substrate includes an insulating base member and conductive layers formed on the respective surfaces of the base member. The base member is made of a ceramic material, for example. The conductive layers are made of copper (Cu), for example, and the semiconductor element is bonded to one of the conductive layers. The semiconductor element and the conductive layer are electrically connected by, for example, a wire made of Al.

### BRIEF DESCRIPTION OF THE DRAWINGS

FIG. 1 is a perspective view showing a semiconductor device according to a first embodiment of the present disclosure.

FIG. 2 is a partial perspective view showing the semiconductor device according to the first embodiment of the present disclosure.

FIG. 3 is a partial perspective view showing the semiconductor device according to the first embodiment of the present disclosure.

FIG. 4 is a plan view showing the semiconductor device according to the first embodiment of the present disclosure.

FIG. 5 is a partial plan view showing the semiconductor device according to the first embodiment of the present disclosure.

FIG. 6 is a partial side view showing the semiconductor device according to the first embodiment of the present disclosure.

FIG. 7 is a partially enlarged plan view showing the semiconductor device according to the first embodiment of the present disclosure.

FIG. 8 is a partial plan view showing the semiconductor device according to the first embodiment of the present disclosure.

FIG. 9 is a partial plan view showing the semiconductor device according to the first embodiment of the present disclosure.

FIG. 10 is a side view showing the semiconductor device according to the first embodiment of the present disclosure.

FIG. 11 is a bottom view showing the semiconductor device according to the first embodiment of the present disclosure.

FIG. 12 is a cross-sectional view taken along line XII-XII in FIG. 5.

FIG. 13 is a partially enlarged cross-sectional view showing the semiconductor device according to the first embodiment of the present disclosure.

FIG. 14 is a partially enlarged cross-sectional view showing the semiconductor device according to the first embodiment of the present disclosure.

FIG. 15 is a cross-sectional view taken along line XV-XV in FIG. 5.

FIG. 16 is a cross-sectional view taken along line XVI-XVI in FIG. 5.

FIG. 17 is a partially enlarged plan view showing the semiconductor device according to the first embodiment of the present disclosure.

FIG. 18 is a partially enlarged plan view showing the semiconductor device according to the first embodiment of the present disclosure.

FIG. 19 is a partially enlarged cross-sectional view taken along line XIX-XIX in FIG. 17.

FIG. 20 shows the configuration of a vehicle according to the first embodiment of the present disclosure.

FIG. 21 is a partially enlarged cross-sectional view showing a first variation of the semiconductor device according to the first embodiment of the present disclosure.

FIG. 22 is a partially enlarged cross-sectional view showing a second variation of the semiconductor device according to the first embodiment of the present disclosure.

FIG. 23 is a partially enlarged cross-sectional view showing a third variation of the semiconductor device according to the first embodiment of the present disclosure.

FIG. 24 is a partially enlarged plan view showing a fourth variation of the semiconductor device according to the first embodiment of the present disclosure.

FIG. 25 is a partially enlarged plan view showing a semiconductor device according to a second embodiment of the present disclosure.

FIG. 26 is a partially enlarged cross-sectional view taken along line XXVI-XXVI in FIG. 25.

FIG. 27 is a partially enlarged cross-sectional view showing a first variation of the semiconductor device according to the second embodiment of the present disclosure.

FIG. 28 is a partially enlarged cross-sectional view showing a second variation of the semiconductor device according to the second embodiment of the present disclosure.

FIG. 29 is a partially enlarged cross-sectional view showing a third variation of the semiconductor device according to the second embodiment of the present disclosure.

FIG. 30 is a partially enlarged plan view showing a fourth variation of the semiconductor device according to the second embodiment of the present disclosure.

FIG. 31 is a partially enlarged cross-sectional view showing the semiconductor device according to a third embodiment of the present disclosure.

FIG. 32 is a partially enlarged plan view showing a first variation of the semiconductor device according to the third embodiment of the present disclosure.

FIG. 33 is a partially enlarged cross-sectional view taken along line XXXIII-XXXIII in FIG. 32.

FIG. 34 is a perspective view showing a semiconductor device according to a fourth embodiment of the present disclosure.

FIG. 35 is a partial perspective view showing the semiconductor device according to the fourth embodiment of the present disclosure.

FIG. 36 is a partial perspective view showing the semiconductor device according to the fourth embodiment of the present disclosure.

FIG. 37 is a plan view showing the semiconductor device according to the fourth embodiment of the present disclosure.

FIG. 38 is a partial plan view showing the semiconductor device according to the fourth embodiment of the present disclosure.

FIG. 39 is a partial side view showing the semiconductor device according to the fourth embodiment of the present disclosure.

FIG. 40 is a partially enlarged plan view showing the semiconductor device according to the fourth embodiment of the present disclosure.

FIG. 41 is a partial plan view showing the semiconductor device according to the fourth embodiment of the present disclosure.

FIG. 42 is a partial plan view showing the semiconductor device according to the fourth embodiment of the present disclosure.

FIG. 43 is a side view showing the semiconductor device according to the fourth embodiment of the present disclosure.

FIG. 44 is a bottom view showing the semiconductor device according to the fourth embodiment of the present disclosure.

FIG. 45 is a cross-sectional view taken along line XLV-XLV in FIG. 38.

FIG. 46 is a cross-sectional view taken along line XLVI-XLVI in FIG. 38.

FIG. 47 is a partially enlarged cross-sectional view showing the semiconductor device according to the fourth embodiment of the present disclosure.

FIG. 48 is a partially enlarged cross-sectional view showing the semiconductor device according to the fourth embodiment of the present disclosure.

FIG. 49 is a cross-sectional view taken along line XLIX-XLIX in FIG. 38.

FIG. 50 is a cross-sectional view taken along line L-L in FIG. 38.

FIG. 51 is a cross-sectional view taken along line LI-LI in FIG. 38.

FIG. 52 is a cross-sectional view taken along line LII-LII in FIG. 38.

FIG. 53 is a cross-sectional view taken along line LIII-LIII in FIG. 38.

FIG. 54 is a cross-sectional view taken along line LIV-LIV in FIG. 42.

FIG. 55 is a partially enlarged cross-sectional view taken along line LV-LV in FIG. 54.

FIG. 56 is a partially enlarged cross-sectional view showing a third conductive component of a first variation of the semiconductor device according to the fourth embodiment of the present disclosure.

FIG. 57 is a partially enlarged cross-sectional view showing a third conductive component of a second variation of the semiconductor device according to the fourth embodiment of the present disclosure.

FIG. 58 is a partially enlarged cross-sectional view showing a third conductive component of a third variation of the semiconductor device according to the fourth embodiment of the present disclosure.

FIG. 59 is a partially enlarged cross-sectional view taken along line LIX-LIX in FIG. 58.

FIG. 60 is a partial plan view showing a semiconductor device according to a fifth embodiment of the present disclosure.

FIG. 61 is a partial cross-sectional view taken along line LXI-LXI in FIG. 60.

FIG. 62 is a partial cross-sectional view taken along line LXII-LXII in FIG. 60.

FIG. 63 is a partial cross-sectional view taken along line LXIII-LXIII in FIG. 60.

FIG. 64 is a partial cross-sectional view taken along line LXIV-LXIV in FIG. 60.

FIG. 65 is a partial plan view showing a semiconductor device according to a sixth embodiment of the present disclosure.

FIG. 66 is a partial cross-sectional view taken along line LXVI-LXVI in FIG. 65.

FIG. 67 is a partial cross-sectional view taken along line LXVII-LXVII in FIG. 65.

### DETAILED DESCRIPTION OF EMBODIMENTS

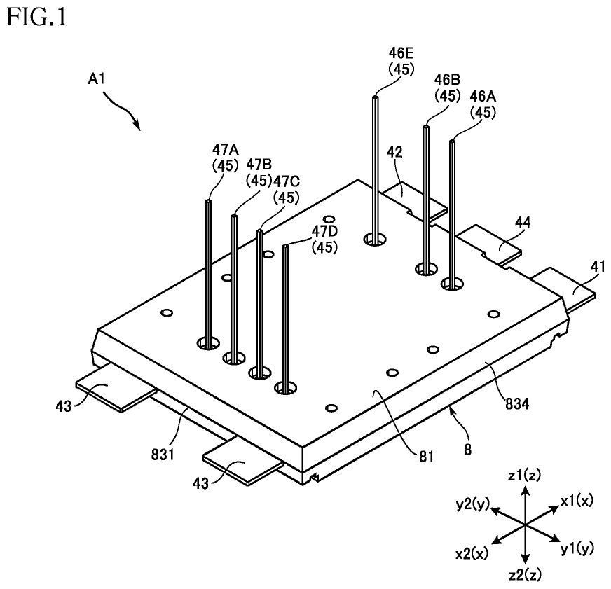

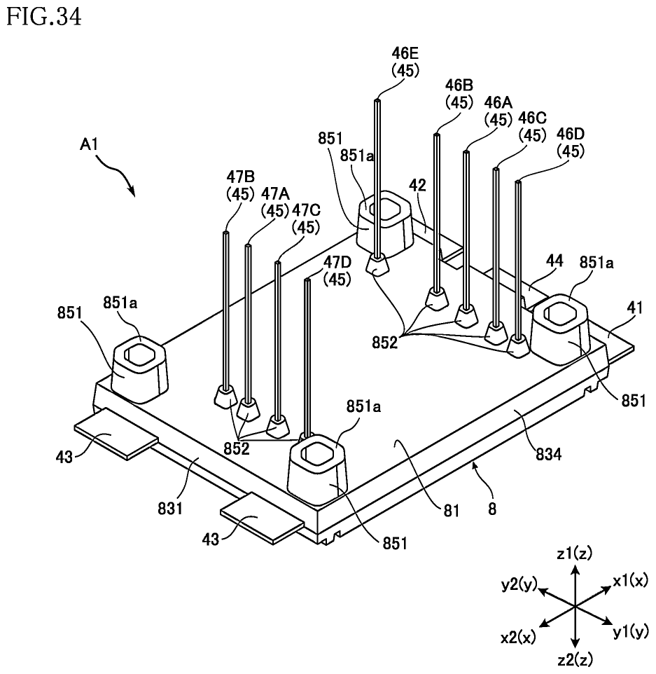

The following describes preferred embodiments of the present disclosure in detail with reference to the drawings. The reference numerals used in FIGS. 1 to 33 (first to third embodiments) are provided independently from the reference numerals used in FIGS. 34 to 67 (fourth to sixth embodiments). For example, the same reference numeral may be used for different members (elements or the like), or different reference numerals may be used for identical (or similar) members (elements or the like).

The terms such as “first”, “second” and “third” in the present disclosure are used merely for identification, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a portion of an object B”. Further, the phrase “a plane A faces (a first side or a second side) in a direction B” is not limited to the case where the angle of the plane A with respect to the direction B is 90°, but also includes the case where the plane A is inclined to the direction B.

First embodiment: FIGS. 1 to 20 show a semiconductor device according to a first embodiment of the present disclosure. A semiconductor device A1 of the present embodiment includes a plurality of first semiconductor elements 10A, a plurality of second semiconductor elements 10B, a main substrate 3, a first terminal 41, a second terminal 42, a plurality of third terminals 43, a fourth terminal 44, a plurality of control terminals 45, a first sub-substrate 48A, a second sub-substrate 48B, a first conductive member 5, a second conductive member 6, and a sealing resin 8.

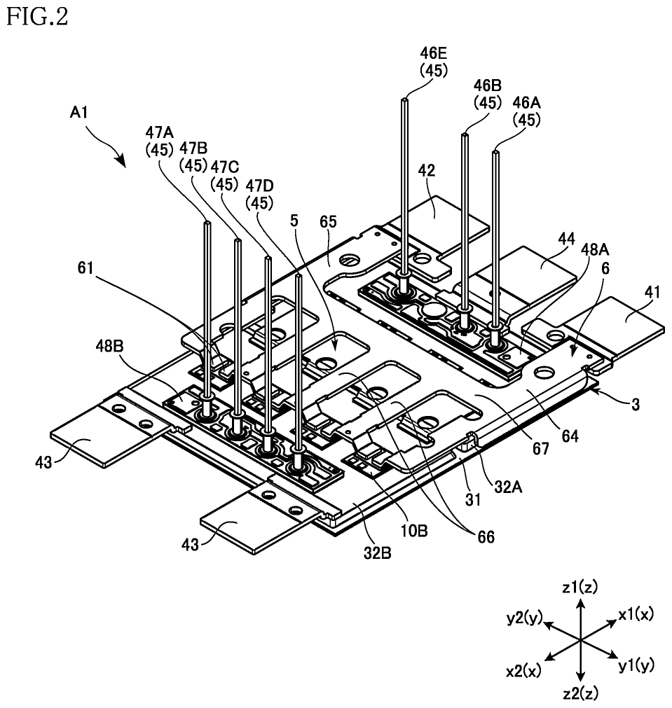

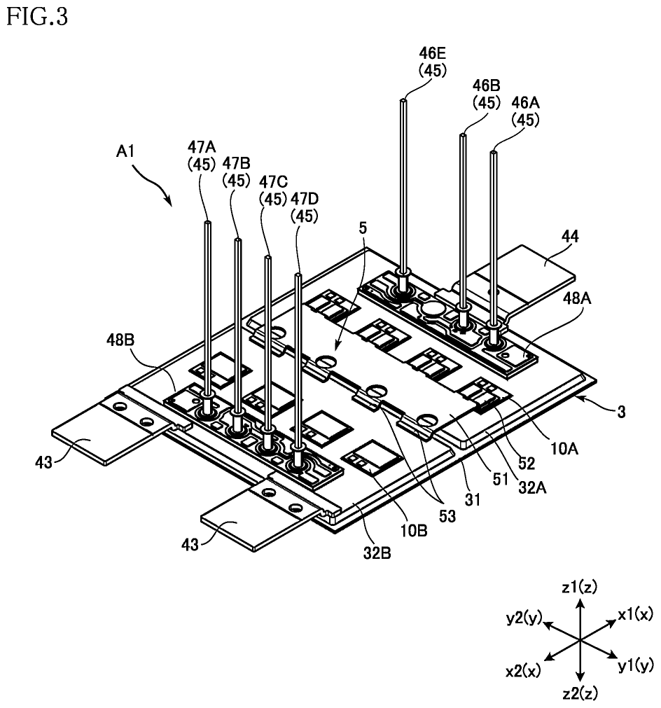

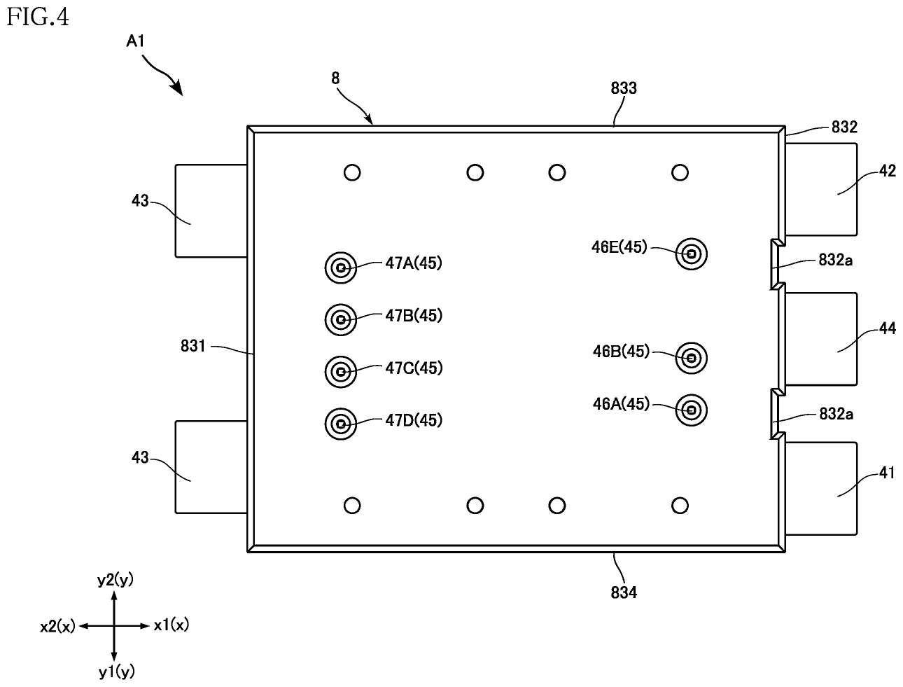

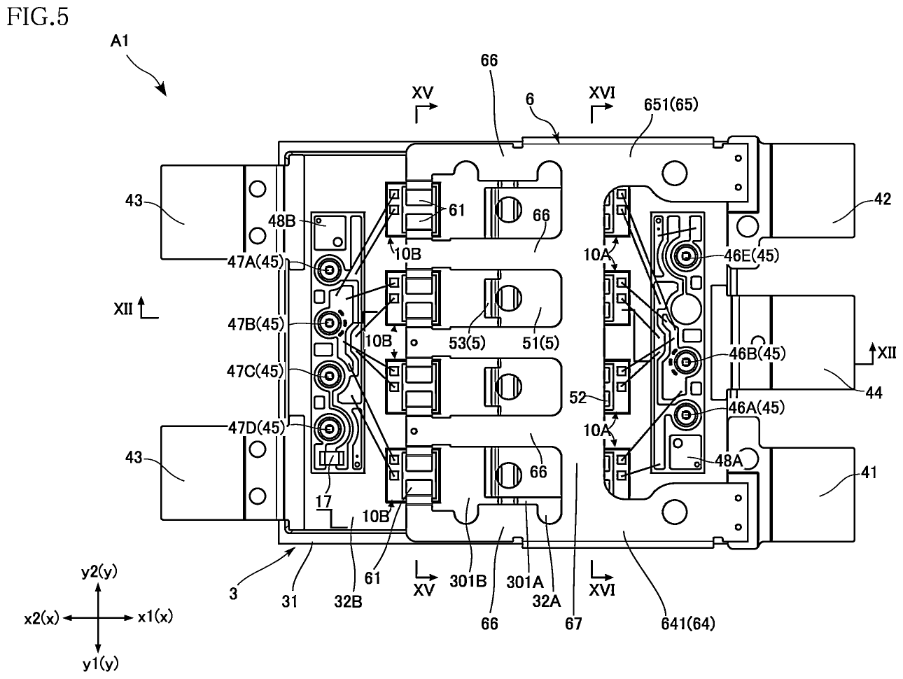

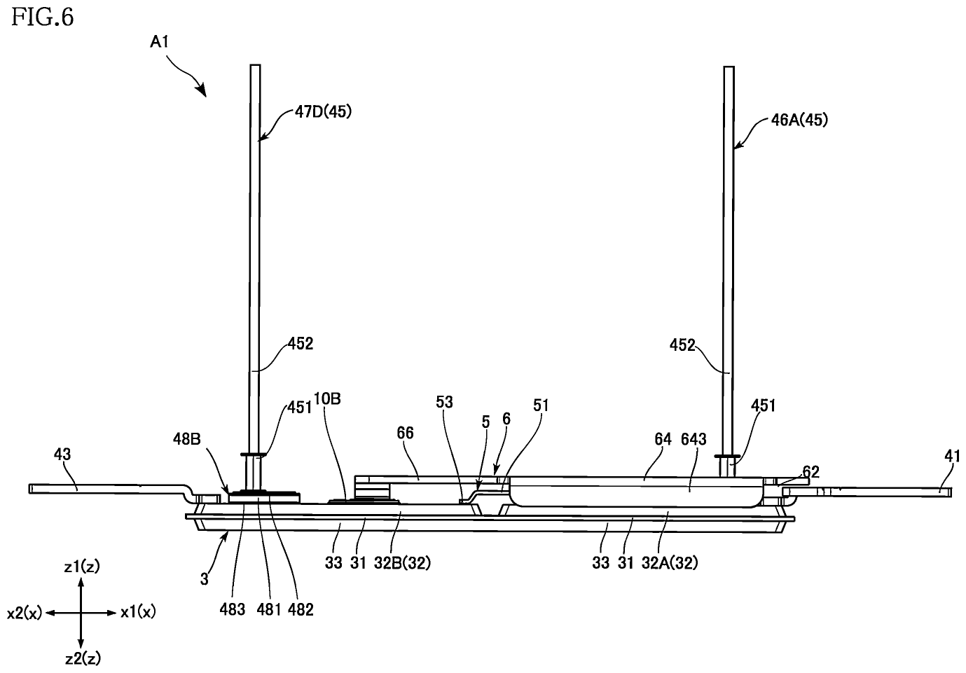

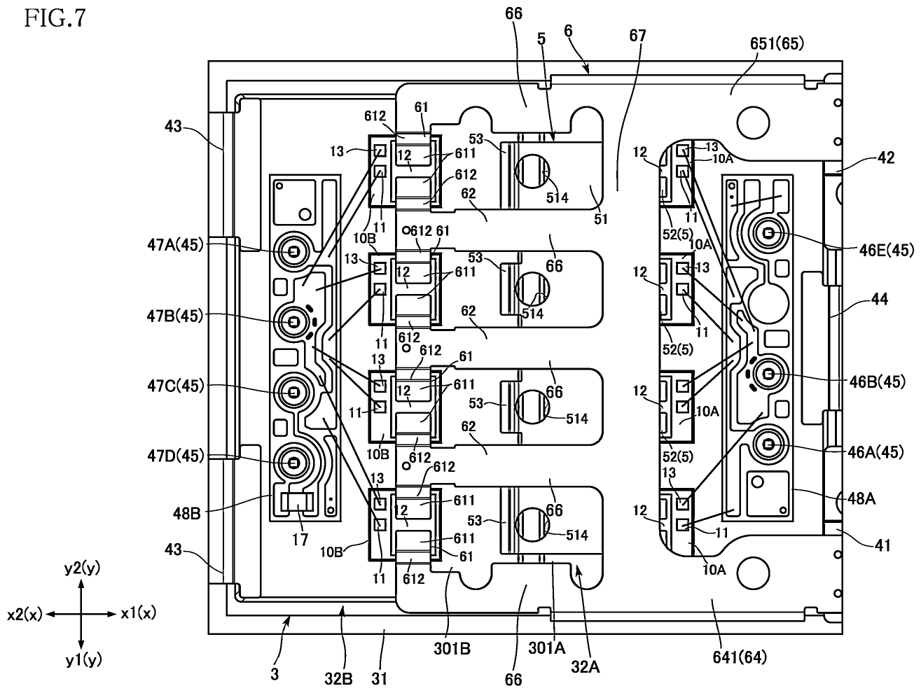

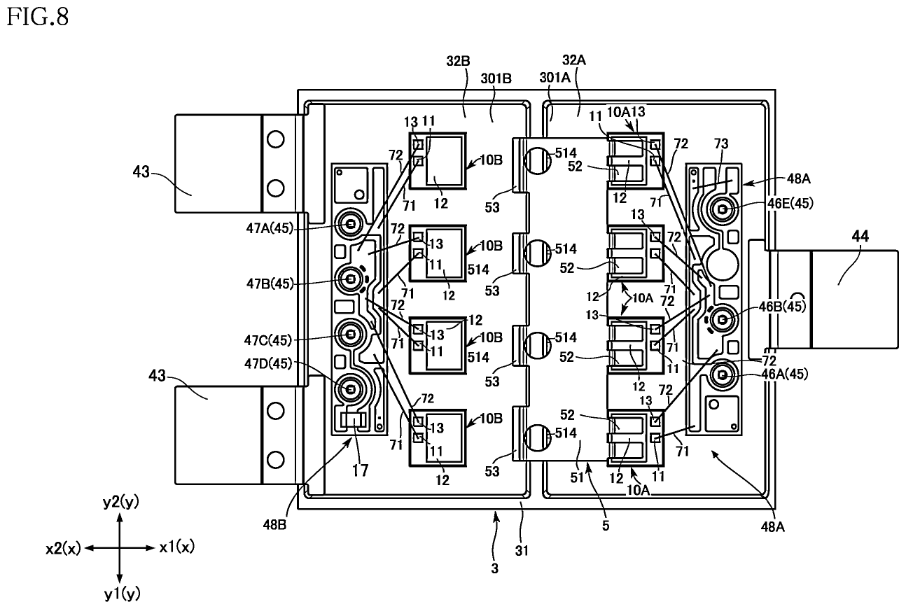

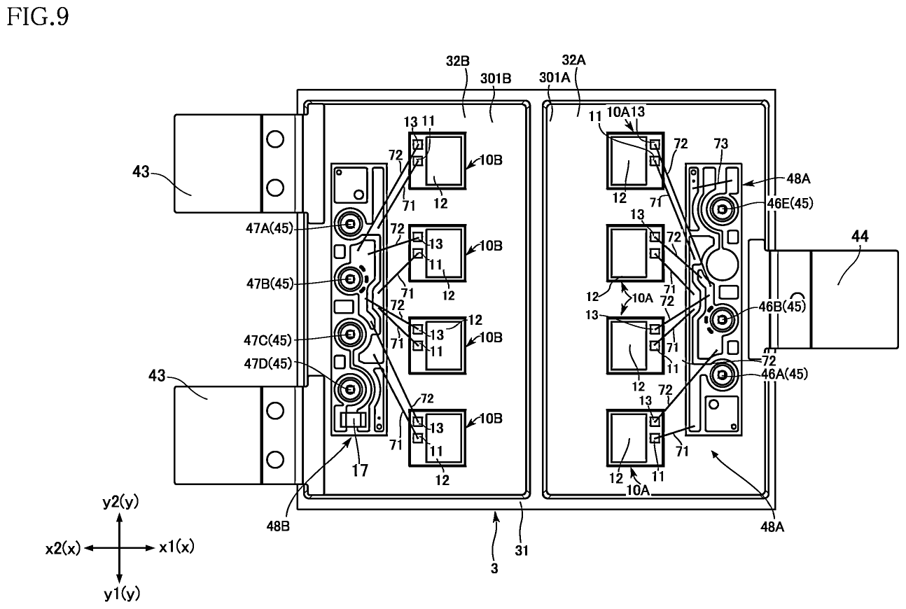

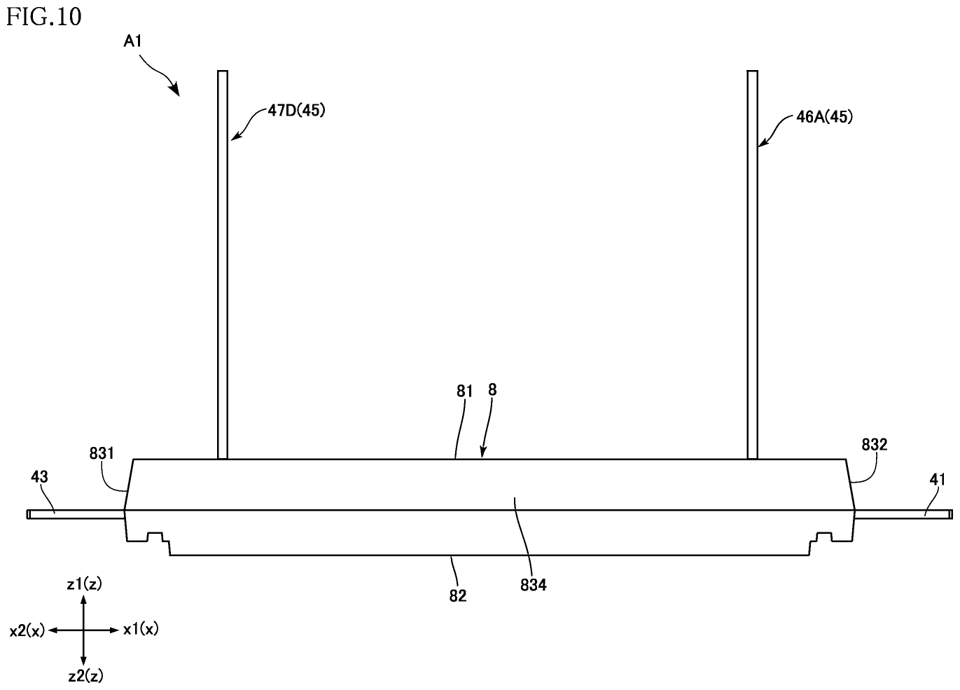

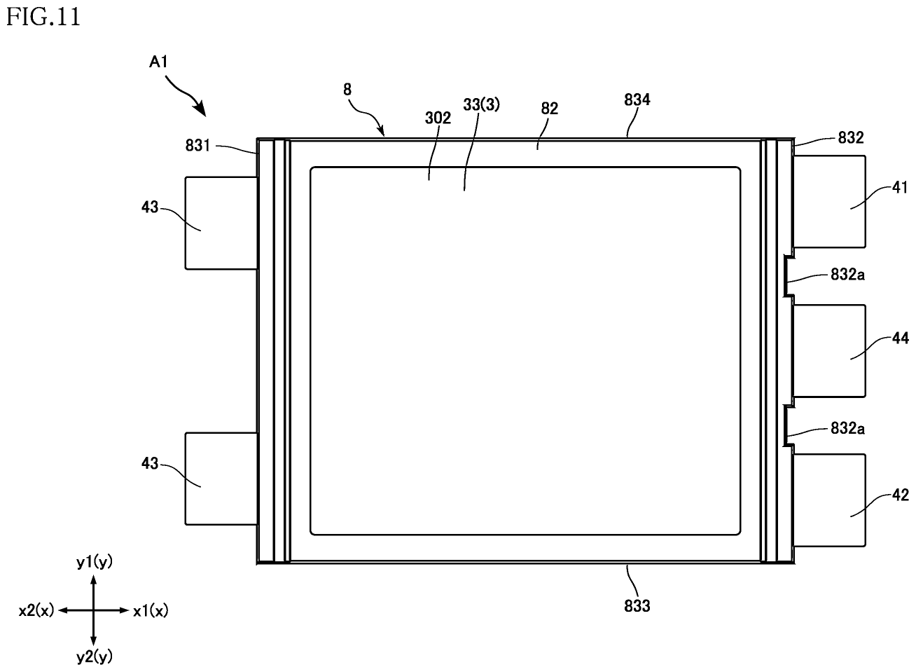

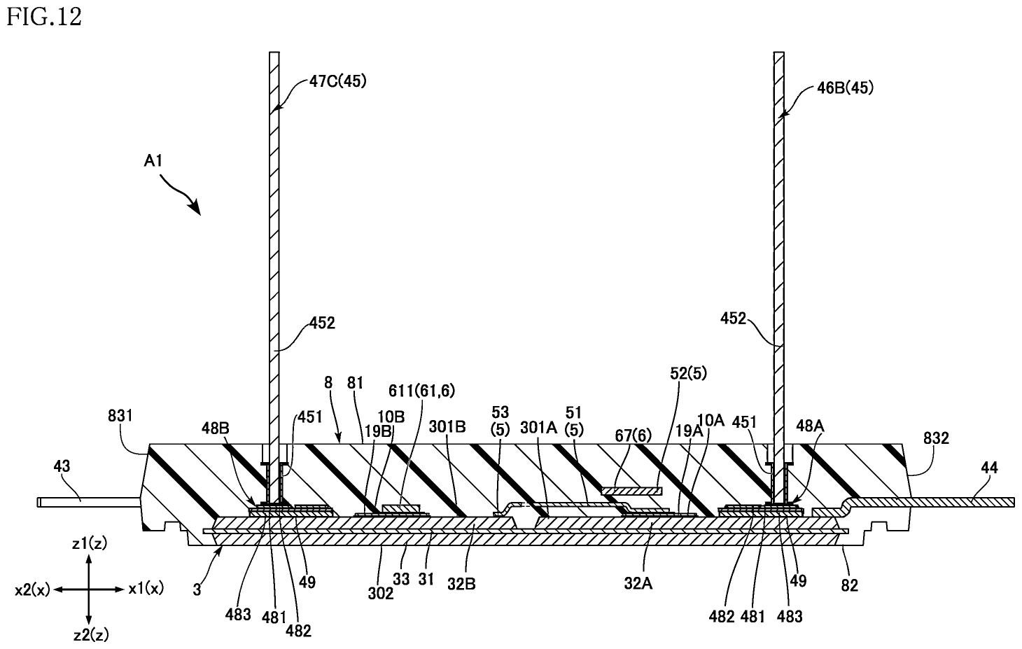

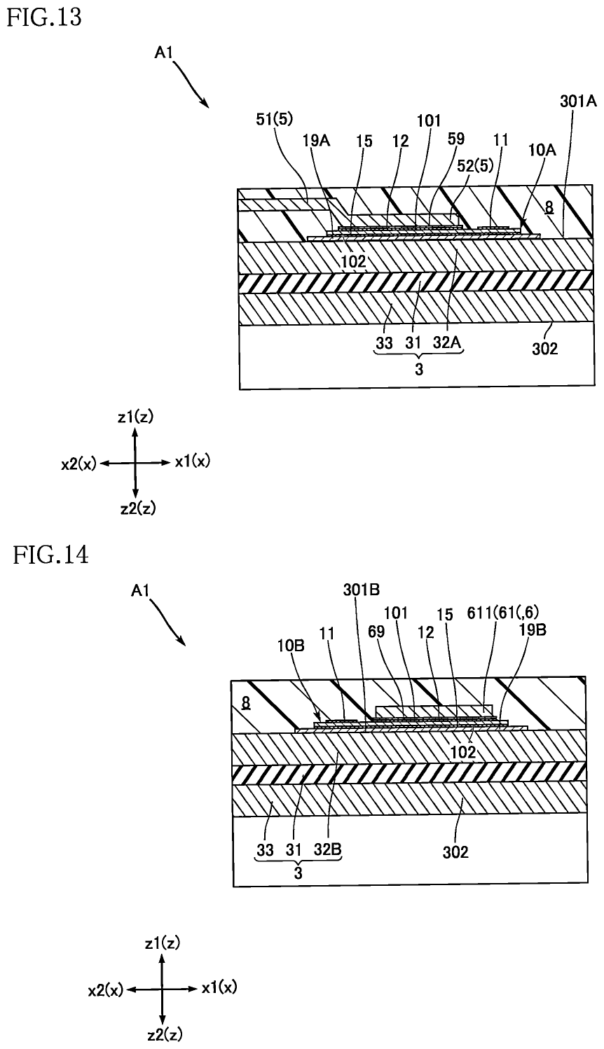

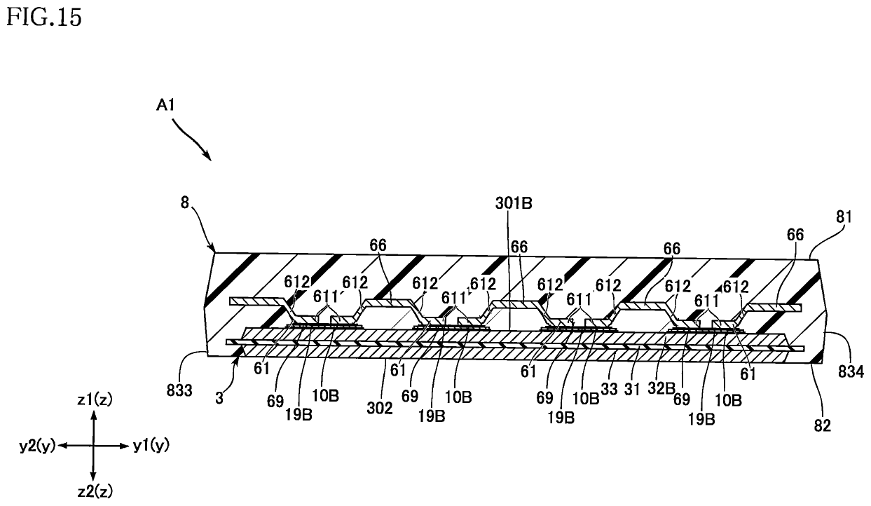

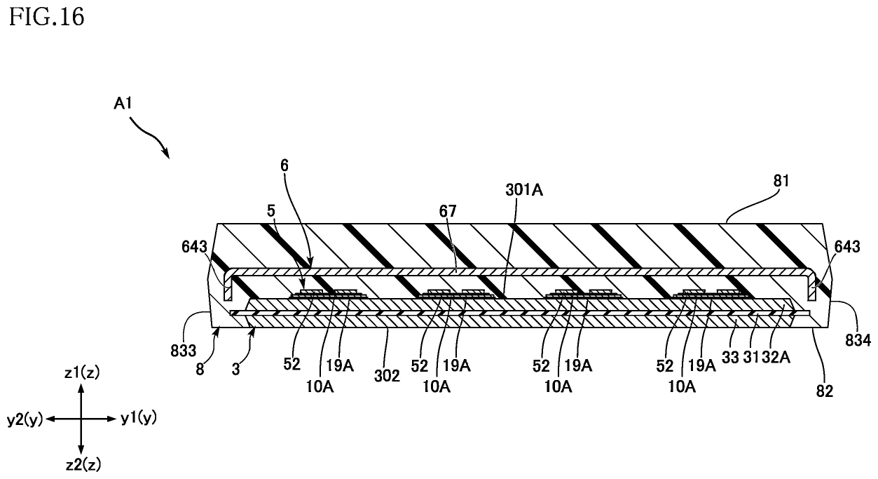

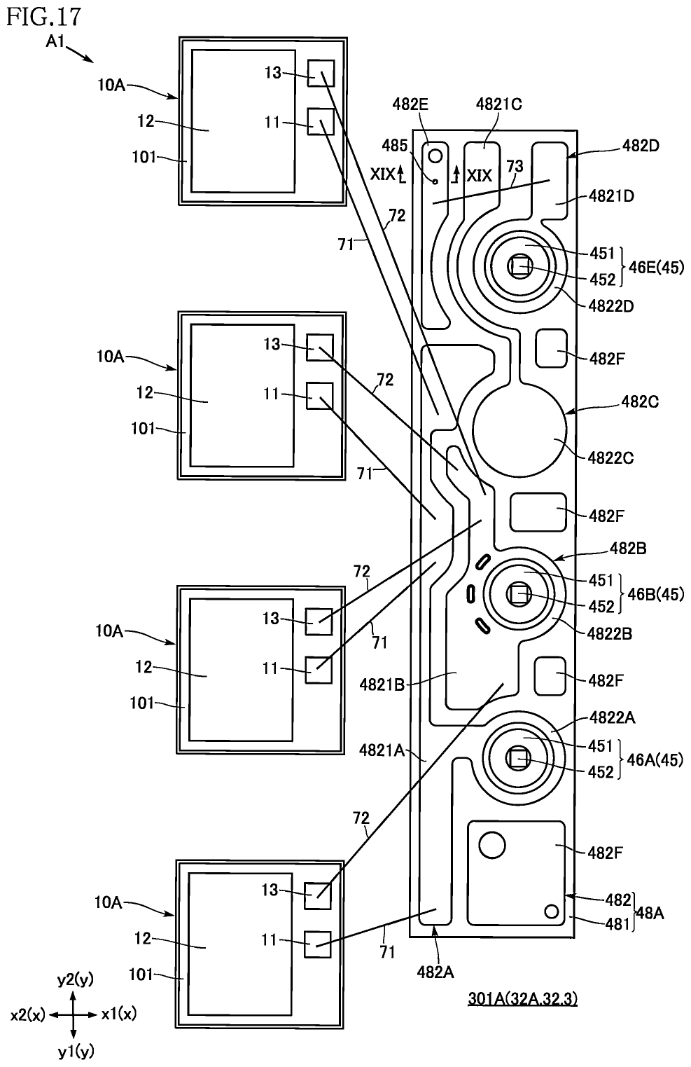

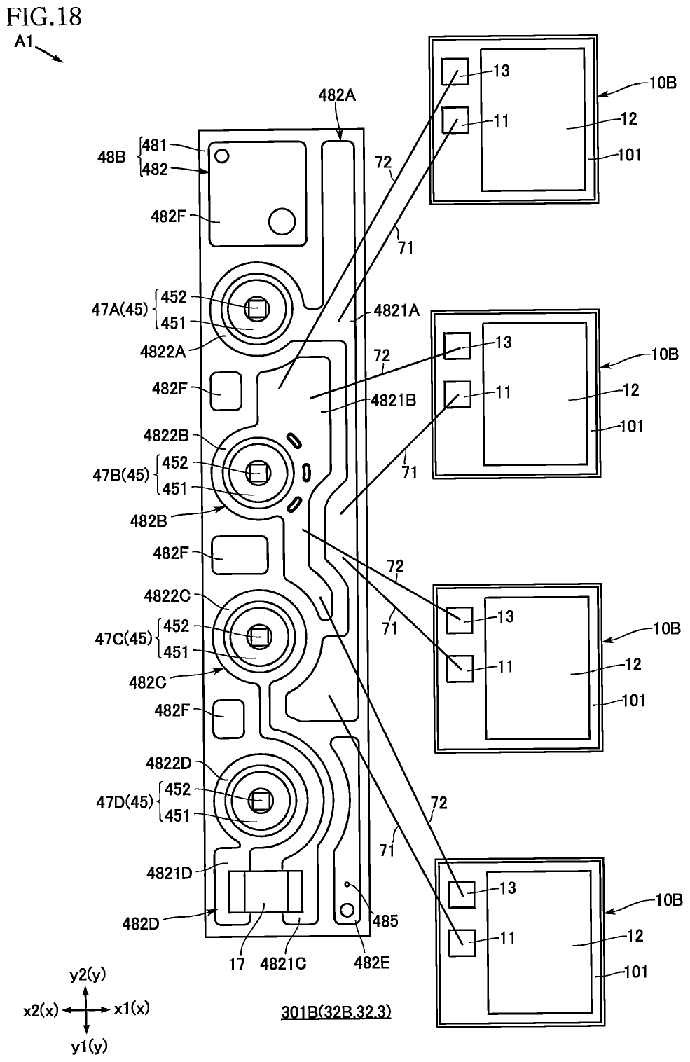

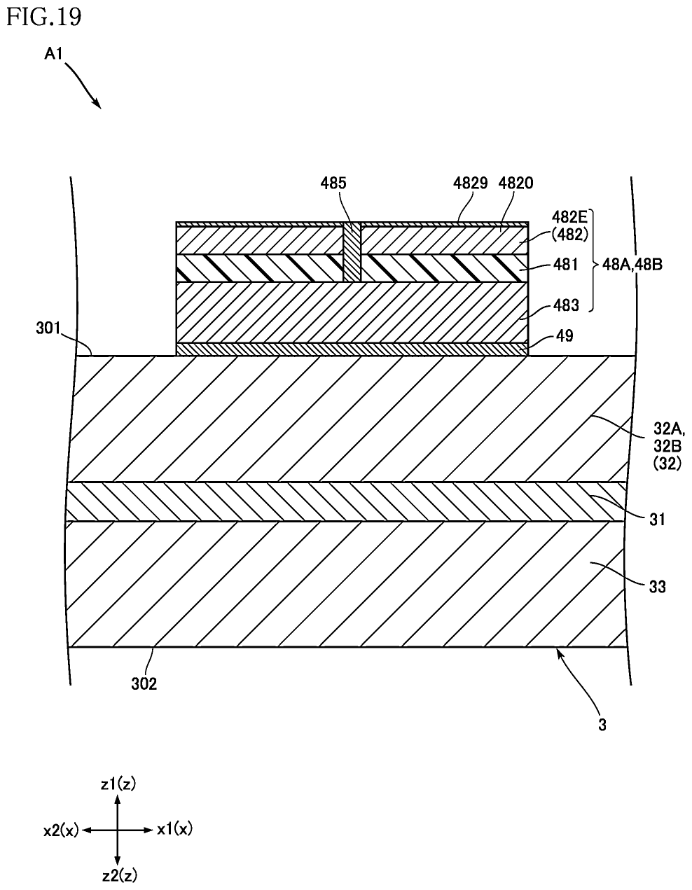

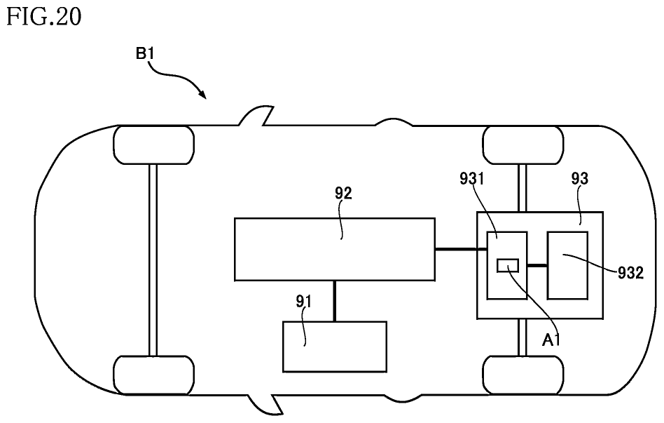

FIG. 1 is a perspective view showing the semiconductor device A1. FIG. 2 is a partial perspective view showing the semiconductor device A1. FIG. 3 is a partial perspective view showing the semiconductor device A1. FIG. 4 is a plan view showing the semiconductor device A1. FIG. 5 is a partial plan view showing the semiconductor device A1. FIG. 6 is a partial side view showing the semiconductor device A1. FIG. 7 is a partially enlarged plan view showing the semiconductor device A1. FIG. 8 is a partial plan view showing the semiconductor device A1. FIG. 9 is a partial plan view showing the semiconductor device A1. FIG. 10 is a side view showing the semiconductor device A1. FIG. 11 is a bottom view showing the semiconductor device A1. FIG. 12 is a cross-sectional view taken along line XII-XII in FIG. 5. FIG. 13 is a partially enlarged cross-sectional view showing the semiconductor device A1. FIG. 14 is a partially enlarged cross-sectional view showing the semiconductor device A1. FIG. 15 is a cross-sectional view taken along line XVIII-XVIII in FIG. 5. FIG. 16 is a cross-sectional view taken along line XX-XX in FIG. 5. FIG. 17 is a partially enlarged plan view showing the semiconductor device A1. FIG. 18 is a partially enlarged plan view showing the semiconductor device A1. FIG. 19 is a partially enlarged cross-sectional view taken along line XIX-XIX in FIG. 17. FIG. 20 shows the configuration of a vehicle according to the first embodiment of the present disclosure. In FIG. 19, the sealing resin 8 is omitted to facilitate understanding.

A thickness direction z in FIGS. 1 to 20 is a thickness direction in the present disclosure. A first direction x is a direction perpendicular to the thickness direction z. A second direction y is the direction perpendicular to the thickness direction z and the first direction x. One side in the first direction x is referred to as x1 side in the first direction x, and the other side in the first direction x as x2 side in the first direction x. One side in the second direction y is referred to as y1 side in the second direction y, and the other side in the second direction y as y2 side in the second direction y. One side in the thickness direction z is referred to as z1 side in the thickness direction z, and the other side in the thickness direction z as z2 side in the thickness direction z.

First semiconductor elements 10A and second semiconductor elements 10B: Each of the first semiconductor elements 10A and the second semiconductor elements 10B is an electronic component that forms the functional core of the semiconductor device A1. The first semiconductor elements 10A and the second semiconductor elements 10B are made of a semiconductor material mainly containing silicon carbide (SiC), for example. The semiconductor material is not limited to silicon carbide (SiC), and may be silicon (Si), gallium nitride (GaN), or diamond (C). Each of the first semiconductor elements 10A and the second semiconductor elements 10B is a power semiconductor chip having a switching function such as a metal oxide semiconductor field effect transistor (MOSFET), for example. The first semiconductor elements 10A and the second semiconductor elements 10B are MOSFETs in the present embodiment, but may be other transistors such as insulated gate bipolar transistors (IGBTs) in other examples. The first semiconductor elements 10A and the second semiconductor elements 10B may have different configurations or the same configuration. In the following description, the first semiconductor elements 10A and the second semiconductor elements 10B are identical to each other. The first semiconductor elements 10A and the second semiconductor elements 10B are n-channel MOSFETs, but may be p-channel MOSFETs instead.

As shown in FIGS. 13 and 14, each of the first semiconductor elements 10A and the second semiconductor elements 10B has an element obverse surface 101 and an element reverse surface 102. In each of the first semiconductor elements 10A and the second semiconductor elements 10B, the element obverse surface 101 and the element reverse surface 102 are spaced apart from each other in the thickness direction z. The element obverse surface 101 faces the z1 side in the thickness direction z, and the element reverse surface 102 faces the z2 side in the thickness direction z.

The number of first semiconductor elements 10A and the number of second semiconductor elements 10B are changed appropriately according to the performance required such as the capacity of current handled by the semiconductor device A1. In the present embodiment, four first semiconductor elements 10A and four second semiconductor elements 10B are arranged as shown in FIGS. 8 and 9. Each of the number of first semiconductor elements 10A and the number of second semiconductor elements 10B may be two or three, or may be five or greater. The number of first semiconductor elements 10A may be the same as or different from the number of second semiconductor elements 10B.

The semiconductor device A1 is configured as a half-bridge switching circuit, for example. In this case, the first semiconductor elements 10A form an upper arm circuit of the semiconductor device A1, and the second semiconductor elements 10B form a lower arm circuit. In the upper arm circuit, the first semiconductor elements 10A are connected in parallel. In the lower arm circuit, the second semiconductor elements 10B are also connected in parallel. Each first semiconductor element 10A is connected in series to a second semiconductor element 10B to form a bridge layer.

As shown in FIGS. 8, 9, and 16 in particular, the first semiconductor elements 10A are mounted on a below-described first conductive portion 32A of the main substrate 3. In the example shown in FIGS. 8 and 9, the first semiconductor elements 10A are aligned in the second direction y and spaced apart from each other. Each of the first semiconductor elements 10A is electrically bonded to the first conductive portion 32A via a first conductive bonding member 19A. The element reverse surface 102 of each first semiconductor element 10A faces the first conductive portion 32A.

As shown in FIGS. 8, 9, and 15 in particular, the second semiconductor elements 10B are mounted on a below-described second conductive portion 32B of the main substrate 3. In the example shown in FIGS. 8 and 9, the second semiconductor elements 10B are aligned in the second direction y and spaced apart from each other. Each of the second semiconductor elements 10B is electrically bonded to the second conductive portion 32B via a second conductive bonding member 19B. The element reverse surface 102 of each second semiconductor element 10B faces the second conductive portion 32B. As can be understood from FIG. 9, the first semiconductor elements 10A and the second semiconductor elements 10B overlap with each other as viewed in the first direction x, but this overlap is not necessary.

Each of the first semiconductor elements 10A and the second semiconductor elements 10B includes a first obverse-surface electrode 11, a second obverse-surface electrode 12, a third obverse-surface electrode 13, and a reverse-surface electrode 15. The description given below of the configurations of the first obverse-surface electrode 11, the second obverse-surface electrode 12, the third obverse-surface electrode 13, and the reverse-surface electrode 15 is common to all the first semiconductor elements 10A and the second semiconductor elements 10B. The first obverse-surface electrode 11, the second obverse-surface electrode 12, and the third obverse-surface electrode 13 are disposed on the element obverse surface 101. The first obverse-surface electrode 11, the second obverse-surface electrode 12, and the third obverse-surface electrode 13 are insulated by a non-illustrated insulating film. The reverse-surface electrode 15 is disposed on the element reverse surface 102.

The first obverse-surface electrode 11 is a gate electrode, for example, and receives a drive signal (e.g., gate voltage) inputted to drive the first semiconductor element 10A (the second semiconductor element 10B). The second obverse-surface electrode 12 of the first semiconductor element 10A (the second semiconductor element 10B) is a source electrode, for example, and conducts a source current. The third obverse-surface electrode 13 is a source sense electrode, for example, and conducts the source current. The reverse-surface electrode 15 is a drain electrode, for example, and conducts a drain current. The reverse-surface electrode 15 covers substantially the entirety of the element reverse surface 102. The reverse-surface electrode 15 is formed by silver (Ag) plating, for example.

Each first semiconductor element 10A (each second semiconductor element 10B) switches between a conducting state and a non-conducting state in response to a drive signal (gate voltage) inputted to the first obverse-surface electrode 11 (the gate electrode). In the conducting state, a current flows from the reverse-surface electrode 15 (the drain electrode) to the second obverse-surface electrode 12 (the source electrode). In the non-conducting state, the current does not flow. In short, each first semiconductor element 10A (each second semiconductor element 10B) performs a switching operation. With the switching functions of the first semiconductor elements 10A and the second semiconductor elements 10B, the semiconductor device A1 converts the DC voltage inputted between the fourth terminal 44 and each of the first terminal 41 and the second terminal 42 into AC voltage, for example, and outputs the AC voltage from the third terminals 43.

Main substrate 3: The main substrate 3 supports the first semiconductor elements 10A and the second semiconductor elements 10B. The specific configuration of the main substrate 3 is not particularly limited. For example, the main substrate 3 may be a direct bonded copper (DBC) substrate or an active metal brazing (AMB) substrate. The main substrate 3 includes a main insulating layer 31, a first main metal layer 32, and a second main metal layer 33. The first main metal layer 32 includes the first conductive portion 32A and the second conductive portion 32B. The dimension of the main substrate 3 in the thickness direction z is not particularly limited, and may be at least 0.4 mm and at most 3.0 mm, for example. In the illustrated example, the first main metal layer 32 is a single layer and does not include a plating layer or the like.

The constituent material of the main insulating layer 31 may contain ceramic having excellent thermal conductivity. Examples of such a ceramic material include silicon nitride (SiN). The constituent material of the main insulating layer 31 is not limited to ceramic, and may be an insulating resin sheet, for example. The main insulating layer 31 is rectangular in plan view, for example. The dimension of the main insulating layer 31 in the thickness direction z is not particularly limited, and may be at least 0.05 mm and at most 1.0 mm, for example.

As shown in FIGS. 8, 9, and 12, the first conductive portion 32A supports the first semiconductor elements 10A, and the second conductive portion 32B supports the second semiconductor elements 10B. The first conductive portion 32A and the second conductive portion 32B are formed on the upper surface (the surface facing the z1 side in the thickness direction z) of the main insulating layer 31. The constituent material of each of the first conductive portion 32A and the second conductive portion 32B contains copper (Cu), for example. The constituent material may contain aluminum (Al) instead of copper (Cu), for example. The first conductive portion 32A and the second conductive portion 32B are spaced apart from each other in the first direction x. The first conductive portion 32A is located on the x1 side in the first direction x from the second conductive portion 32B. Each of the first conductive portion 32A and the second conductive portion 32B is rectangular in plan view, for example. The first conductive portion 32A and the second conductive portion 32B, together with the first conductive member 5 and the second conductive member 6, form the path of a main circuit current that is switched by the first semiconductor elements 10A and the second semiconductor elements 10B.

The first conductive portion 32A has a first obverse surface 301A. The first obverse surface 301A is a flat surface facing the z1 side in the thickness direction z. Each of the first semiconductor elements 10A is bonded to the first obverse surface 301A of the first conductive portion 32A via a first conductive bonding member 19A. The second conductive portion 32B has a second obverse surface 301B. The second obverse surface 301B is a flat surface facing the z1 side in the thickness direction z. Each of the second semiconductor elements 10B is bonded to the second obverse surface 301B of the second conductive portion 32B via a second conductive bonding member 19B. The constituent material of each of the first conductive bonding members 19A and the second conductive bonding members 19B is not particularly limited, and examples include solder, metal paste containing a metal such as silver (Ag), or a sintered metal containing a metal such as silver (Ag). The dimension of each of the first conductive portion 32A and the second conductive portion 32B in the thickness direction z is not particularly limited, and may be at least 0.1 mm and at most 1.5 mm, for example.

The second main metal layer 33 is formed on the lower surface (the surface facing the z2 side in the thickness direction z) of the main insulating layer 31. The constituent material of the second main metal layer 33 is the same as that of the first main metal layer 32, for example. The second main metal layer 33 has a reverse surface 302. The reverse surface 302 is a flat surface facing the z2 side in the thickness direction z. In the example shown in FIG. 11, the reverse surface 302 is exposed from the scaling resin 8, for example. A heat dissipating member (e.g., a heat sink), which is not shown in the figures, can be attached to the reverse surface 302. In another example, the reverse surface 302 may not be exposed from the sealing resin 8, and may be covered with the scaling resin 8. In plan view, the second main metal layer 33 overlaps with the first conductive portion 32A and the second conductive portion 32B.

First terminal 41, second terminal 42, third terminals 43, and fourth terminal 44: The specific configuration of each of the first terminal 41, the second terminal 42, the third terminals 43, and the fourth terminal 44 is not particularly limited. In the present embodiment, each of these terminals may be made of a metal plate. The metal plate may contain copper (Cu) or an alloy of copper (Cu), for example. In the example shown in FIGS. 1 to 6, 8, 9, and 11, the semiconductor device A1 includes one first terminal 41, one second terminal 42, one fourth terminal 44, and two third terminals 43, but the respective numbers of these terminals are not particularly limited.

The first terminal 41, the second terminal 42, and the fourth terminal 44 are input terminals for DC voltage that is to be converted. The fourth terminal 44 may be a positive electrode (P terminal), and the first terminal 41 and the second terminal 42 may be negative electrodes (N terminals). The third terminals 43 are output terminals for the AC voltage resulting from the power conversion by the first semiconductor elements 10A and the second semiconductor elements 10B. Each of the first terminal 41, the second terminal 42, the third terminals 43, and the fourth terminal 44 includes a portion covered with the sealing resin 8 and a portion exposed from the sealing resin 8.

As shown in FIG. 12, the fourth terminal 44 is electrically bonded to the first conductive portion 32A. The method for electrical bonding is not particularly limited, and may be ultrasonic bonding, laser bonding, welding, or bonding with solder, metal paste or a sintered silver, as appropriate. The fourth terminal 44 may have a configuration integrally formed with the first conductive portion 32A. As shown in FIGS. 8 and 9 in particular, the fourth terminal 44 is located on the x1 side in the first direction x from the first semiconductor elements 10A and the first conductive portion 32A. The fourth terminal 44 is electrically connected to the first conductive portion 32A, and also to the reverse-surface electrodes 15 (the drain electrodes) of the first semiconductor elements 10A via the first conductive portion 32A.

As shown in FIG. 5, the first terminal 41 and the second terminal 42 are electrically bonded to the second conductive member 6. The method for electrical bonding is not particularly limited, and may be ultrasonic bonding, laser bonding, welding, or bonding with solder, metal paste or a sintered silver, as appropriate. Each of the first terminal 41 and the second terminal 42 may have a configuration integrally formed with the second conductive member 6. As shown in FIGS. 5 and 8 in particular, the first terminal 41 and the second terminal 42 are located on the x1 side in the first direction x from the first semiconductor elements 10A and the first conductive portion 32A. The first terminal 41 and the second terminal 42 are electrically connected to the second conductive member 6, and also to the second obverse-surface electrodes 12 (the source electrodes) of the respective second semiconductor elements 10B via the second conductive member 6.

As shown in FIGS. 1 to 5, and 11 in particular, the first terminal 41, the second terminal 42, and the fourth terminal 44 of the semiconductor device A1 protrude from the sealing resin 8 toward the x1 side in the first direction x. The first terminal 41, the second terminal 42, and the fourth terminal 44 are spaced apart from each other. The first terminal 41 and the second terminal 42 are located opposite to each other across the fourth terminal 44 in the second direction y. The first terminal 41 is located on the y1 side in the second direction y from the fourth terminal 44, and the second terminal 42 is located on the y2 side in the second direction y from the fourth terminal 44. The first terminal 41, the second terminal 42, and the fourth terminal 44 overlap with each other as viewed in the second direction y.

As can be seen from FIGS. 8, 9, and 12, the two third terminals 43 are electrically bonded to the second conductive portion 32B. The method for electrical bonding is not particularly limited, and may be ultrasonic bonding, laser bonding, welding, or bonding with solder, metal paste or a sintered silver, as appropriate. As shown in FIG. 8 in particular, the two third terminals 43 are located on the x2 side in the first direction x from the second semiconductor elements 10B and the second conductive portion 32B. The third terminals 43 are electrically connected to the second conductive portion 32B, and also to the reverse-surface electrodes 15 (the drain electrodes) of the second semiconductor elements 10B via the second conductive portion 32B. Note that the number of third terminals 43 is not limited to two, and may be one or greater than two. If one third terminal 43 is provided, it is preferable that the third terminal 43 be connected to the central portion of the second conductive portion 32B in the second direction y.

First sub-substrate 48A and second sub-substrate 48B: The first sub-substrate 48A and the second sub-substrate 48B support the control terminals 45. The first sub-substrate 48A and the second sub-substrate 48B are located between the first and second obverse surfaces 301A and 301B and the control terminals 45 in the thickness direction z. The first sub-substrate 48A and the second sub-substrate 48B may have different configurations or the same configuration. The first sub-substrate 48A is disposed on the first conductive portion 32A. The second sub-substrate 48B is disposed on the second conductive portion 32B. In the present embodiment, the first sub-substrate 48A and the second sub-substrate 48B have the same configuration where one of them is rotated 180° with respect to the other as viewed in the thickness direction z.

The specific configuration of each of the first sub-substrate 48A and the second sub-substrate 48B is not particularly limited. Specific examples of the configuration of the first sub-substrate 48A and the second sub-substrate 48B include an insulated metal substrate (IMS substrate) and a glass epoxy resin substrate. In the present embodiment, the first sub-substrate 48A and the second sub-substrate 48B are IMS substrates. Each of the first sub-substrate 48A and the second sub-substrate 48B includes a stack of a sub-insulating layer 481, a first sub-metal layer 482, and a second sub-metal layer 483.

The sub-insulating layer 481 is made of a ceramic material, for example. The sub-insulating layer 481 is rectangular in plan view, for example. The thickness of the sub-insulating layer 481 is not particularly limited, and may be at least 0.05 mm and at most 1.0 mm, for example.

As shown in FIG. 19 in particular, the first sub-metal layer 482 is formed on the upper surface (the surface facing the z1 side in the thickness direction z) of the sub-insulating layer 481. The first sub-metal layer 482 may contain copper (Cu) or an alloy of copper (Cu), for example. The specific configuration of the first sub-metal layer 482 is not particularly limited. In the present embodiment, the first sub-metal layer 482 includes a base layer 4820 and a surface metal layer 4829. The base layer 4820 is in contact with the sub-insulating layer 481. The base layer 4820 may contain copper (Cu) or an alloy of copper (Cu), for example. The thickness of the base layer 4820 is not particularly limited, and may be at least 0.035 mm and at most 2.0 mm, for example. The surface metal layer 4829 is formed on the surface of the base layer 4820 opposite from the sub-insulating layer 481. The surface metal layer 4829 contains a metal different from the constituent material of the base layer 4820, and may contain nickel (Ni). The surface metal layer 4829 may be configured by a stack of a plurality of metal layers. The thickness of the surface metal layer 4829 is not particularly limited, and may be at least 1 μm and at most 10 μm, for example.

As shown in FIGS. 17 and 18, the first sub-metal layer 482 includes a plurality of regions 482A, 482B, 482C, 482D, 482E, and 482F. The plurality of regions 482A, 482B, 482C, 482D, 482E, and 482F are spaced apart and insulated from each other.

The region 482A includes a connecting portion 4821A and a terminal portion 4822A. In the first sub-substrate 48A, the connecting portion 4821A is located on the x2 side in the first direction x, and the terminal portion 4822A is located on the x1 side in the first direction x. In the second sub-substrate 48B, the connecting portion 4821A is located on the x1 side in the first direction x, and the terminal portion 4822A is located on the x2 side in the first direction x. The connecting portion 4821A is elongated in the second direction y. The terminal portion 4822A has a substantially circular shape.

A plurality of wires 71 are bonded to the connecting portion 4821A. In the present embodiment, the wires 71 are bonded to the surface metal layer 4829 of the connecting portion 4821A. The constituent material of the wires 71 is not particularly limited, and may contain aluminum (Al) or an alloy of aluminum (Al). The region 482A is electrically connected to the first obverse-surface electrodes 11 (gate electrodes) of the first semiconductor elements 10A (the second semiconductor elements 10B) via the wires 71.

The region 482B includes a connecting portion 4821B and a terminal portion 4822B. In the first sub-substrate 48A, the connecting portion 4821B is located on the x2 side in the first direction x, and the terminal portion 4822B is located on the x1 side in the first direction x. In the second sub-substrate 48B, the connecting portion 4821B is located on the x1 side in the first direction x, and the terminal portion 4822B is located on the x2 side in the first direction x. In the first sub-substrate 48A, the region 482B is located on the x1 side in the first direction x from the connecting portion 4821A. In the second sub-substrate 48B, the region 482B is located on the x2 side in the first direction x from the connecting portion 4821A. The connecting portion 4821B is elongated in the second direction y. The terminal portion 4822B has a substantially circular shape. In the first sub-substrate 48A, the terminal portion 4822B is located on the y2 side in the second direction y from the terminal portion 4822A. In the second sub-substrate 48B, the terminal portion 4822B is located on the y1 side in the second direction y from the terminal portion 4822A.

A plurality of wires 72 are bonded to the connecting portion 4821B. In the present embodiment, the wires 72 are bonded to the surface metal layer 4829 of the connecting portion 4821B. The constituent material of the wires 72 is not particularly limited, and may contain aluminum (Al) or an alloy of aluminum (Al). The region 482B is electrically connected to the third obverse-surface electrodes 13 (the source sense electrodes) of the first semiconductor elements 10A (the second semiconductor elements 10B) via the wires 72.

The region 482C includes a connecting portion 4821C and a terminal portion 4822C. In the first sub-substrate 48A, the connecting portion 4821C is located on the y2 side in the second direction y, and the terminal portion 4822C is located on the y1 side in the second direction y. In the second sub-substrate 48B, the connecting portion 4821C is located on the y1 side in the second direction y, and the terminal portion 4822C is located on the y2 side in the second direction y. The connecting portion 4821C has a bent shape extending in the second direction y. The terminal portion 4822C has a substantially circular shape. In the first sub-substrate 48A, the terminal portion 4822C is located on the x1 side in the first direction x from the connecting portion 4821A, and is located on the y2 in the second direction y from the terminal portion 4822B. In the second sub-substrate 48B, the terminal portion 4822C is located on the x2 side in the first direction x from the connecting portion 4821A, and is located on the y1 side in the second direction y from the terminal portion 4822B.

The region 482D includes a connecting portion 4821D and a terminal portion 4822D. In the first sub-substrate 48A, the connecting portion 4821D is located on the y2 side in the second direction y, and the terminal portion 4822D is located on the y1 side in the second direction y. The connecting portion 4821D has a rectangular shape, for example, and the terminal portion 4822D has a substantially circular shape, for example. In the first sub-substrate 48A, the connecting portion 4821D is located on the x1 side in the first direction x from the connecting portion 4821C. In the second sub-substrate 48B, the connecting portion 4821D is located on the x2 side in the first direction x from the connecting portion 4821C. In the first sub-substrate 48A, the terminal portion 4822D is located on the y2 side in the second direction y from the terminal portion 4822C. In the first sub-substrate 48A, the terminal portion 4822D is located on the y2 side in the second direction y from the terminal portion 4822C.

In the first sub-substrate 48A, the region 482E is located on the y2 side in the second direction y from the connecting portion 4821A, and on the x2 side in the first direction x from the connecting portion 4821C. In the second sub-substrate 48B, the region 482E is located on the y1 side in the second direction y from the connecting portion 4821A, and on the x1 side in the first direction x from the connecting portion 4821C. The region 482E is elongated in the second direction y.

The region 482E corresponds to the “first region” in the present disclosure. The region 482D corresponds to the “second region” in the present disclosure. The region 482C corresponds to the “third region” in the present disclosure. In other words, the region 482C is located between the region 482E and the region 482D in the first direction x.

The regions 482F are arranged alternately with the terminal portion 4822A, the terminal portion 4822B, the terminal portion 4822C, and the terminal portion 4822D in the second direction y. The shape of each region 482F is not particularly limited, and may be rectangular or circular, for example. In the illustrated example, each region 482F has a rectangular shape.

As shown in FIGS. 13, 14, and 19 in particular, the second sub-metal layer 483 is formed on the lower surface (the surface on the z2 side in the thickness direction z) of the sub-insulating layer 481. The constituent material of the second sub-metal layer 483 may contain copper (Cu) or an alloy of copper (Cu), for example. The thickness of the second sub-metal layer 483 is not particularly limited, and may be at least 0.035 mm and at most 3.0 mm, for example.

The second sub-metal layer 483 of the first sub-substrate 48A is electrically bonded to the first conductive portion 32A. The second sub-metal layer 483 of the second sub-substrate 48B is electrically bonded to the second conductive portion 32B. The method for electrically bonding a second sub-metal layer 483 to the first conductive portion 32A or the second conductive portion 32B is not particularly limited. The method for electrical bonding may be bonding with a conductive bonding member, laser bonding, ultrasonic bonding, or solid-phase bonding. In the present embodiment, the second sub-metal layer 483 of each of the first sub-substrate 48A and the second sub-substrate 48B is electrically bonded to the first conductive portion 32A or the second conductive portion 32B via a conductive bonding member 49, as shown in FIG. 19. The conductive bonding member 49 may be solder, for example.

As shown in FIGS. 17 to 19, each of the first sub-substrate 48A and the second sub-substrate 48B has a connecting conductive portion 485. The connecting conductive portion 485 electrically connects the region 482E and the second sub-metal layer 483. The specific configuration of the connecting conductive portion 485 is not particularly limited. In the illustrated example, the connecting conductive portion 485 is configured with a conductive member penetrating the sub-insulating layer 481 in the thickness direction z. Such a connecting conductive portion 485 may contain a plating member containing copper (Cu), or solder, for example. In the illustrated example, the connecting conductive portion 485 penetrates through the sub-insulating layer 481 and the region 482E.

As shown in FIG. 17, a wire 73 is connected to the region 482E and the connecting portion 4821D in the first sub-substrate 48A. In the present embodiment, the wire 73 is bonded to the surface metal layers 4829 of the region 482E and the connecting portion 4821D respectively. The constituent material of the wire 73 is not particularly limited, and may contain aluminum (Al) or an alloy of aluminum (Al). As a result, the region 482D is electrically connected to the first conductive portion 32A.

As shown in FIG. 18, a thermistor 17 is connected to the connecting portion 4821C and the connecting portion 4821D in the second sub-substrate 48B. The thermistor 17 is used as a temperature detection sensor. Note that the semiconductor device A1 may include a temperature-sensing diode, for example, in addition to the thermistor 17, or may not include a thermistor 17.

The wires 71, the wires 72, and the wire 73 are not connected to the first main metal layer 32. In other words, the first main metal layer 32 is spaced apart from the wires 71, 72, and 73.

Control terminals 45: The control terminals 45 are used to control the first semiconductor elements 10A and the second semiconductor elements 10B. The control terminals 45 include a plurality of control terminals 46A, 46B, and 46E, and a plurality of control terminals 47A to 47D. The control terminals 46A, 46B, and 46E are used to control the first semiconductor elements 10A, for example. The control terminals 47A to 47D are used to control the second semiconductor elements 10B, for example.

The control terminals 46A, 46B, and 46E are spaced apart from each other in the second direction y. As shown in FIGS. 2, 3, 5, 6, 8, and 17 in particular, the control terminals 46A, 46B, and 46E are supported by the first conductive portion 32A via the first sub-substrate 48A. As shown in FIG. 5, the control terminals 46A, 46B, and 46E are located between the first semiconductor elements 10A and the first, second, and fourth terminals 41, 42, and 44 in the first direction x.

As shown in FIG. 17, the control terminal 46A is disposed on the terminal portion 4822A. The control terminal 46A is a terminal (a gate terminal) for receiving input of a drive signal for the first semiconductor elements 10A. The control terminal 46A receives a drive signal (e.g., gate voltage) for driving the first semiconductor elements 10A.

The control terminal 46B is disposed on the terminal portion 4822B. The control terminal 46B is a terminal (a source sense terminal) for detecting the source signal of the first semiconductor elements 10A. The voltage (the voltage corresponding to the source current) applied to the second obverse-surface electrodes 12 (the source electrodes) of the first semiconductor elements 10A is detected at the control terminal 46B.

The control terminal 46E is disposed on the terminal portion 4822D. The control terminal 46E is a terminal (a drain sense terminal) for detecting the drain signal of the first semiconductor elements 10A. The voltage (the voltage corresponding to the drain current) applied to the reverse-surface electrodes 15 (the drain electrodes) of the first semiconductor elements 10A is detected at the control terminal 46E. The control terminal 46E corresponds to the “first control terminal” in the present disclosure.

The control terminals 47A to 47D are spaced apart from each other in the second direction y. As shown in FIGS. 2, 3, 5, 6, 8, and 18 in particular, the control terminals 47A to 47D are supported by the second conductive portion 32B via the second sub-substrate 48B. As shown in FIG. 5, the control terminals 47A to 47D are located between the second semiconductor elements 10B and the third terminals 43 in the first direction x.

As shown in FIG. 18, the control terminal 47A is disposed on the terminal portion 4822A. The control terminal 47A is a terminal (a gate terminal) for receiving input of a drive signal for the second semiconductor elements 10B. The control terminal 47A receives a drive signal (e.g., gate voltage) for driving the second semiconductor elements 10B.

The control terminal 47B is disposed on the terminal portion 4822B. The control terminal 47B is a terminal (a source sense terminal) for detecting the source signal of the second semiconductor elements 10B. The voltage (the voltage corresponding to the source current) applied to the second obverse-surface electrodes 12 (the source electrodes) of the second semiconductor elements 10B is detected at the control terminal 47B.

The control terminal 47C is disposed on the terminal portion 4822C. The control terminal 47D is disposed on the terminal portion 4822D. The control terminal 47C and the control terminal 47D are electrically connected to the thermistor 17.

As shown in FIGS. 12, 17, and 18, each of the control terminals 45 (the control terminals 46A, 46B, and 46E and the control terminals 47A to 47D) includes a holder 451 and a metal pin 452.

The holder 451 is made of a conductive material. As shown in FIGS. 13 and 14, the holder 451 is bonded to the first sub-metal layer 482 via a conductive bonding member (not illustrated). The holder 451 includes a tubular portion, an upper flange, and a lower flange. The upper flange is connected to the upper end of the tubular portion, and the lower flange is connected to the lower end of the tubular portion. The metal pin 452 is inserted through at least the upper flange and the tubular portion of the holder 451. The holder 451 is covered with the sealing resin 8.

The metal pin 452 is a rod-like member extending in the thickness direction z. The metal pin 452 is pressed into the holder 451 and supported by the holder 451. The metal pin 452 is electrically connected to the first sub-metal layer 482 at least through the holder 451. As shown in FIGS. 1 and 12, the metal pin 452 protrudes from the sealing resin 8 toward the z1 side in the thickness direction z.

First conductive member 5 and second conductive member 6: The first conductive member 5 and the second conductive member 6, together with the first conductive portion 32A and the second conductive portion 32B, form the path of the main circuit current that is switched by the first semiconductor elements 10A and the second semiconductor elements 10B. The first conductive member 5 and the second conductive member 6 are spaced apart from the first obverse surface 301A and the second obverse surface 301B toward the z1 side in the thickness direction z. In plan view, the first conductive member 5 and the second conductive member 6 overlap with the first obverse surface 301A and the second obverse surface 301B. In the present embodiment, each of the first conductive member 5 and the second conductive member 6 is made of a metal plate. The metal may contain copper (Cu) or an alloy of copper (Cu), for example. Specifically, the first conductive member 5 and the second conductive member 6 are metal plates having been bent as needed.

The first conductive member 5 is connected to the second obverse-surface electrodes 12 (the source electrodes) of the first semiconductor elements 10A and the second conductive portion 32B, and electrically connects the second obverse-surface electrodes 12 of the first semiconductor elements 10A and the second conductive portion 32B. The first conductive member 5 forms the path of the main circuit current that is switched by the first semiconductor elements 10A. As shown in FIGS. 7 and 8, the first conductive member 5 includes a main portion 51, a plurality of first bonding portions 52, and a plurality of second bonding portions 53.

The main portion 51 is located between the first semiconductor elements 10A and the second conductive portion 32B in the first direction x, and has the shape of a strip extending in the second direction y in plan view. The main portion 51 overlaps with both the first conductive portion 32A and the second conductive portion 32B in plan view, and is spaced apart from the first obverse surface 301A and the second obverse surface 301B to toward the z1 side in the thickness direction z. As shown in FIG. 16 in particular, the main portion 51 is located on the z2 side in the thickness direction z from a plurality of third path portions 66 and a fourth path portion 67 of the second conductive member 6 described below, and is closer to the first obverse surface 301A and the second obverse surface 301B than the third path portions 66 and the fourth path portion 67.

In the present embodiment, the main portion 51 is parallel to the first obverse surface 301A and the second obverse surface 301B.

As shown in FIG. 8 in particular, the main portion 51 extends in the second direction y to correspond to a region in which the first semiconductor elements 10A are positioned. In the present embodiment, the main portion 51 has a plurality of first openings 514 as shown in FIGS. 7, 8, and 12 in particular. The first openings 514 may be through-holes extending in the thickness direction z (the direction of the plate thickness of the main portion 51), for example. The first openings 514 are spaced apart from each other in the second direction y. The first openings 514 are provided for the respective first semiconductor elements 10A. In the present embodiment, the main portion 51 has four first openings 514, each of which corresponds in position in the second direction y to one of the plurality of (four) first semiconductor elements 10A.

As shown in FIGS. 8 and 12 in particular, the first openings 514 of the present embodiment overlap with the space between the first conductive portion 32A and the second conductive portion 32B in plan view. The first openings 514 are provided to facilitate the flow of a molten resin material between the upper region (on the z1 side in the thickness direction z) and the lower region (on the z2 side in the thickness direction z) around the main portion 51 (the first conductive member 5) when the molten resin material is injected in the process of forming the sealing resin 8.

As shown in FIG. 8 in particular, the first bonding portions 52 and the second bonding portions 53 are connected to the main portion 51, and are arranged to correspond to the first semiconductor elements 10A and the second semiconductor elements 10B. Specifically, the first bonding portions 52 are located on the x1 side in the first direction x from the main portion 51. The second bonding portions 53 are located on the x2 side in the first direction x from the main portion 51. As shown in FIG. 13, each of the first bonding portions 52 is bonded to the second obverse-surface electrode 12 of a first semiconductor element 10A via a conductive bonding member 59. Each of the second bonding portions 53 is bonded to the second conductive portion 32B via a conductive bonding member 59. The material of the conductive bonding members 59 is not particularly limited, and may be solder, metal paste, or sintered metal. In the present embodiment, each of the first bonding portions 52 includes two regions spaced apart from each other in the second direction y.

The second conductive member 6 electrically connects the second obverse-surface electrodes 12 (the source electrodes) of the second semiconductor elements 10B to the first terminal 41 and the second terminal 42. The second conductive member 6 is integrally formed with the first terminal 41 and the second terminal 42. The second conductive member 6 forms the path of the main circuit current that is switched by the second semiconductor elements 10B. As shown in FIGS. 2, and 5 to 7, the second conductive member 6 includes a plurality of third bonding portions 61, a first path portion 64, a second path portion 65, a plurality of third path portions 66, and a fourth path portion 67.

The third bonding portions 61 are bonded to the respective second semiconductor elements 10B. Each of the third bonding portions 61 is bonded to the second obverse-surface electrode 12 of a second semiconductor element 10B via a conductive bonding member 69. The material of the conductive bonding members 69 is not particularly limited, and may be solder, metal paste, or sintered metal. In the present embodiment, each of the third bonding portions 61 includes two flat sections 611 and two first inclined sections 612.

The two flat sections 611 are aligned in the second direction y. The two flat sections 611 are spaced apart from each other in the second direction y. The shape of each flat section 611 is not particularly limited, and is rectangular in the illustrated example. The two flat sections are bonded to the second obverse-surface electrode 12 on the respective sides in the second direction y.

The two first inclined sections 612 are connected to the outer ends of the respective two flat sections 611 in the second direction y. In other words, the first inclined section 612 on the y1 side in the second direction y is connected to the y1-side end of the flat section 611 located on the y1 side in the second direction y. The first inclined section 612 on the y2 side in the second direction y is connected to the y2-side end of the flat section 611 located on the y2 side in the second direction y. Each of the first inclined sections 612 is inclined toward the z1 side in the thickness direction z with an increasing distance from the flat section 611 in the second direction y.

The first path portion 64 is located between the third bonding portions 61 and the first terminal 41. In the illustrated example, the first path portion 64 is connected to the first terminal 41 via a first ramp portion 602. The first path portion 64 overlaps with the first conductive portion 32A in plan view. The first path portion 64 generally extends in the first direction x.

The first path portion 64 includes a first band-shaped section 641 and a first extended section 643. The first band-shaped section 641 is located on the x2 side in the first direction x from the first terminal 41, and is substantially parallel to the first obverse surface 301A. The first band-shaped section 641 generally extends in the first direction x.

The first extended section 643 extends from the y1-side end of the first band-shaped section 641 in the second direction y toward the z2 side in the thickness direction z. The first extended section 643 is spaced apart from the first conductive portion 32A. In the illustrated example, the first extended section 643 is shaped along the thickness direction z, and has a rectangular shape elongated in the first direction x. Note that the first path portion 64 may be configured without the first extended section 643.

The second path portion 65 is located between the third bonding portions 61 and the second terminal 42. In the illustrated example, the second path portion 65 is connected to the second terminal 42 via a second ramp portion 603. The second path portion 65 overlaps with the first conductive portion 32A in plan view. The second path portion 65 generally extends in the first direction x.

The second path portion 65 includes a second band-shaped section 651 and a second extended section 653. The second band-shaped section 651 is located on the x2 side in the first direction x from the second terminal 42, and is substantially parallel to the first obverse surface 301A. The second band-shaped section 651 generally extends in the first direction x.

The second extended section 653 extends from the y2-side end of the second band-shaped section 651 in the second direction y toward the z2 side in the thickness direction z. The second extended section 653 is spaced apart from the first conductive portion 32A. In the illustrated example, the second extended section 653 is shaped along the thickness direction z, and has a rectangular shape elongated in the first direction x. Note that the second path portion 65 may be configured without the second extended section 653.

The third path portions 66 are individually connected to the third bonding portions 61. The third path portions 66 extend in the first direction x, and are spaced apart from each other in the second direction y. The number of third path portions 66 is not particularly limited. In the illustrated example, five third path portions 66 are provided. Each of the third path portions 66 is located either between two of the second semiconductor elements 10B in the second direction y or outside the second semiconductor elements 10B in the second direction y.

In the present embodiment, each of the third bonding portions 61 is located between two third path portions 66 adjacent in the second direction y. Each of the third bonding portions 61 has two first inclined sections 612, one on the y1 side in the second direction y and the other on the y2 side in the second direction y. The first inclined section 612 on the y1 side is connected to one of the two adjacent third path portions 66 that is located on the y1 side in the second direction y. The first inclined section 612 on the y2 side is connected to one of the two adjacent third path portions 66 that is located on the y2 side in the second direction y.

The fourth path portion 67 is connected to the ends of the respective third path portions 66 on the x1 side in the first direction x. The fourth path portion 67 extends in the second direction y. The fourth path portion 67 is connected to the x2-side end of the first band-shaped section 641 of the first path portion 64 in the first direction x, and to the x2-side end of the second band-shaped section 651 of the second path portion 65 in the first direction x. In the illustrated example, the fourth path portion 67 is connected to the first path portion 64 at the end on the y1 side in the second direction y and to the second path portion 65 at the end on the y2 side in the second direction y.

Scaling resin 8: The sealing resin 8 covers the first semiconductor elements 10A, the second semiconductor elements 10B, the main substrate 3 (except for the reverse surface 302), a part of each of the first terminal 41, the second terminal 42, the third terminals 43, and the fourth terminal 44, a part of each of the control terminals 45, the first sub-substrate 48A and the second sub-substrate 48B, the first conductive member 5, the second conductive member 6, and the wires 71 to 73. The sealing resin 8 may be made of a black epoxy resin, for example. The scaling resin 8 may be formed by molding, for example. The size of the sealing resin 8 is not particularly limited. For example, the sealing resin 8 may have a dimension of about 35 mm to 60 mm in the first direction x, a dimension of about 35 mm to 50 mm in the second direction y, and a dimension of about 4 mm to 15 mm in the thickness direction z. These dimensions are measured at the largest portions in the respective directions. The sealing resin 8 has a resin obverse surface 81, a resin reverse surface 82, and resin side surfaces 831 to 834.

As shown in FIGS. 10, 12, and 15 in particular, the resin obverse surface 81 and the resin reverse surface 82 are spaced apart from each other in the thickness direction z. The resin obverse surface 81 faces the z1 side in the thickness direction z, and the resin reverse surface 82 faces the z2 side in the thickness direction z. The control terminals 45 (the control terminals 46A, 46B, and 46E and the control terminals 47A to 47D) protrude from the resin obverse surface 81. As shown in FIG. 11, the resin reverse surface 82 has the shape of a frame surrounding the reverse surface 302 (the lower surface of the second main metal layer 33) of the main substrate 3 in plan view. The reverse surface 302 of the main substrate 3 is exposed from the resin reverse surface 82, and is flush with the resin reverse surface 82, for example.

The resin side surfaces 831 to 834 are connected to both the resin obverse surface 81 and the resin reverse surface 82, and are located between the resin obverse surface 81 and the resin reverse surface 82 in the thickness direction z. As shown in FIG. 4 in particular, the resin side surface 831 and the resin side surface 832 are spaced apart from each other in the first direction x. The resin side surface 831 faces the x2 side in the first direction x, and the resin side surface 832 faces the x1 side in the first direction x. The two third terminals 43 protrude from the resin side surface 831, and the first terminal 41, the second terminal 42, and the fourth terminal 44 protrude from the resin side surface 832. As shown in FIG. 4 in particular, the resin side surface 833 and the resin side surface 834 are spaced apart from each other in the second direction y. The resin side surface 833 faces the y2 side in the second direction y, and the resin side surface 834 faces the y1 side in the second direction y.

As shown in FIG. 4, the resin side surface 832 has a plurality of recesses 832a. Each of the recesses 832a is recessed in the first direction x in plan view. The recesses 832a include one formed between the first terminal 41 and the fourth terminal 44, and one formed between the second terminal 42 and the fourth terminal 44 in plan view. The recesses 832a are provided to increase the creepage distance along the resin side surface 832 between the first terminal 41 and the fourth terminal 44, and also to increase the creepage distance along the resin side surface 832 between the second terminal 42 and the fourth terminal 44.

Next, a vehicle B1 provided with the semiconductor device A1 will be described with reference to FIG. 20. The vehicle B1 is an electric vehicle (EV), for example.

As shown in FIG. 20, the vehicle B1 includes an on-board charger 91, a storage battery 92, and a drive system 93. The on-board charger 91 receives power wirelessly from an outdoor power supply facility (not shown). Alternatively, the on-board charger 91 may receive power from the power supply facility by wire. The on-board charger 91 includes a step-up DC-DC converter. The voltage of the power supplied to the on-board charger 91 is boosted by the converter and then supplied to the storage battery 92. The voltage is boosted to 600 V, for example.

The drive system 93 drives the vehicle B1. The drive system 93 includes an inverter 931 and a drive source 932. The semiconductor device A1 constitutes a part of the inverter 931. The power stored in the storage battery 92 is supplied to the inverter 931. The power supplied from the storage battery 92 to the inverter 931 is DC power. In an example different from FIG. 20, the power system may additionally include a step-up DC-DC converter between the storage battery 92 and the inverter 931. The inverter 931 converts the DC power into AC power. The inverter 931 that includes the semiconductor device A1 is electrically connected to the drive source 932.

The drive source 932 include an AC motor and a transmission. The AC power converted by the inverter 931 is supplied to the drive source 932 to rotate the AC motor. The rotation of the AC motor is transmitted to the transmission. The transmission appropriately reduces the rotational speed transmitted from the AC motor and rotates the drive shaft of the vehicle B1. This drives the vehicle B1. Driving the vehicle B1 requires freely regulating the rotational speed of the AC motor based on the amount of accelerator pedal operation and other information. The semiconductor device A1 in the inverter 931 is necessary for outputting the AC power at a frequency appropriately adjusted to correspond to the required rotational speed of the AC motor. The following describes advantages of the semiconductor device A1.

As shown in FIG. 19, the region 482E of the first sub-substrate 48A is electrically connected to the first conductive portion 32A via the connecting conductive portion 485 and the second sub-metal layer 483. Thus, in order to electrically connect the control terminal 46E and the first conductive portion 32A shown in FIG. 17, it is sufficient to electrically connect the region 482D and the region 482E, and it is not necessary to connect other conductive members to the first conductive portion 32A. This makes it possible to set a greater variety of conductive paths to the main substrate 3.

The first sub-metal layer 482 has the surface metal layer 4829. The wires 71, 72, and 73 are connected to the surface metal layer 4829. This makes it possible to avoid the Kirkendall void phenomenon occurring at the portion where the wires 71, 72, and 73 are connected to the base layer 4820. When the wires 71, 72, and 73 contain aluminum (Al) and the base layer 4820 contains copper (Cu), the Kirkendall void phenomenon can be more reliably prevented by providing a surface metal layer 4829 containing nickel (Ni).

In addition, there is no need to connect a wire or the like to the first conductive portion 32A for the purpose of detecting a potential in the first conductive portion 32A with use of the control terminal 46E. This eliminates the need of providing the first conductive portion 32A with a metal layer or the like to prevent the Kirkendall void phenomenon. This is desirable for reducing the cost of the semiconductor device A1.

As shown in FIGS. 17 and 18, the first sub-substrate 48A and the second sub-substrate 48B have common configurations. As shown in FIG. 17, the first sub-substrate 48A includes the region 482E and the connecting portion 4821D connected by the wire 73, thus allowing the detection of a potential in the first conductive portion 32A with use of the control terminal 46E. On the other hand, as shown in FIG. 18, the thermistor 17 can be connected to the connecting portion 4821C and the connecting portion 4821D to allow temperature monitoring using the control terminal 47C and the control terminal 47D. As described above, two sub-substrates having different functions, namely the first sub-substrate 48A and the second sub-substrate 48B, can be realized with a single type of sub-substrate, which is advantageous for reducing the cost of semiconductor device A1.

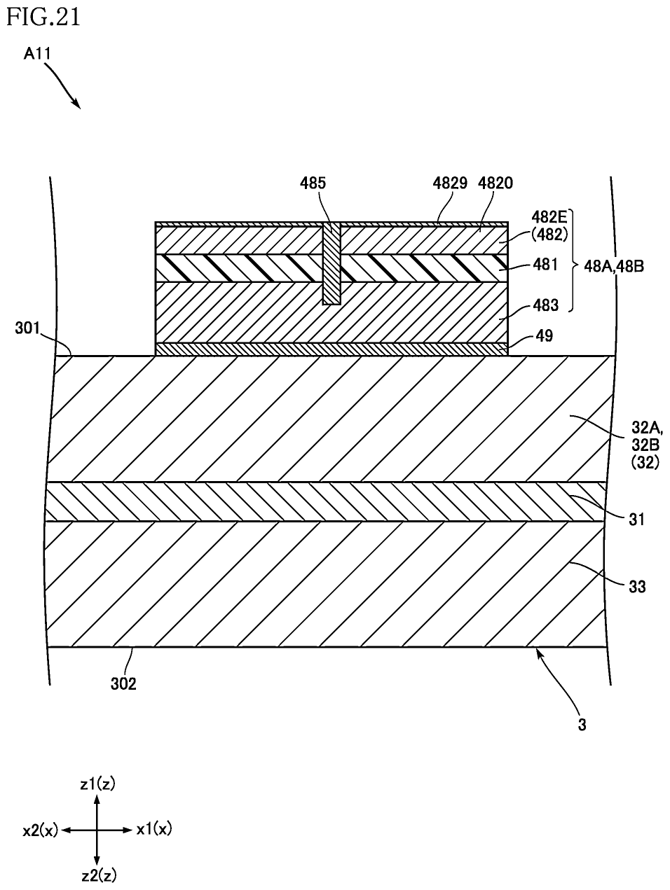

FIGS. 21 to 33 show variations and other embodiments of the present disclosure. In these figures, elements that are identical or similar to those described in the above embodiment are indicated by the same reference numerals. In addition, the configurations of the elements in each variation and each embodiment can be combined as appropriate as long as the combination does not cause technical contradictions. Unless otherwise specified, the following variations and embodiments are described with matters common to the first sub-substrate 48A and the second sub-substrate 48B.

First variation of the first embodiment: FIG. 21 shows a first variation of the semiconductor device A1. A semiconductor device A11 of the present variation is different from the example described above in the configuration of the connecting conductive portion 485. In the present variation, the connecting conductive portion 485 penetrates through the first sub-metal layer 482 (the region 482E) and the sub-insulating layer 481, and enters a part of the second sub-metal layer 483. The connecting conductive portion 485 as described above is formed, for example, when performing a removal process of the first sub-metal layer 482 and the sub-insulating layer 481, by continuing the removal process of the first sub-metal layer 482 from the z1 side to the z2 side in the thickness direction z to reach the second sub-metal layer 483 and further removing a part of the second sub-metal layer 483 beyond the first sub-metal layer 482 and the sub-insulating layer 481. The removal process may be a machining process or a chemical process such as etching.

The present variation also makes it possible to set a greater variety of conductive paths to the main substrate 3. In addition, the removal process for forming the connecting conductive portion 485 includes forming a through-hole that completely penetrates the sub-insulating layer 481. This allows the connecting conductive portion 485 to be electrically connected to the second sub-metal layer 483 more reliably.

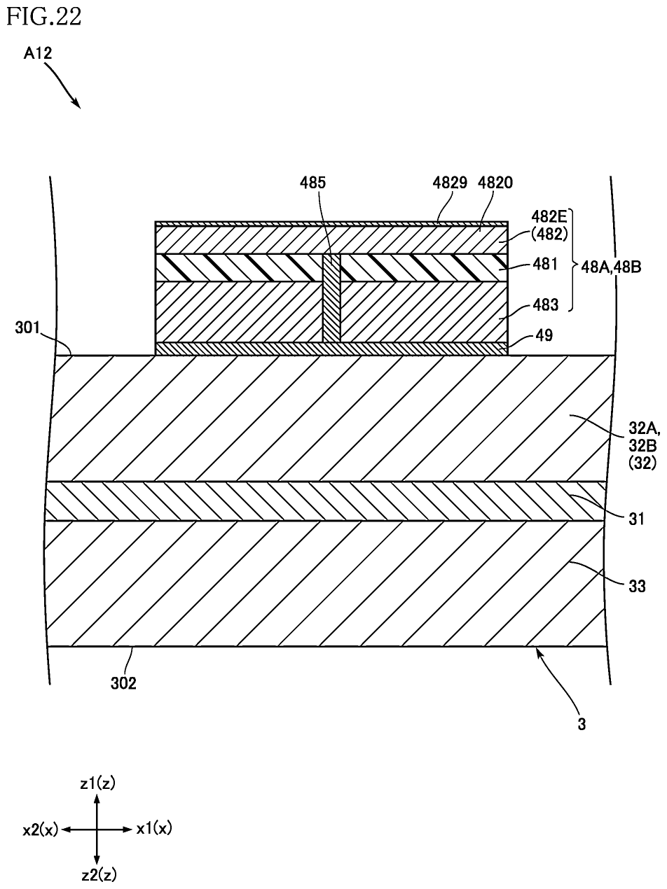

Second variation of the first embodiment: FIG. 22 shows a second variation of the semiconductor device A1. In the semiconductor device A12 of the present variation, the connecting conductive portion 485 penetrates through the second sub-metal layer 483 and the sub-insulating layer 481, and is in contact with the first sub-metal layer 482 (the region 482E).

The present variation also makes it possible to set a greater variety of conductive paths to the main substrate 3. As can be understood from the present variation, the connecting conductive portion 485 may be configured to penetrate through the first sub-metal layer 482, or to penetrate through the second sub-metal layer 483.

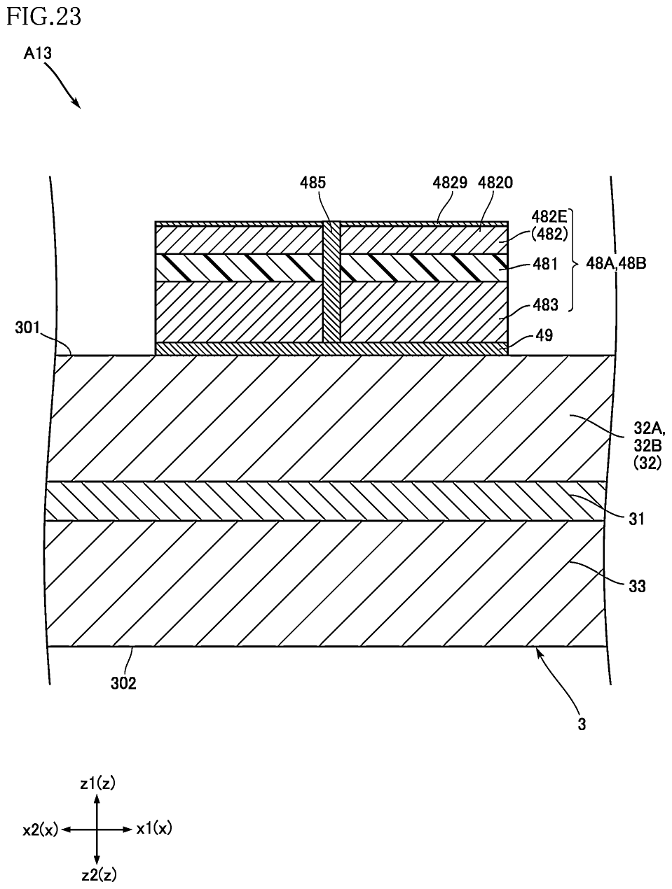

Third variation of the first embodiment: FIG. 23 shows a third variation of the semiconductor device A1. In the semiconductor device A13 of the present variation, the connecting conductive portion 485 penetrates through the first sub-metal layer 482 (the region 482E), the sub-insulating layer 481, and the second sub-metal layer 483.

The present variation also makes it possible to set a greater variety of conductive paths to the main substrate 3. As can be understood from the present variation, the connecting conductive portion 485 may be configured to penetrate through the entirety of the first sub-substrate 48A or the second sub-substrate 48B in the thickness direction z.

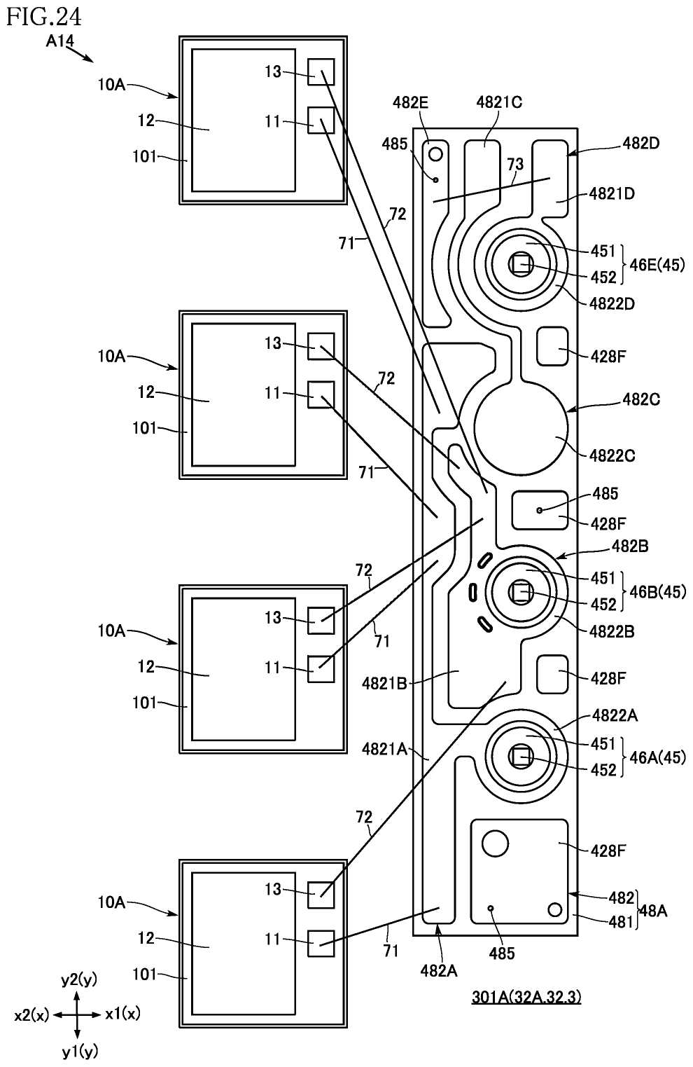

Fourth variation of the first embodiment: FIG. 24 shows a fourth variation of the semiconductor device A1. In a semiconductor device A14 of the present variation, the first sub-substrate 48A has a plurality of connecting conductive portions 485. In the illustrated example, the first sub-substrate 48A has three connecting conductive portions 485. One connecting conductive portion 485 electrically connects the region 482E and the second sub-metal layer 483. Two connecting conductive portions 485 electrically connect two regions 482F and the second sub-metal layer 483. One of the two regions 482F is located farthest of the plurality of regions 482F on the y1 side in the second direction y, and the other is the third region 482F counted from the y1 side in the second direction y among the plurality of regions 482.

The present variation also makes it possible to set a greater variety of conductive paths to the main substrate 3. As can be understood from the present variation, the number of connecting conductive portions 485 is not particularly limited. The regions 482F do not have the wires 71 to 73 or the control terminals 45 connected thereto. Thus, the semiconductor device A14 still achieves its electrical function even when the regions 482F are electrically connected to the second sub-metal layer 483 by the connecting conductive portions 485.

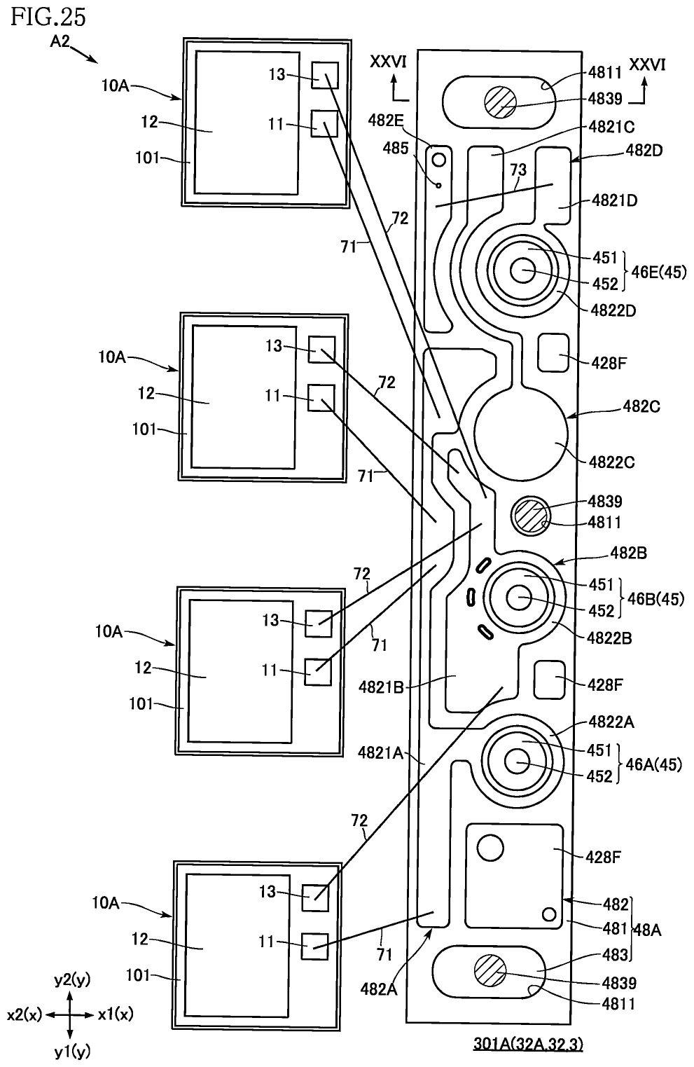

Second embodiment: FIGS. 25 and 26 show a semiconductor device according to a second embodiment of the present disclosure. A semiconductor device A2 of the present embodiment is different from the embodiment described above in the method of electrically bonding the second sub-metal layer 483 of the first sub-substrate 48A and the first conductive portion 32A. In the present embodiment, laser bonding is used to electrically bond the second sub-metal layer 483 of the first sub-substrate 48A and the first conductive portion 32A.

The sub-insulating layer 481 has an opening 4811. The opening 4811 penetrates through the sub-insulating layer 481 in the thickness direction z, and allows the second sub-metal layer 483 to be exposed to the z1 side in the thickness direction z. The second sub-metal layer 483 has a bonding portion 4839 formed therein.

The bonding portion 4839 may be formed by placing the first sub-substrate 48A on the first conductive portion 32A, and in that state, irradiating a part of the second sub-metal layer 483 exposed from the opening 4811 with laser light. The irradiation of laser light causes a part of the second sub-metal layer 483 and a part of the first conductive portion 32A to melt together to form the bonding portion 4839 as shown in the figures.

In the illustrated example, the sub-insulating layer 481 has three openings 4811. A control terminal support 48 (the second sub-metal layer 483) has three bonding portions 4839. The three openings 4811 and the three bonding portions 4839 are spaced apart from each other in the second direction y. Two openings 4811 and two bonding portions 4839 are formed on the respective ends of the first sub-substrate 48A in the second direction y. One opening 4811 and one bonding portion 4839 are formed between the terminal portion 4822B and the terminal portion 4822C in the second direction y, substantially at the center of the first sub-substrate 48A in the second direction y.

The present embodiment also makes it possible to set a greater variety of conductive paths to the main substrate 3. In addition, the laser bonding can reduce the amount of heat applied to the first sub-substrate 48A and the first conductive portion 32A when the first sub-substrate 48A is bonded to the first conductive portion 32A. This is suitable for suppressing unintended thermal deformation of the first sub-substrate 48A, etc.

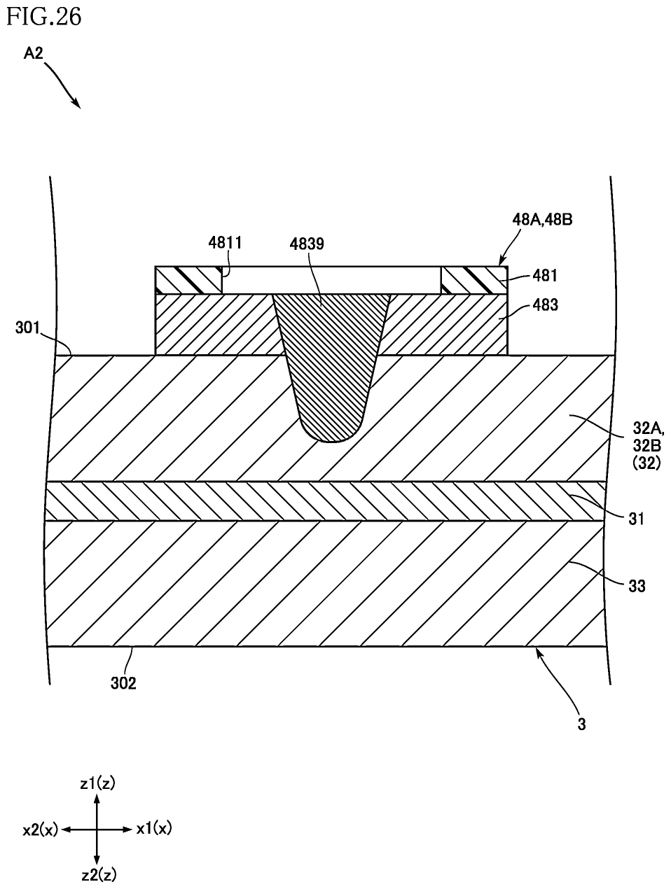

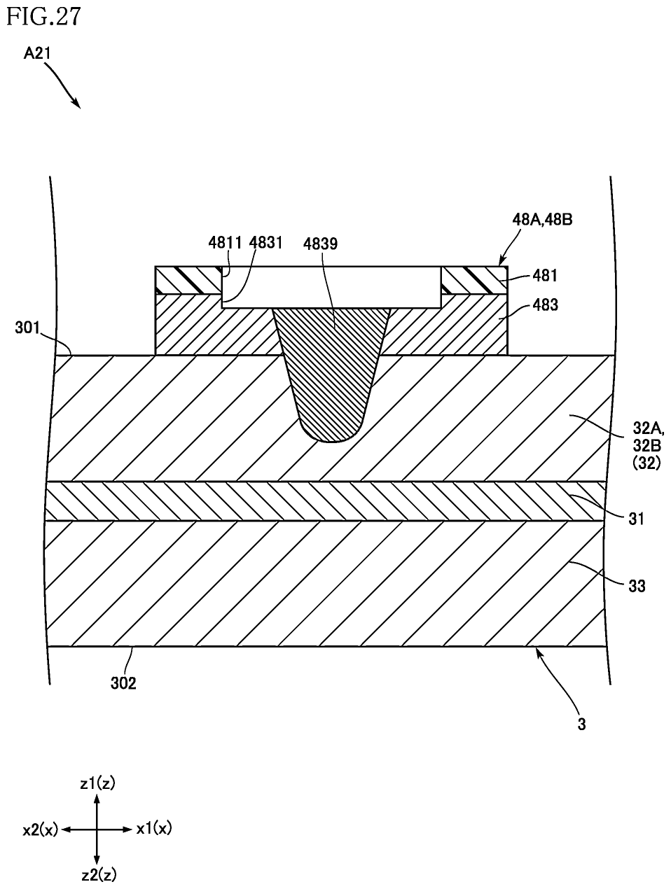

First variation of the second embodiment: FIG. 27 shows a first variation of the semiconductor device A2. In a semiconductor device A21 of the present variation, the second sub-metal layer 483 is formed with a recess 4831.

For example, the recess 4831 is formed by penetrating the sub-insulating layer 481 in a removal process for forming an opening 4811 and then removing a part of the second sub-metal layer 483. The bottom of the recess 4831 is irradiated with laser light to form a bonding portion 4839.

The present variation also makes it possible to set a greater variety of conductive paths to the main substrate 3. In addition, the recess 4831 formed in the present variation makes it possible to more reliably form an opening 4811 that penetrates through the sub-insulating layer 481. This can avoid insufficient formation of a bonding portion 4839 as a result of a part of the sub-insulating layer 481 unintentionally remaining in the laser bonding process for forming the bonding portion 4839.

Second variation of the second embodiment: FIG. 28 shows a second variation of the semiconductor device A2. In a semiconductor device A22 of the present variation, the first sub-metal layer 482 has an opening 4825.

The opening 4825 penetrates through the first sub-metal layer 482 in the thickness direction z. The opening 4825 substantially coincides with an opening 4811 as viewed in the thickness direction z.

The present variation also makes it possible to set a greater variety of conductive paths to the main substrate 3. As can be understood from the present variation, in the laser bonding for forming a bonding portion 4839, the first sub-metal layer 482 can be irradiated with laser light through the opening 4825 and the opening 4811.

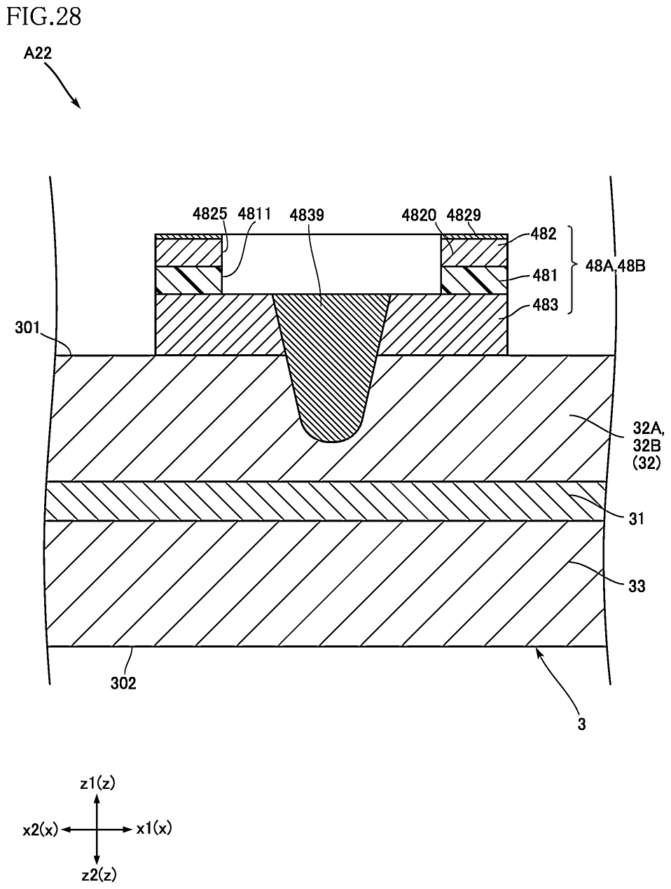

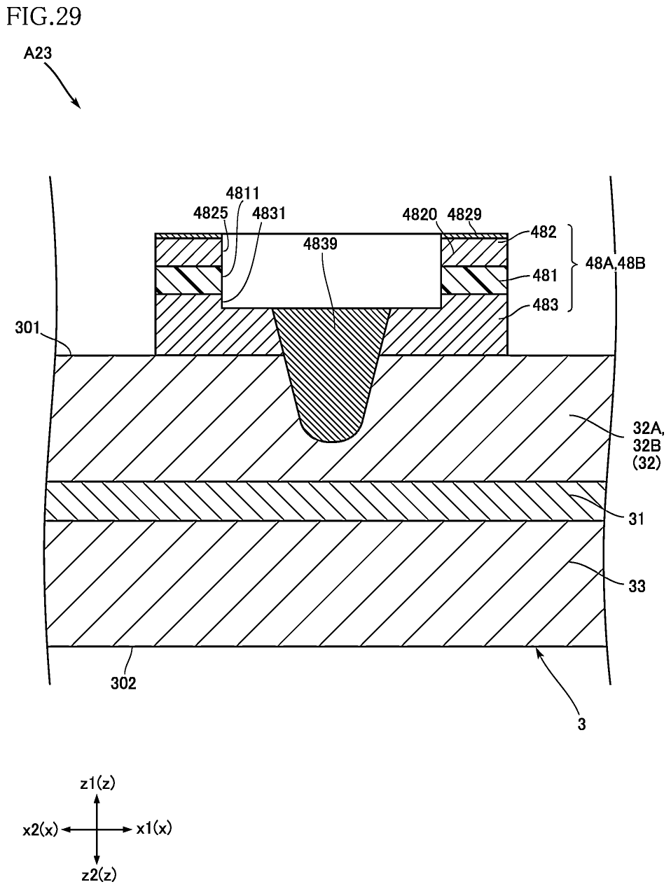

Third variation of the second embodiment: FIG. 29 shows a third variation of the semiconductor device A2. In a semiconductor device A23 of the present variation, the sub-insulating layer 481 has an opening 4811, the first sub-metal layer 482 has an opening 4825, and the second sub-metal layer 483 has a recess 4831.

The present variation also makes it possible to set a greater variety of conductive paths to the main substrate 3. Since the recess 4831 is formed, the part of the second sub-metal layer 483 that is irradiated with laser light in the laser bonding for forming a bonding portion 4839 is farther away from the first sub-metal layer 482 to the z2 side in the thickness direction z. This can prevent the heat generated in the laser bonding from reaching the first sub-metal layer 482.

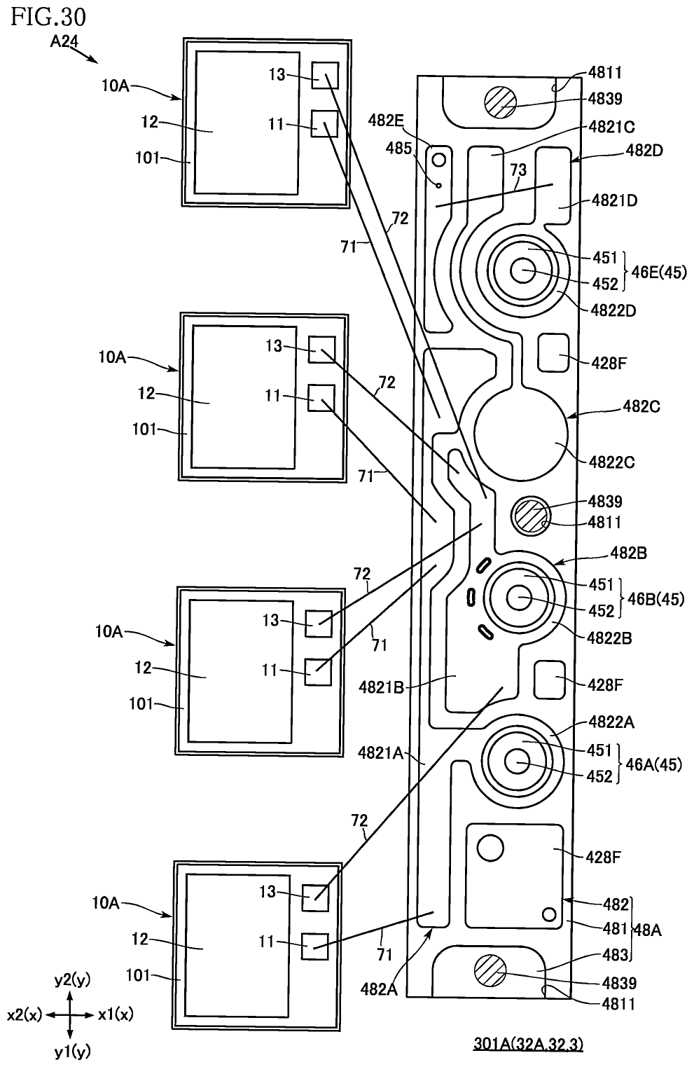

Fourth variation of the second embodiment: FIG. 30 shows a fourth variation of the semiconductor device A2. A semiconductor device A24 in the present variation is different from above examples in the configuration of the two openings 4811 formed on the respective ends of the first sub-substrate 48A in the second direction y. In the present variation, the two openings 4811 formed on the respective ends of the first sub-substrate 48A in the second direction y are connected to the respective ends of the first sub-substrate 48A in the second direction y. In other words, these openings 4811 are not closed as viewed in the thickness direction z, and are open to the outside of the sub-insulating layer 481.

The present variation also makes it possible to set a greater variety of conductive paths to the main substrate 3. As can be understood from the present variation, the shape and arrangement of each opening 4811 are not particularly limited. According to the present variation, the first sub-substrate 48A can be downsized in the second direction y as compared to that in the semiconductor device A2.

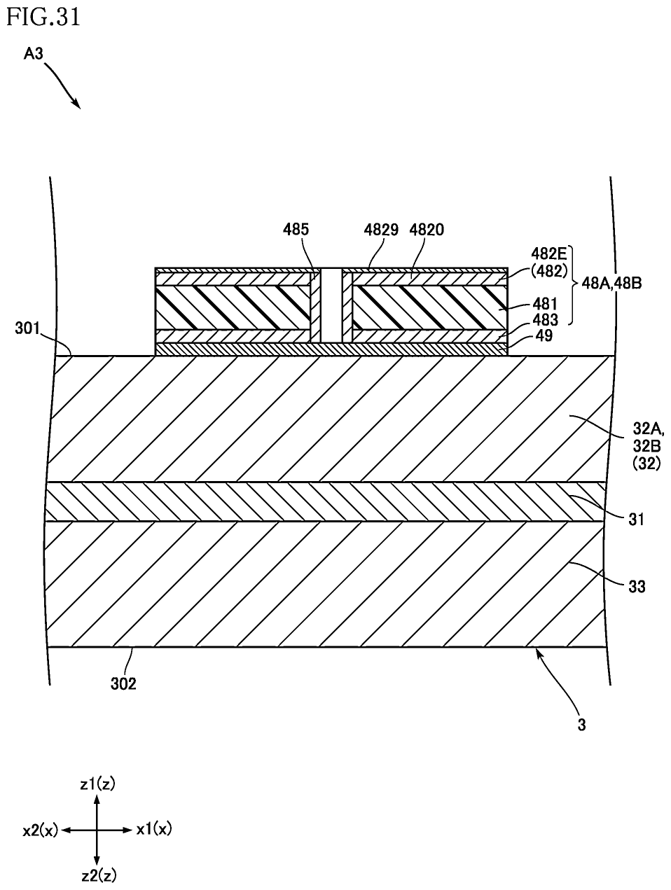

Third embodiment: FIG. 31 shows a semiconductor device according to a third embodiment of the present disclosure. A semiconductor device A3 of the present embodiment is different from those in the above embodiments in the configurations of the first sub-substrate 48A and the second sub-substrate 48B.

In the present embodiment, each of the first sub-substrate 48A and the second sub-substrate 48B is composed of a glass epoxy resin substrate. The sub-insulating layer 481 is made of glass epoxy resin. The first sub-metal layer 482 and the second sub-metal layer 483 may be metal plating layers formed on the respective sides of the sub-insulating layer 481, and may contain copper (Cu). The shape of the first sub-metal layer 482 as viewed in the thickness direction z may be the same as that of the first sub-metal layer 482 of the semiconductor device A1, for example. The second sub-metal layer 483 is electrically bonded to the first conductive portion 32A or the second conductive portion 32B with a conductive bonding member 49, for example.

The connecting conductive portion 485 of the present embodiment may have a configuration called “through-hole conductive portion”. A through-hole is formed through the sub-insulating layer 481, the first sub-metal layer 482, and the second sub-metal layer 483, and the connecting conductive portion 485 is composed of a metal plating layer formed on the inner surface of the through-hole.

The present embodiment also makes it possible to set a greater variety of conductive paths to the main substrate 3. As can be understood from the present embodiment, the specific configuration of each of the first sub-substrate 48A and the second sub-substrate 48B is not particularly limited. The first sub-substrate 48A and the second sub-substrate 48B, which are composed of glass epoxy resin substrates, are suitable for forming the first sub-metal layer 482 to have a fine shape.

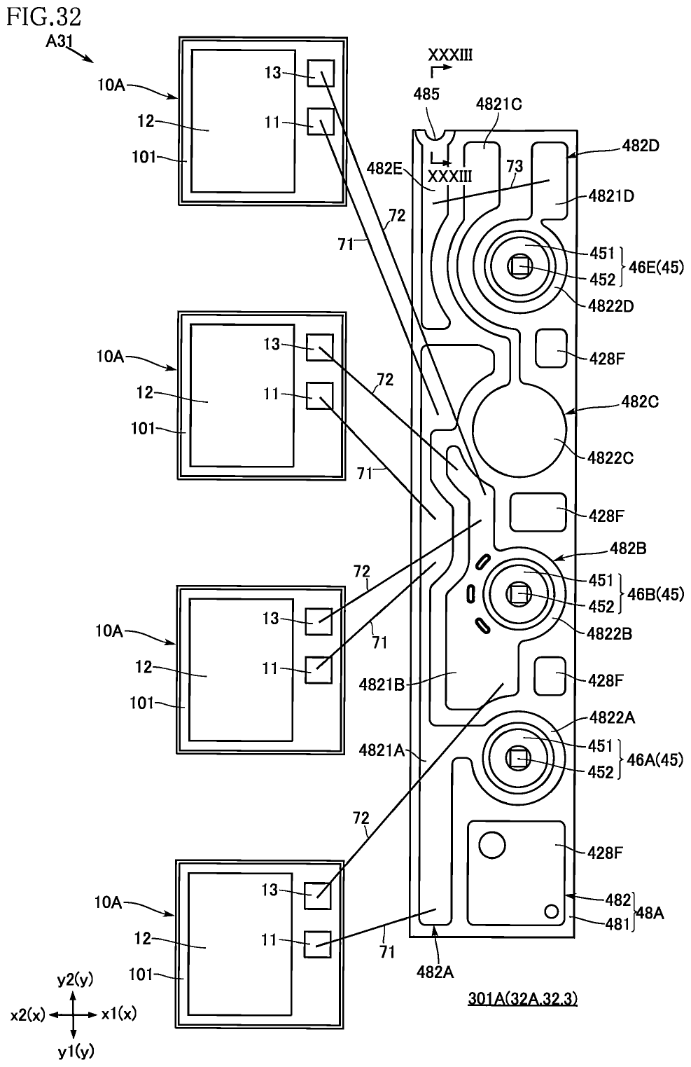

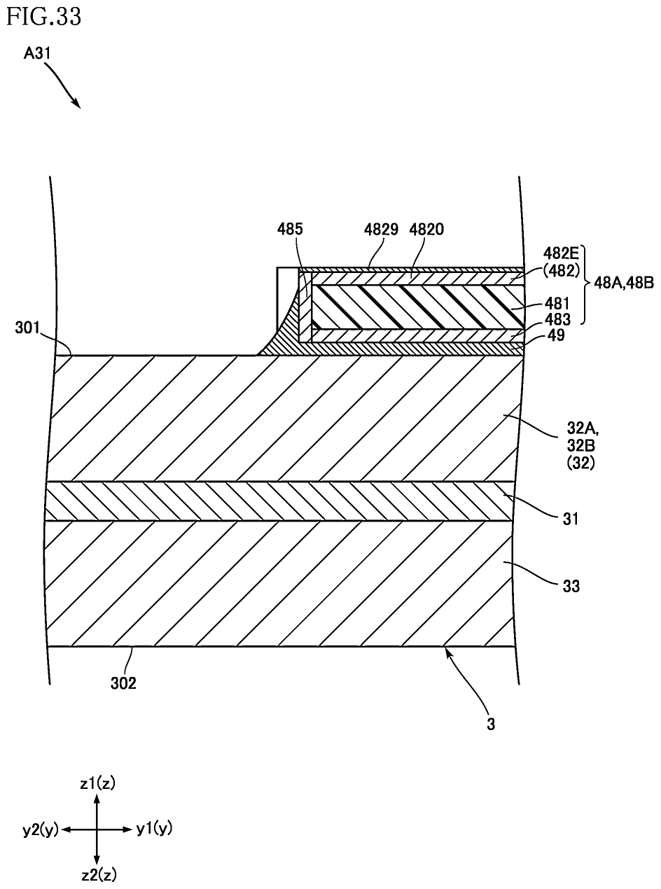

First variation of the third embodiment: FIGS. 32 and 33 show a first variation of the semiconductor device A3. A semiconductor device A31 of the present variation is different from those in the embodiments described above in the configuration of the connecting conductive portion 485.

In the present variation, a recessed groove that extends in the thickness direction z is formed at the end of the sub-insulating layer 481 on the y2 side in the second direction y. The connecting conductive portion 485 is formed to cover the groove, and electrically connects the first sub-metal layer 482 and the second sub-metal layer 483.

The present variation also makes it possible to set a greater variety of conductive paths to the main substrate 3. As can be understood from the present variation, the specific configuration of the connecting conductive portion 485 is not particularly limited. According to the present variation, the conductive bonding member 49 is expected to adhere along the connecting conductive portion 485, as shown in FIG. 33. This is suitable for increasing the bonding strength between the first sub-substrate 48A and the first conductive portion 32A.

The semiconductor device and the vehicle according to the present disclosure are not limited to the embodiments described above. Various design changes can be made to the specific configurations of the elements of the semiconductor device and the vehicle according to the present disclosure.

### Clause 1A.

A semiconductor device comprising:
a main substrate including a first main metal layer;
a first semiconductor element supported by the main substrate;
a first sub-substrate supported by the main substrate; and
a sealing resin covering the first semiconductor element,
wherein the first sub-substrate includes a sub-insulating layer, and a first sub-metal layer and a second sub-metal layer that flank the sub-insulating layer in a thickness direction,
the second sub-metal layer is electrically bonded to the first main metal layer,
the first sub-metal layer includes a first region, and
the first sub-substrate further includes a connecting conductive portion that electrically connects the first region and the second sub-metal layer.

### Clause 2A.

The semiconductor device according to clause 1A, wherein the first semiconductor element is electrically bonded to the first main metal layer.

### Clause 3A.

The semiconductor device according to clause 1A or 2A, further comprising a first control terminal that is electrically connected to the first region and protrudes from the sealing resin.

### Clause 4A.

The semiconductor device according to clause 3A, wherein the first sub-metal layer further includes a second region spaced apart from the first region.

### Clause 5A.

The semiconductor device according to clause 4A, wherein the first control terminal is supported by the second region.

### Clause 6A.

The semiconductor device according to clause 5A, further comprising a first wire connected to the first region and the second region.

### Clause 7A.

The semiconductor device according to clause 6A, wherein the first sub-metal layer further includes a third region that is spaced apart from the first region and the second region and located between the first region and the second region.

### Clause 8A.

The semiconductor device according to clause 6A or 7A, wherein the first sub-metal layer includes a base layer and a surface metal layer.

### Clause 9A.

The semiconductor device according to clause 8A, wherein the base layer includes Cu.

### Clause 10A.

The semiconductor device according to clause 9A, wherein the surface metal layer contains Ni.

### Clause 11A.

The semiconductor device according to clause 10A, wherein the first sub-metal layer contains Cu.

### Clause 12A.

The semiconductor device according to clause 11A, wherein the first wire contains Al.

### Clause 13A.

The semiconductor device according to any of clauses 1A to 12A, wherein the second sub-metal layer is electrically bonded to the first main metal layer by a conductive bonding member.

### Clause 14A.

The semiconductor device according to any of clauses 1A to 12A, wherein the second sub-metal layer is electrically bonded to the first main metal layer by laser bonding.

### Clause 15A.

The semiconductor device according to clause 14A, wherein the second sub-metal layer has a bonding portion formed by laser bonding, and
the second sub-metal layer has an opening surrounding the bonding portion as viewed in the thickness direction.

### Clause 16A.

The semiconductor device according to any of clauses 1A to 15A, wherein the sub-insulating layer contains ceramic.

### Clause 17A.

The semiconductor device according to any of clauses 1A to 15A, wherein the sub-insulating layer contains glass epoxy resin.

### Clause 18A.

A vehicle comprising:
a drive source; and
the semiconductor device according to any of clauses 1A to 17A,
wherein the semiconductor device is electrically connected to the drive source.

The following describes fourth to sixth embodiments according to the present disclosure, with reference to FIGS. 34 to 67. FIGS. 34 to 55 show a semiconductor device according to the fourth embodiment of the present disclosure. A semiconductor device A1 according to the present embodiment includes a plurality of first semiconductor elements 10A, a plurality of second semiconductor elements 10B, a thermistor 17, a support substrate 3, a first terminal 41, a second terminal 42, a plurality of third terminals 43, a fourth terminal 44, a plurality of control terminals 45, a control terminal support 48, a third conductive component 38, wires 71 to 74, a first conductive member 5, a second conductive member 6, and a sealing resin 8.

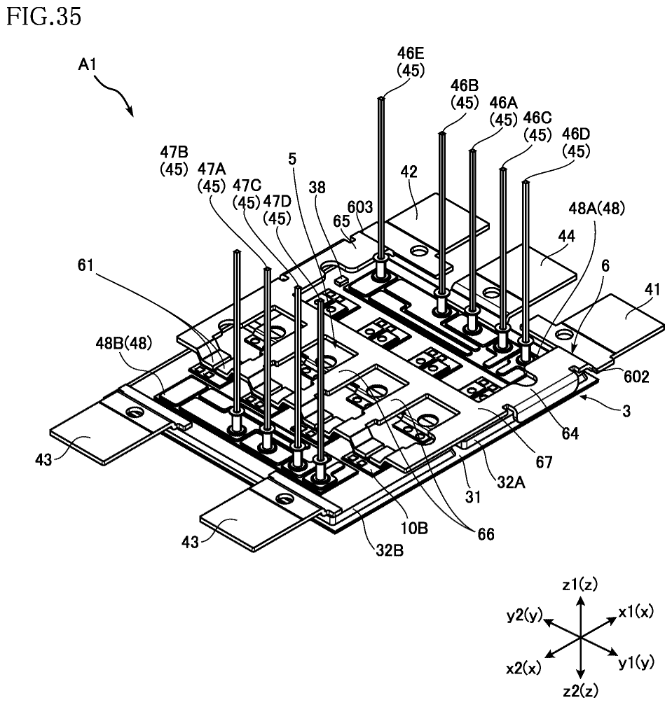

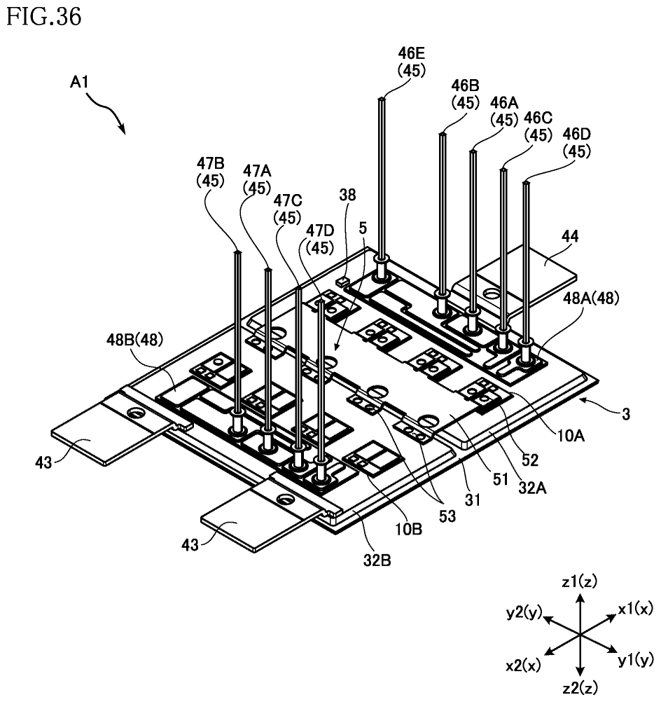

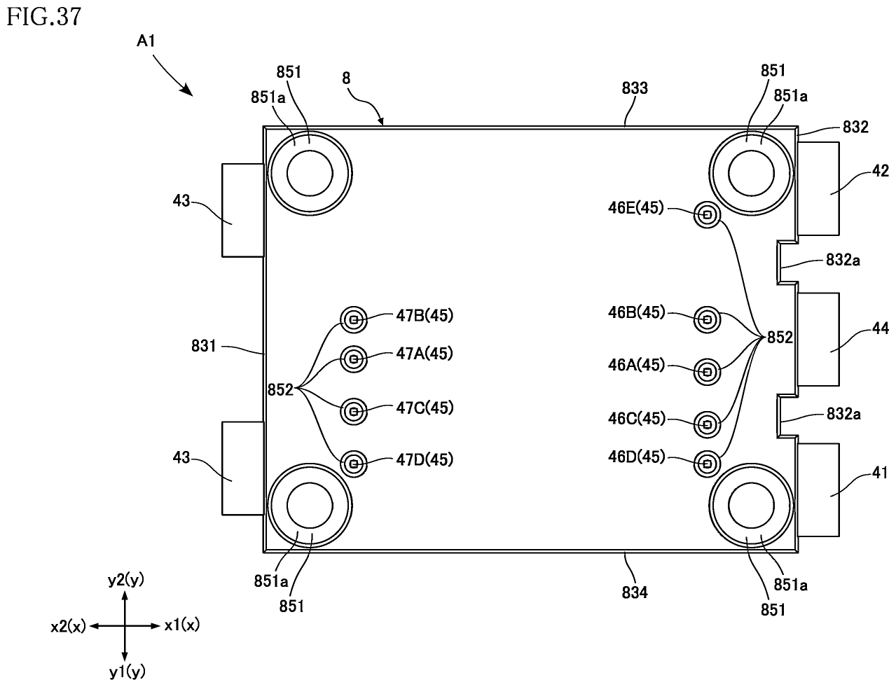

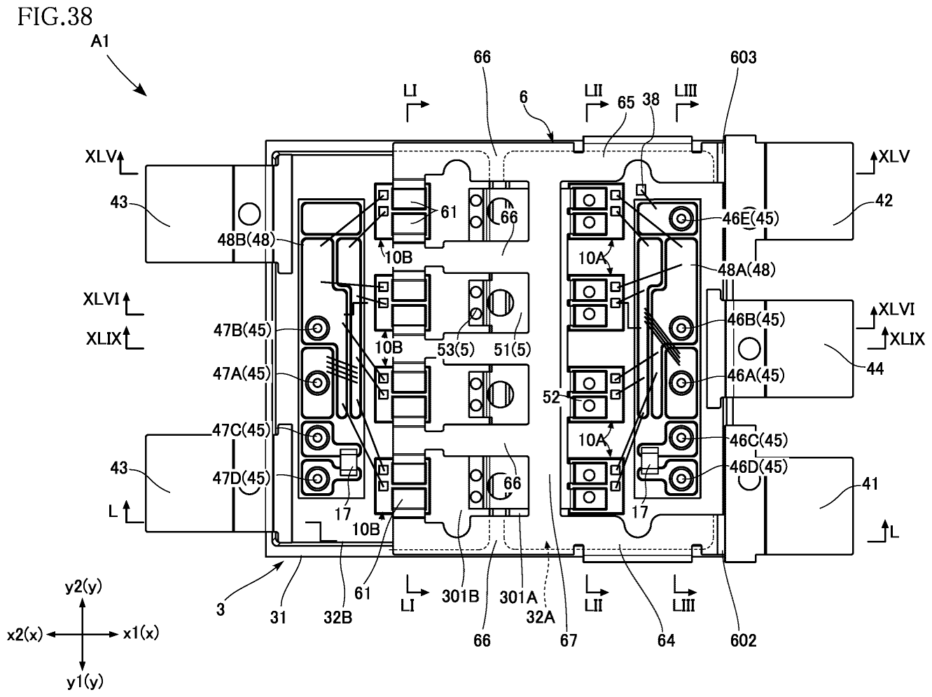

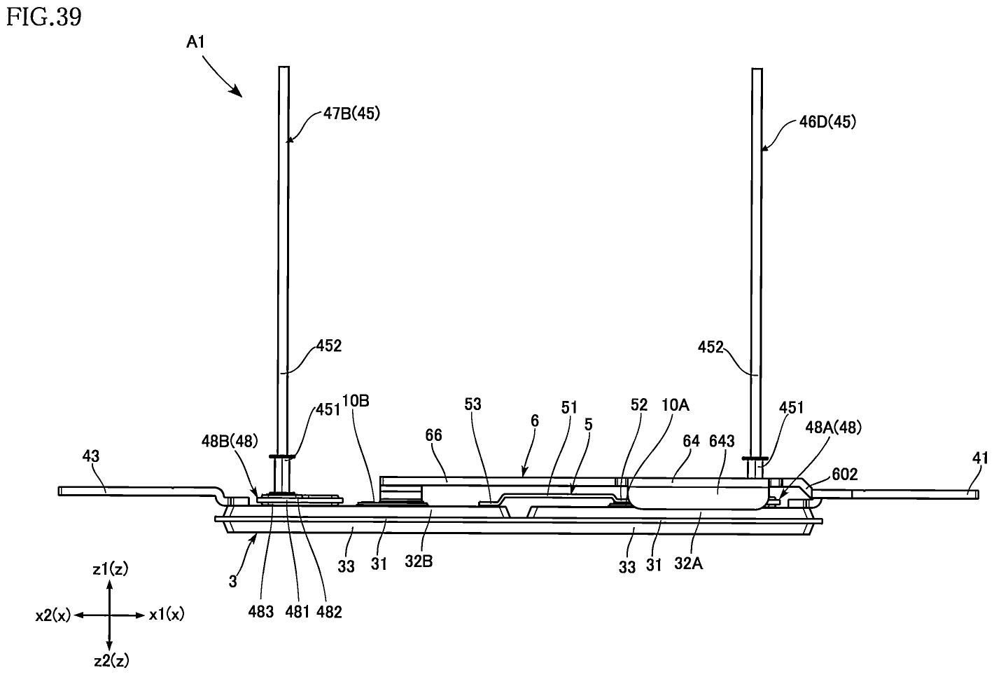

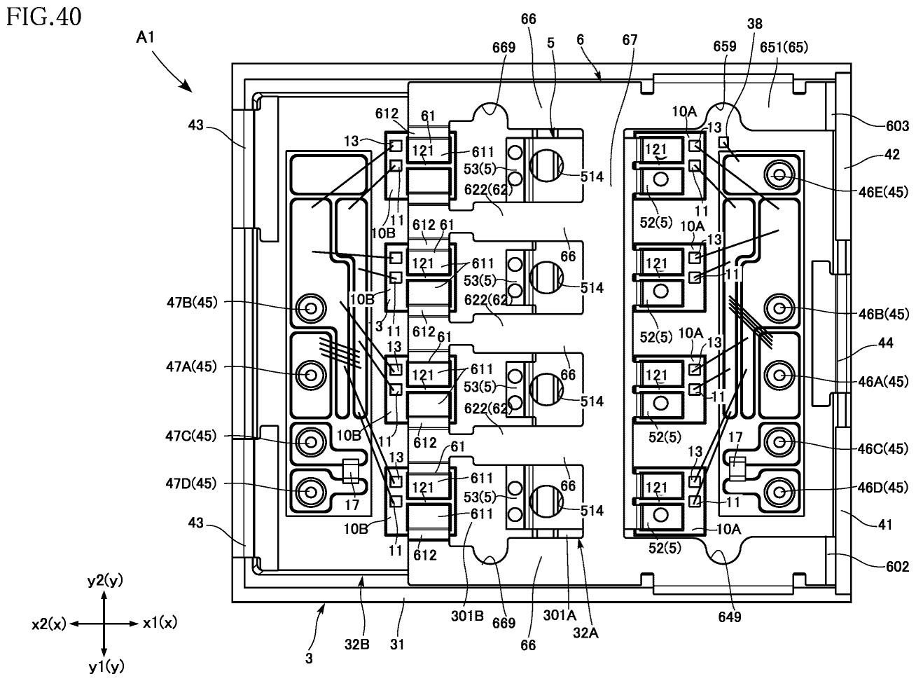

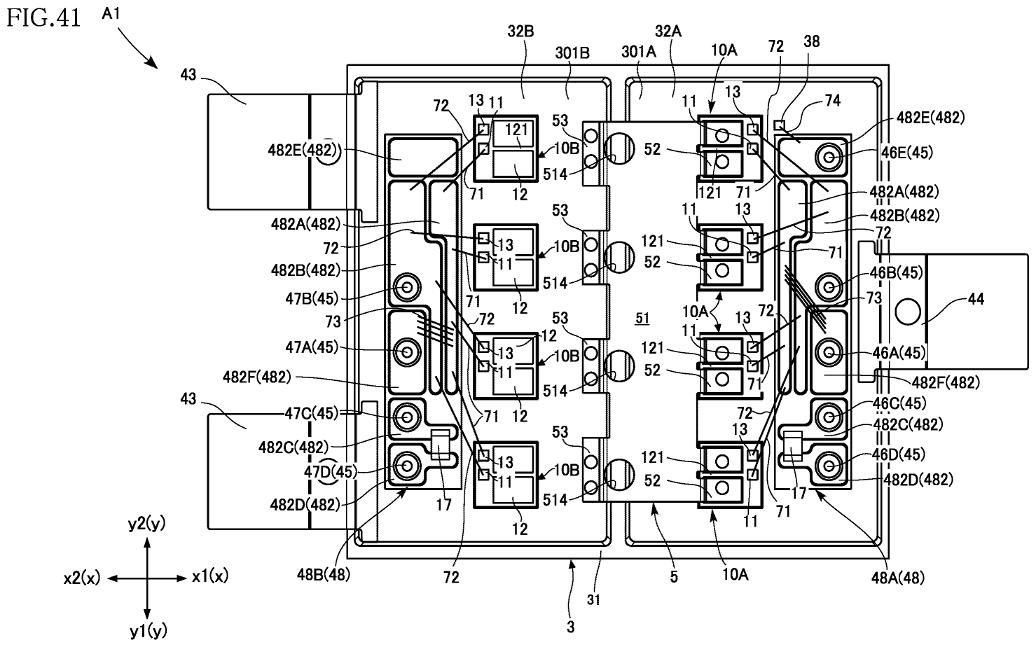

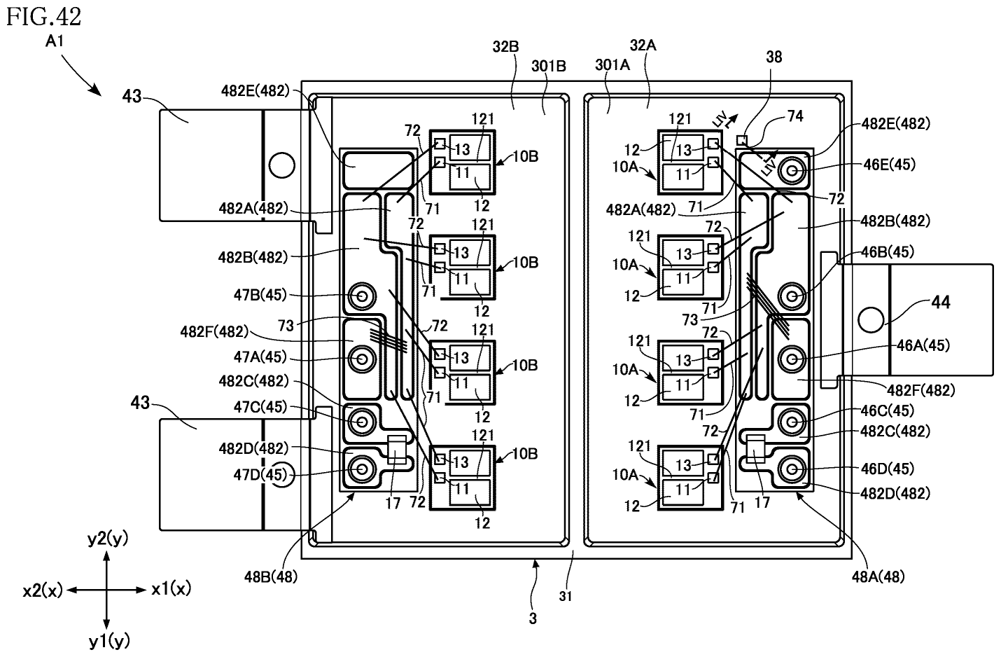

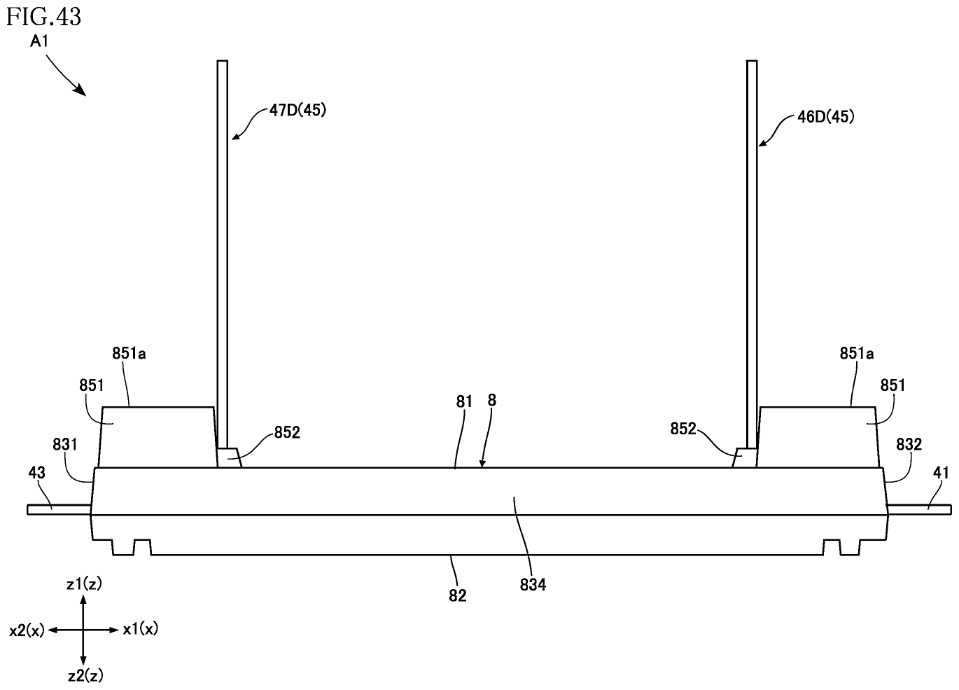

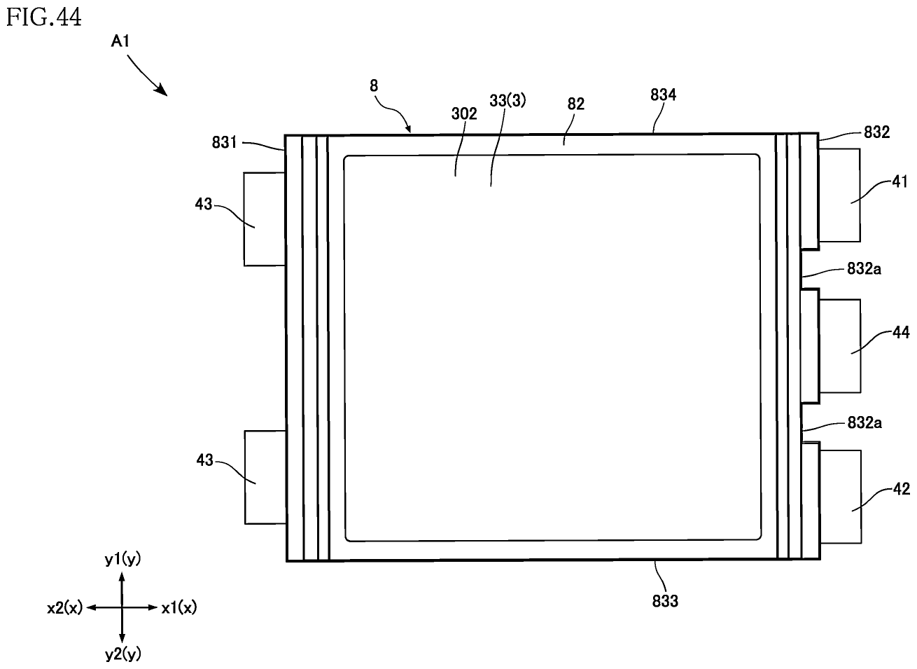

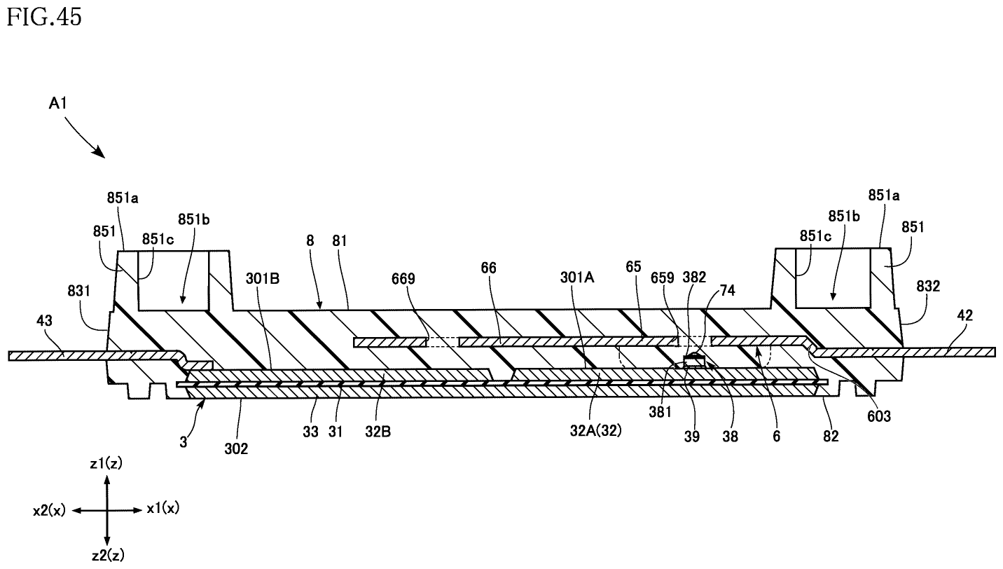

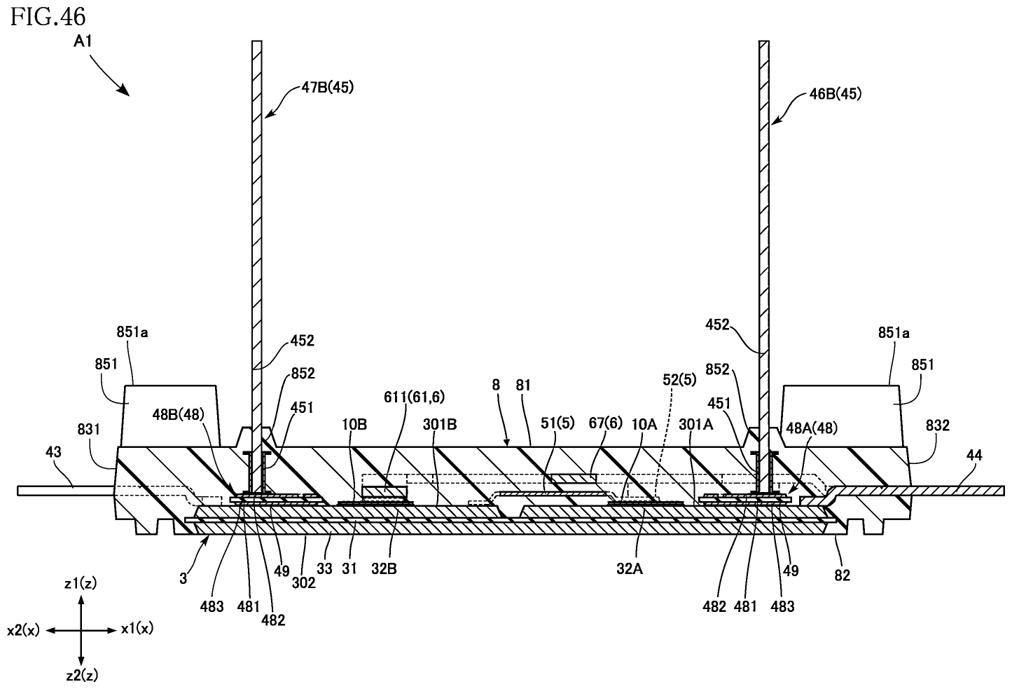

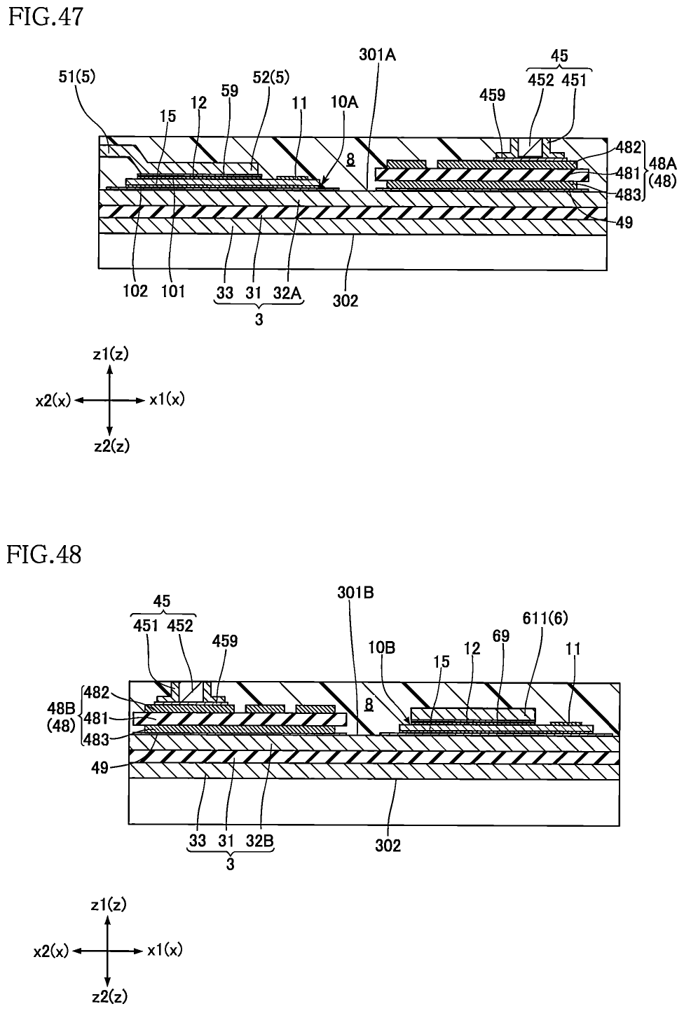

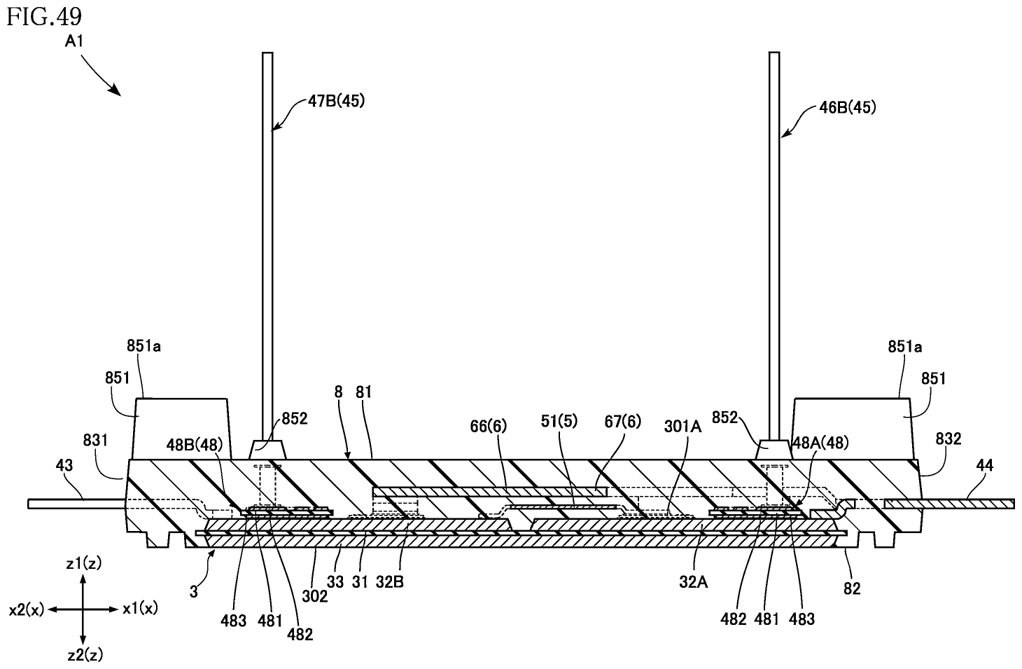

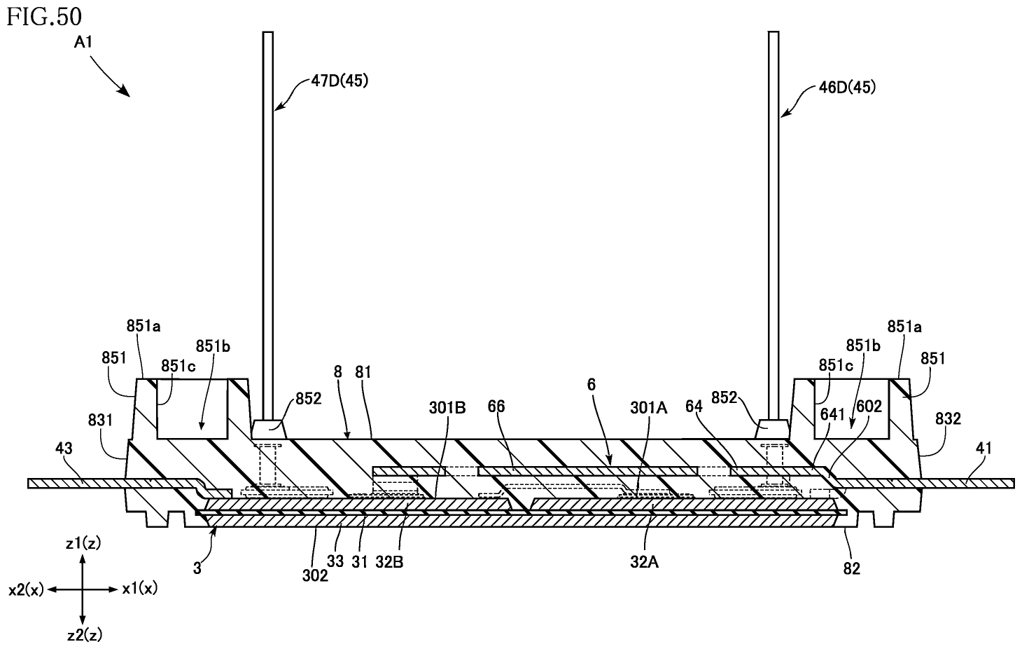

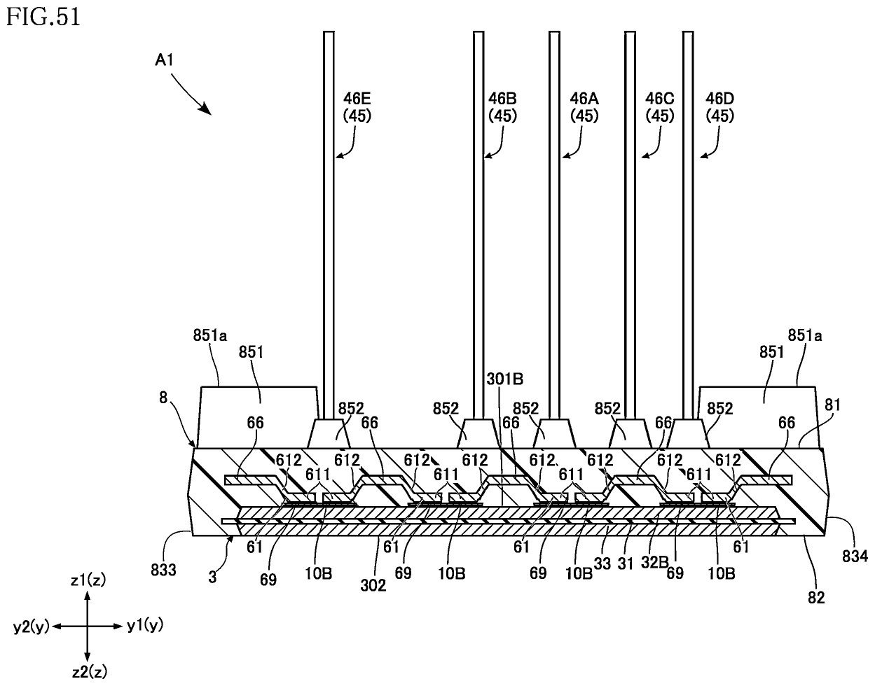

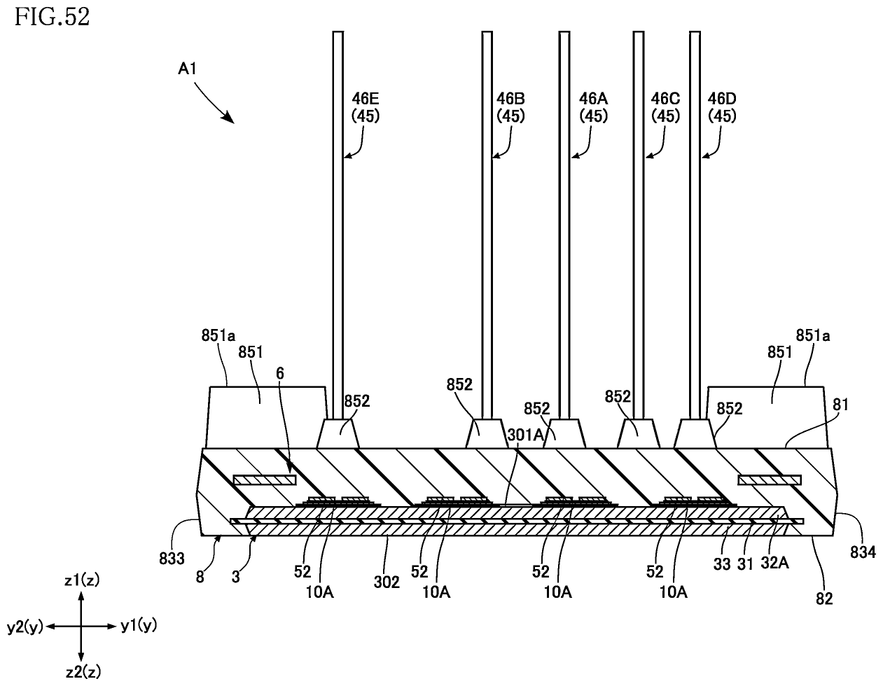

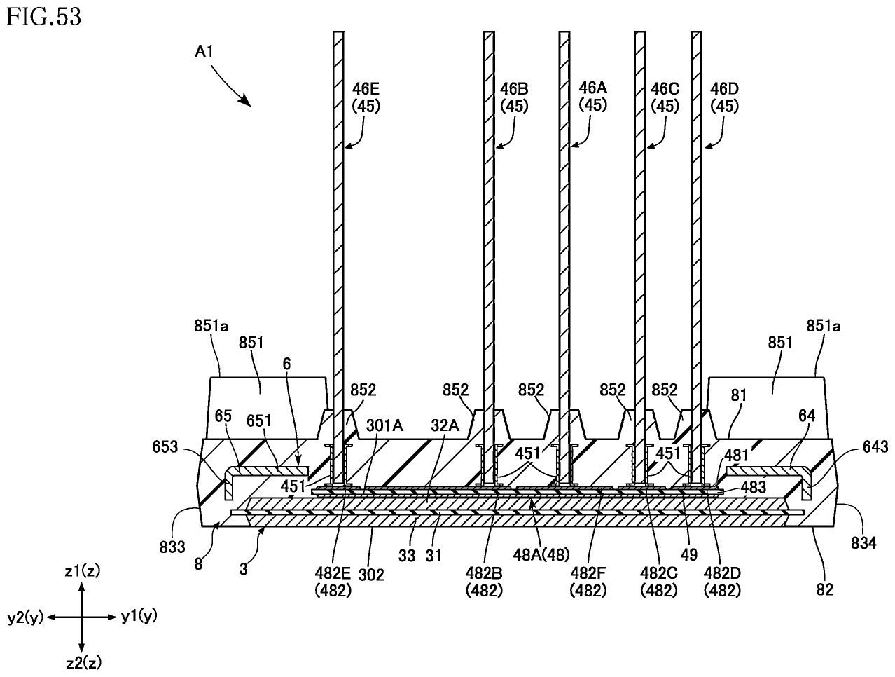

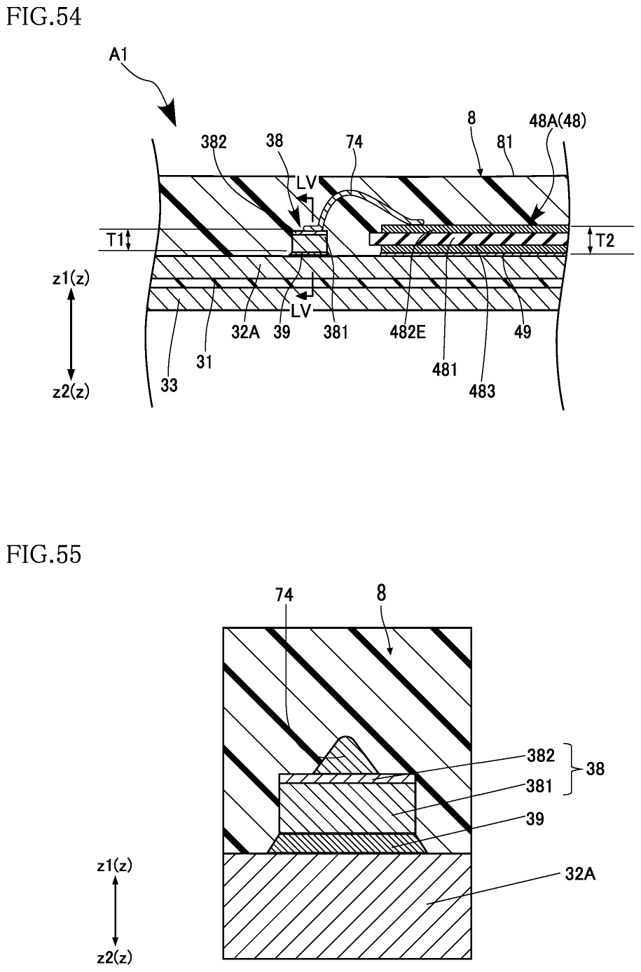

FIG. 34 is a perspective view showing the semiconductor device A1. FIGS. 35 and 36 are partial perspective views each showing the semiconductor device A1. FIG. 37 is a plan view showing the semiconductor device A1. FIG. 38 is a partial plan view showing the semiconductor device A1. FIG. 39 is a partial side view showing the semiconductor device A1. FIG. 40 is a partially enlarged plan view showing the semiconductor device A1. FIGS. 41 and 42 are partial plan views each showing the semiconductor device A1. FIG. 43 is a side view showing the semiconductor device A1. FIG. 44 is a bottom view showing the semiconductor device A1. FIG. 45 is a cross-sectional view taken along line XLV-XLV in FIG. 38. FIG. 46 is a cross-sectional view taken along line XLVI-XLVI in FIG. 38. FIGS. 47 and 48 are partially enlarged cross-sectional views each showing the semiconductor device A1. FIG. 49 is a cross-sectional view taken along line XLIX-XLIX in FIG. 38. FIG. 50 is a cross-sectional view taken along line L-L in FIG. 38. FIG. 51 is a cross-sectional view taken along line LI-LI in FIG. 38. FIG. 52 is a cross-sectional view taken along line LII-LII in FIG. 38. FIG. 53 is a cross-sectional view taken along line LIII-LIII in FIG. 38. FIG. 54 is a cross-sectional view taken along line LIV-LIV in FIG. 42. FIG. 55 is a cross-sectional view of the third conductive component 38.

In FIGS. 34 to 55, the thickness direction z is the thickness direction in the present disclosure, the first direction x is the first direction in the present disclosure, the second direction y is the second direction in the present disclosure. One side in the first direction x is referred to as the x1 side in the first direction x, and the other side in the first direction x as the x2 side in the first direction x. One side in the second direction y is referred to as the y1 side in the second direction y, and the other side in the second direction y as the y2 side in the second direction y. One side in the thickness direction z is referred to as the z1 side in the thickness direction z, and the other side in the thickness direction z as the z2 side in the thickness direction z.

Each of the first semiconductor elements 10A and the second semiconductor elements 10B is an electronic component that forms the functional core of the semiconductor device A1. The first semiconductor elements 10A and the second semiconductor elements 10B are made of a semiconductor material mainly containing silicon carbide (SiC), for example. The semiconductor material is not limited to SiC, and may be silicon (Si), gallium nitride (GaN), or diamond (C). Each of the first semiconductor elements 10A and the second semiconductor elements 10B is a power semiconductor chip having a switching function such as a metal oxide semiconductor field effect transistor (MOSFET), for example. The first semiconductor elements 10A and the second semiconductor elements 10B are MOSFETs in the present embodiment, but may be other transistors such as insulated gate bipolar transistors (IGBTs) in other examples. The first semiconductor elements 10A and the second semiconductor elements 10B are identical to each other. The first semiconductor elements 10A and the second semiconductor elements 10B are n-channel MOSFETs, but may be p-channel MOSFETs instead.

As shown in FIGS. 47 and 48, each of the first semiconductor elements 10A and the second semiconductor elements 10B has an element obverse surface 101 and an element reverse surface 102. In each of the first semiconductor elements 10A and the second semiconductor elements 10B, the element obverse surface 101 and the element reverse surface 102 are spaced apart from each other in the thickness direction z. The element obverse surface 101 faces the z1 side in the thickness direction z, and the element reverse surface 102 faces the z2 side in the thickness direction z.

In the present embodiment, the semiconductor device A1 includes four first semiconductor elements 10A and four second semiconductor elements 10B. However, the number of first semiconductor elements 10A and the number of second semiconductor elements 10B are not limited to the present example, and can be changed appropriately according to the performance required for the semiconductor device A1. In the example shown in FIGS. 41 and 42, four first semiconductor elements 10A and four second semiconductor elements 10B are arranged. Each of the number of first semiconductor elements 10A and the number of second semiconductor elements 10B may be two or three, or may be five or greater. The number of first semiconductor elements 10A may be the same as or different from the number of second semiconductor elements 10B. The numbers of first semiconductor elements 10A and second semiconductor elements 10B are determined according to the current capacity handled by the semiconductor device A1.

The semiconductor device A1 is configured as a half-bridge switching circuit, for example. In this case, the first semiconductor elements 10A form an upper arm circuit of the semiconductor device A1, and the second semiconductor elements 10B form a lower arm circuit. In the upper arm circuit, the first semiconductor elements 10A are connected in parallel. In the lower arm circuit, the second semiconductor elements 10B are also connected in parallel. Each first semiconductor element 10A is connected in series to a second semiconductor element 10B to form a bridge layer.

As shown in FIGS. 41, 42, and 52 in particular, the first semiconductor elements 10A are mounted on a below-described first conductive portion 32A of the support substrate 3. In the example shown in FIGS. 41 and 42, the first semiconductor elements 10A are aligned in the second direction y and spaced apart from each other. Each of the first semiconductor elements 10A is electrically bonded to the first conductive portion 32A via a first conductive bonding member 19A. Each of the first semiconductor elements 10A is bonded to the first conductive portion 32A, such that the element reverse surface 102 faces the first conductive portion 32A. Unlike the present embodiment, the first semiconductor elements 10A may be mounted on a metal member different from a part of the substrate, such as a DBC substrate. In this case, the metal member corresponds to the first conductive portion in the present disclosure. The metal member may be supported by the first conductive portion 32A, for example.

As shown in FIGS. 41, 42, and 51 in particular, the second semiconductor elements 10B are mounted on a below-described second conductive portion 32B of the support substrate 3. In the example shown in FIGS. 41 and 42, the second semiconductor elements 10B are aligned in the second direction y and spaced apart from each other. Each of the second semiconductor elements 10B is electrically bonded to the second conductive portion 32B via a second conductive bonding member 19B. Each of the second semiconductor elements 10B is bonded to the second conductive portion 32B, such that the element reverse surface 102 faces the second conductive portion 32B. As can be understood from FIG. 42, the first semiconductor elements 10A and the second semiconductor elements 10B overlap with each other as viewed in the first direction x, but this overlap is not necessary. Unlike the present embodiment, the second semiconductor elements 10B may be mounted on a metal member different from a part of the substrate, such as a DBC substrate. In this case, the metal member corresponds to the second conductive portion in the present disclosure. The metal member may be supported by the second conductive portion 32B, for example.

Each of the first semiconductor elements 10A and the second semiconductor elements 10B includes a first obverse-surface electrode 11, a second obverse-surface electrode 12, a third obverse-surface electrode 13, and a reverse-surface electrode 15. The description given below of the configurations of the first obverse-surface electrode 11, the second obverse-surface electrode 12, the third obverse-surface electrode 13, and the reverse-surface electrode 15 is common to all the first semiconductor elements 10A and the second semiconductor elements 10B. The first obverse-surface electrode 11, the second obverse-surface electrode 12, and the third obverse-surface electrode 13 are disposed on the element obverse surface 101. The first obverse-surface electrode 11, the second obverse-surface electrode 12, and the third obverse-surface electrode 13 are insulated by a non-illustrated insulating film. The reverse-surface electrode 15 is disposed on the element reverse surface 102. The first obverse-surface electrode 11 is a gate electrode, for example, and receives a drive signal (e.g., gate voltage) inputted to drive the first semiconductor element 10A (the second semiconductor element 10B). The second obverse-surface electrode 12 of the first semiconductor element 10A (the second semiconductor element 10B) is a source electrode, for example, and conducts a source current. The second obverse-surface electrode 12 of the present embodiment includes a gate finger 121. The gate finger 121 is a linear insulator that extends in the first direction x, for example, and divides the second obverse-surface electrode 12 into two regions in the second direction y. The third obverse-surface electrode 13 is a source sense electrode, for example, and conducts the source current. The reverse-surface electrode 15 is a drain electrode, for example, and conducts a drain current. The reverse-surface electrode 15 covers substantially the entirety of the element reverse surface 102. The reverse-surface electrode 15 is formed by silver (Ag) plating, for example.

Each first semiconductor element 10A (each second semiconductor element 10B) switches between a conducting state and a non-conducting state in response to a drive signal (gate voltage) inputted to the first obverse-surface electrode 11 (the gate electrode). In the conducting state, a current flows from the reverse-surface electrode 15 (the drain electrode) to the second obverse-surface electrode 12 (the source electrode). In the non-conducting state, the current does not flow. In short, each first semiconductor element 10A (each second semiconductor element 10B) performs a switching operation. With the switching functions of the first semiconductor elements 10A and the second semiconductor elements 10B, the semiconductor device A1 converts the DC voltage inputted between the fourth terminal 44 and each of the first terminal 41 and the second terminal 42 into AC voltage, for example, and outputs the AC voltage from the third terminals 43.

The thermistor 17 is used as a temperature detection sensor. Note that the semiconductor device A1 may include a temperature-sensing diode, for example, in addition to the thermistor 17, or may not include a thermistor 17.

The support substrate 3 supports the first semiconductor elements 10A and the second semiconductor elements 10B. The specific configuration of the support substrate 3 is not particularly limited. For example, the support substrate 3 may be a direct bonded copper (DBC) substrate or an active metal brazing (AMB) substrate. The support substrate 3 includes an insulating layer 31, a surface metal layer 32, and a reverse-surface metal layer 33. The surface metal layer 32 includes the first conductive portion 32A and the second conductive portion 32B. The first conductive portion 32A corresponds to the first conductive component in the present disclosure. The dimension of the support substrate 3 in the thickness direction z is at least 0.4 mm and at most 3.0 mm, for example.

The insulating layer 31 is made of a ceramic material with excellent thermal conductivity, for example. Examples of such a ceramic material include silicon nitride (SiN). The material of the insulating layer 31 is not limited to ceramic, and may be an insulating resin sheet, for example. The insulating layer 31 is rectangular in plan view, for example. The dimension of the insulating layer 31 in the thickness direction z is at least 0.05 mm and at most 1.0 mm, for example.

The first conductive portion 32A supports the first semiconductor elements 10A, and the second conductive portion 32B supports the second semiconductor elements 10B. The first conductive portion 32A and the second conductive portion 32B are formed on the upper surface (the surface facing the z1 side in the thickness direction z) of the insulating layer 31. The constituent material of each of the first conductive portion 32A and the second conductive portion 32B contains copper (Cu), for example. The constituent material may contain aluminum (Al) instead of copper (Cu), for example. The first conductive portion 32A and the second conductive portion 32B are spaced apart from each other in the first direction x. The first conductive portion 32A is located on the x1 side in the first direction x from the second conductive portion 32B. Each of the first conductive portion 32A and the second conductive portion 32B is rectangular in plan view, for example. The first conductive portion 32A and the second conductive portion 32B, together with the first conductive member 5 and the second conductive member 6, form the path of a main circuit current that is switched by the first semiconductor elements 10A and the second semiconductor elements 10B.

The first conductive portion 32A has a first obverse surface 301A. The first obverse surface 301A is a flat surface facing the z1 side in the thickness direction z. Each of the first semiconductor elements 10A is bonded to the first obverse surface 301A of the first conductive portion 32A via a first conductive bonding member 19A. The second conductive portion 32B has a second obverse surface 301B. The second obverse surface 301B is a flat surface facing the z1 side in the thickness direction z. Each of the second semiconductor elements 10B is bonded to the second obverse surface 301B of the second conductive portion 32B via a second conductive bonding member 19B. The constituent material of each of the first conductive bonding members 19A and the second conductive bonding members 19B is not particularly limited, and examples include solder, metal paste containing a metal such as silver (Ag), or a sintered metal containing a metal such as silver (Ag). The dimension of each of the first conductive portion 32A and the second conductive portion 32B in the thickness direction z may be at least 0.1 mm and at most 1.5 mm, for example.

The reverse-surface metal layer 33 is formed on the lower surface (the surface facing the z2 side in the thickness direction 2) of the insulating layer 31. The constituent material of the reverse-surface metal layer 33 is the same as that of the surface metal layer 32. The reverse-surface metal layer 33 has a reverse surface 302. The reverse surface 302 is a flat surface facing the z2 side in the thickness direction z. In the example shown in FIG. 44, the reverse surface 302 is exposed from the sealing resin 8, for example. A heat dissipating member (e.g., a heat sink), which is not shown in the figures, can be attached to the reverse surface 302. In another example, the reverse surface 302 may not be exposed from the sealing resin 8, and may be covered with the scaling resin 8. In plan view, the reverse-surface metal layer 33 overlaps with the first conductive portion 32A and the second conductive portion 32B.

The first terminal 41, the second terminal 42, the third terminals 43, and the fourth terminal 44 are made with metal plates. The metal plates may contain copper (Cu) or an alloy of copper (Cu), for example. In the example shown in FIGS. 34 to 38, 41, 42, and 44, the semiconductor device A1 includes one first terminal 41, one second terminal 42, one fourth terminal 44, and two third terminals 43, but the respective numbers of these terminals are not particularly limited.

The first terminal 41, the second terminal 42, and the fourth terminal 44 are input terminals for DC voltage that is to be converted. The fourth terminal 44 is a positive electrode (P terminal), and the first terminal 41 and the second terminal 42 are negative electrodes (N terminals). The third terminals 43 are output terminals for the AC voltage resulting from the power conversion by the first semiconductor elements 10A and the second semiconductor elements 10B. Each of the first terminal 41, the second terminal 42, the third terminals 43, and the fourth terminal 44 includes a portion covered with the sealing resin 8 and a portion exposed from the scaling resin 8.

As shown in FIG. 46, the fourth terminal 44 is electrically bonded to the first conductive portion 32A. The method for electrical bonding is not particularly limited, and may be ultrasonic bonding, laser bonding, welding, or bonding with solder, metal paste or a sintered silver, as appropriate. As shown in FIGS. 41 and 42 in particular, the fourth terminal 44 is located on the x1 side in the first direction x from the first semiconductor elements 10A and the first conductive portion 32A. The fourth terminal 44 is electrically connected to the first conductive portion 32A, and also to the reverse-surface electrodes 15 (the drain electrodes) of the first semiconductor elements 10A via the first conductive portion 32A.

The first terminal 41 and the second terminal 42 are electrically connected to the second conductive member 6. In the present embodiment, the first terminal 41 and the second conductive member 6 are integrally formed. The first terminal 41 and the second conductive member 6 that are integrally formed have no bonding material or joint, and they may be formed by cutting and bending a single metal plate, for example. In the present embodiment, the second terminal 42 and the second conductive member 6 are also integrally formed. As long as the first terminal 41 and the second terminal 42 are electrically connected to the second conductive member 6, they may be separate components unlike the present embodiment, and may include bonding portions bonded to the second conductive member 6. As shown in FIGS. 35 and 38 in particular, the first terminal 41 and the second terminal 42 are located on the x1 side in the first direction x from the first semiconductor elements 10A and the first conductive portion 32A. The first terminal 41 and the second terminal 42 are electrically connected to the second conductive member 6, and also to the second obverse-surface electrodes 12 (the source electrodes) of the respective second semiconductor elements 10B via the second conductive member 6.

As shown in FIGS. 34 to 38, and 44 in particular, the first terminal 41, the second terminal 42, and the fourth terminal 44 of the semiconductor device A1 protrude from the sealing resin 8 toward the x1 side in the first direction x. The first terminal 41, the second terminal 42, and the fourth terminal 44 are spaced apart from each other. The first terminal 41 and the second terminal 42 are located opposite to each other across the fourth terminal 44 in the second direction y. The first terminal 41 is located on the y1 side in the second direction y from the fourth terminal 44, and the second terminal 42 is located on the y2 side in the second direction y from the fourth terminal 44. The first terminal 41, the second terminal 42, and the fourth terminal 44 overlap with each other as viewed in the second direction y.

As can be seen from FIGS. 41, 42, and 45, the two third terminals 43 are electrically bonded to the second conductive portion 32B. The method for electrical bonding is not particularly limited, and may be ultrasonic bonding, laser bonding, welding, or bonding with solder, metal paste or a sintered silver, as appropriate. As shown in FIG. 41 in particular, the two third terminals 43 are located on the x2 side in the first direction x from the second semiconductor elements 10B and the second conductive portion 32B. The third terminals 43 are electrically connected to the second conductive portion 32B, and also to the reverse-surface electrodes 15 (the drain electrodes) of the second semiconductor elements 10B via the second conductive portion 32B. Note that the number of third terminals 43 is not limited to two, and may be one or greater than two. If one third terminal 43 is provided, it is preferable that the third terminal 43 be connected to the central portion of the second conductive portion 32B in the second direction y.

The control terminals 45 are pin-like terminals for controlling the first semiconductor elements 10A and the second semiconductor elements 10B. The control terminals 45 include a plurality of first control terminals 46A to 46E and a plurality of second control terminals 47A to 47D. The first control terminals 46A to 46E are used to control the first semiconductor elements 10A, for example. The second control terminals 47A to 47D are used to control the second semiconductor elements 10B, for example.

The first control terminals 46A to 46E are spaced apart from each other in the second direction y. As shown in FIGS. 41, 46, and 53 in particular, the first control terminals 46A to 46E are supported by the first conductive portion 32A via the control terminal support 48 (a first support portion 48A described below). As shown in FIGS. 38 and 41, the first control terminals 46A to 46E are located between the first semiconductor elements 10A and the first, second, and fourth terminals 41, 42, and 44 in the first direction x.

The first control terminal 46A is a terminal (a gate terminal) for receiving input of a drive signal for the first semiconductor elements 10A. The first control terminal 46A receives a drive signal (e.g., gate voltage) for driving the first semiconductor elements 10A.

The first control terminal 46B is a terminal (a source sense terminal) for detecting the source signal of the first semiconductor elements 10A. The voltage (the voltage corresponding to the source current) applied to the second obverse-surface electrodes 12 (the source electrodes) of the first semiconductor elements 10A is detected at the first control terminal 46B.

The first control terminals 46C and 46D are electrically connected to the thermistor 17.

The first control terminal 46E is a terminal (a drain sense terminal) for detecting the drain signal of the first semiconductor elements 10A. The voltage (the voltage corresponding to the drain current) applied to the reverse-surface electrodes 15 (the drain electrodes) of the first semiconductor elements 10A is detected at the first control terminal 46E.

The second control terminals 47A to 47D are spaced apart from each other in the second direction y. As shown in FIGS. 41 and 46 in particular, the second control terminals 47A to 47D are supported by the second conductive portion 32B via the control terminal support 48 (a second support portion 48B described below). As shown in FIGS. 38 and 41, the second control terminals 47A to 47D are located between the second semiconductor elements 10B and the two third terminals 43 in the first direction x.

The second control terminal 47A is a terminal (a gate terminal) for receiving input of a drive signal for the second semiconductor elements 10B. The second control terminal 47A receives a drive signal (e.g., gate voltage) for driving the second semiconductor elements 10B. The second control terminal 47B is a terminal (a source sense terminal) for detecting the source signal of the second semiconductor elements 10B. The voltage (the voltage corresponding to the source current) applied to the second obverse-surface electrodes 12 (the source electrodes) of the second semiconductor elements 10B is detected at the second control terminal 47B. The second control terminals 47C and 47D are electrically connected to the thermistor 17.

Each of the control terminals 45 (the first control terminals 46A to 46E and the second control terminals 47A to 47D) includes a holder 451 and a metal pin 452.

The holder 451 is made of a conductive material. As shown in FIGS. 47 and 48, the holder 451 is bonded to the control terminal support 48 (a first metal layer 482 described below) via a conductive bonding member 459. The holder 451 includes a tubular portion, an upper flange, and a lower flange. The upper flange is connected to the upper end of the tubular portion, and the lower flange is connected to the lower end of the tubular portion. The metal pin 452 is inserted through at least the upper flange and the tubular portion of the holder 451. The holder 451 is covered with the sealing resin 8 (a second protrusion 852 described below).

The metal pin 452 is a rod-like member extending in the thickness direction z. The metal pin 452 is pressed into the holder 451 and supported by the holder 451. The metal pin 452 is electrically connected to the control terminal support 48 (the first metal layer 482 described below) at least through the holder 451. When the lower end (the end on the z2 side in the thickness direction z) of the metal pin 452 is in contact with the conductive bonding member 459 within the insertion hole of the holder 451 as in the example shown in FIGS. 47 and 48, the electrical connection of the metal pin 452 to the control terminal support 48 is established also through the conductive bonding member 459.

The control terminal support 48 supports the control terminals 45. In the thickness direction z, the control terminal support 48 is located between the first and second obverse surfaces 301A and 301B and the plurality of control terminals 45.

The control terminal support 48 includes a first support portion 48A and a second support portion 48B. The first support portion 48A is disposed on the first conductive portion 32A and supports the first control terminals 46A to 46E out of the plurality of control terminals 45. As shown in FIG. 47, the first support portion 48A is bonded to the first conductive portion 32A via a bonding member 49. The bonding member 49 can be either conductive or insulating, and solder is used in one example. The second support portion 48B is disposed on the second conductive portion 32B and supports the second control terminals 47A to 47D out of the plurality of control terminals 45. As shown in FIG. 48, the second support portion 48B is bonded to the second conductive portion 32B via a bonding member 49.

The control terminal support 48 (each of the first support portion 48A and the second support portion 48B) may be composed of a direct bonded copper (DBC) substrate, for example. The control terminal support 48 includes a stack of an insulating layer 481, a first metal layer 482, and a second metal layer 483.

The insulating layer 481 is made of a ceramic material, for example. The insulating layer 481 is rectangular in plan view, for example.

As shown in FIGS. 47 and 48 in particular, the first metal layer 482 is formed on the upper surface of the insulating layer 481. Each of the control terminals 45 stands on the first metal layer 482. The first metal layer 482 contains copper (Cu) or an alloy of copper (Cu), for example. As shown in FIG. 41 in particular, the first metal layer 482 includes a first region 482A, a second region 482B, a third region 482C, a fourth region 482D, a fifth region 482E, and a sixth region 482F. The first region 482A, the second region 482B, the third region 482C, the fourth region 482D, the fifth region 482E, and the sixth region 482F are spaced apart and insulated from each other.

A plurality of wires 71 are bonded to the first region 482A. The wires 71 electrically connect the first region 482A to the first obverse-surface electrodes 11 (the gate electrodes) of the first semiconductor elements 10A (the second semiconductor elements 10B). A plurality of wires 73 are bonded to the first region 482A and the sixth region 482F. Thus, the sixth region 482F is electrically connected to the first obverse-surface electrodes 11 (the gate electrodes) of the first semiconductor elements 10A (the second semiconductor elements 10B) via the wires 73 and 71. As shown in FIG. 41, the first control terminal 46A is bonded to the sixth region 482F of the first support portion 48A, and the second control terminal 47A is bonded to the sixth region 482F of the second support portion 48B.

A plurality of wires 72 are bonded to the second region 482B. The wires 72 electrically connect the second region 482B to the third obverse-surface electrodes 13 (the source sense electrodes) of the first semiconductor elements 10A (the second semiconductor elements 10). As shown in FIG. 41, the first control terminal 46B is bonded to the second region 482B of the first support portion 48A, and the second control terminal 47B is bonded to the second region 482B of the second support portion 48B.

The thermistor 17 is bonded to the third region 482C and the fourth region 482D. As shown in FIG. 41, the first control terminals 46C and 46D are respectively bonded to the third region 482C and the fourth region 482D of the first support portion 48A. In addition, the second control terminals 47C and 47D are respectively bonded to the third region 482C and the fourth region 482D of the second support portion 48B.

The fifth region 482E is electrically connected to the first conductive portion 32A via a wire 74. As shown in FIG. 41, the first control terminal 46E is bonded to the fifth region 482E of the first support portion 48A. The fifth region 482E of the second support portion 48B is not electrically connected to any element. The surface of the fifth region 482E is plated with nickel (Ni), which is not illustrated. The constituent material of the wires 71 to 74 may contain gold (Au), aluminum (Al), or copper (Cu), for example.

As shown in FIGS. 47 and 48 in particular, the second metal layer 483 is formed on the lower surface of the insulating layer 481. As shown in FIG. 47, the second metal layer 483 of the first support portion 48A is bonded to the first conductive portion 32A via the bonding member 49. As shown in FIG. 48, the second metal layer 483 of the second support portion 48B is bonded to the second conductive portion 32B via the bonding member 49.

The wire 74 electrically bonds the first conductive portion 32A and the fifth region 482E. The wire 74 corresponds to the second conductive component in the present disclosure. The wire 74 contains a second metal. In the present embodiment, the wire 74 contains the second metal as a primary component. The second metal is aluminum (Al), for example.

As shown in FIGS. 41, 42, and 45, the third conductive component 38 is disposed between the surface metal layer 32 and the wire 74. The surface metal layer 32 contains a first metal. In the present embodiment, the surface metal layer 32 contains the first metal as a primary component. The first metal is copper (Cu), for example. As shown in FIG. 42, the third conductive component 38 is located on the y2 side in the y direction from the first support portion 48A. The shape of the third conductive component 38 is not particularly limited, and is rectangular as viewed in the z direction in the illustrated example. The specific method for disposing the third conductive component 38 on the surface metal layer 32 is not particularly limited. In the present embodiment, the third conductive component 38 is electrically bonded to the surface metal layer 32 via a conductive bonding member 39, for example.

The specific configuration of the third conductive component 38 is not particularly limited. In the illustrated example, the third conductive component 38 has a core 381 and a first layer 382, as shown in FIGS. 54 and 55. The core 381 mainly contains the first metal. The core 381 is electrically bonded to the surface metal layer 32 via the conductive bonding member 39. The first layer 382 is formed on the surface of the core 381 on the z1 side in the z direction. The first layer 382 mainly contains a third metal. The third metal is nickel (Ni), for example. The first layer 382 and the wire 74 are directly bonded to each other. The first layer 382 is formed on the surface of the core 381 by plating, for example. In this case, the first layer 382 is thinner than the core 381 in the z direction.

The first conductive member 5 and the second conductive member 6, together with the first conductive portion 32A and the second conductive portion 32B, form the path of the main circuit current that is switched by the first semiconductor elements 10A and the second semiconductor elements 10B. The first conductive member 5 and the second conductive member 6 are spaced apart from the first obverse surface 301A and the second obverse surface 301B toward the z1 side in the thickness direction z. In plan view, the first conductive member 5 and the second conductive member 6 overlap with the first obverse surface 301A and the second obverse surface 301B. In the present embodiment, each of the first conductive member 5 and the second conductive member 6 is made of a metal plate. The metal may contain copper (Cu) or an alloy of copper (Cu), for example. Specifically, the first conductive member 5 and the second conductive member 6 are metal plates having been bent as needed.

The first conductive member 5 is connected to the second obverse-surface electrodes 12 (the source electrodes) of the first semiconductor elements 10A and the second conductive portion 32B, and electrically connects the second obverse-surface electrodes 12 of the first semiconductor elements 10A and the second conductive portion 32B. The first conductive member 5 forms the path of the main circuit current that is switched by the first semiconductor elements 10A. As shown in FIGS. 40 and 41, the first conductive member 5 includes a main portion 51, a plurality of first bonding portions 52, and a plurality of second bonding portions 53.

The main portion 51 is located between the first semiconductor elements 10A and the second conductive portion 32B in the first direction x, and has the shape of a strip extending in the second direction y in plan view. The main portion 51 overlaps with both the first conductive portion 32A and the second conductive portion 32B in plan view, and is spaced apart from the first obverse surface 301A and the second obverse surface 301B to toward the z1 side in the thickness direction z. As shown in FIG. 49 in particular, the main portion 51 is located on the z2 side in the thickness direction z from a plurality of third path portions 66 and a fourth path portion 67 of the second conductive member 6 described below, and is closer to the first obverse surface 301A and the second obverse surface 301B than the third path portions 66 and the fourth path portion 67.

In the present embodiment, the main portion 51 is parallel to the first obverse surface 301A and the second obverse surface 301B.

As shown in FIG. 41 in particular, the main portion 51 extends in the second direction y to correspond to a region in which the first semiconductor elements 10A are positioned. In the present embodiment, the main portion 51 has a plurality of first openings 514 as shown in FIGS. 40, 41, and 46 in particular. The first openings 514 may be through-holes extending in the thickness direction z (the direction of the plate thickness of the main portion 51), for example. The first openings 514 are spaced apart from each other in the second direction y. The first openings 514 are provided for the respective first semiconductor elements 10A. In the present embodiment, the main portion 51 has four first openings 514, each of which corresponds in position in the second direction y to one of the plurality of (four) first semiconductor elements 10A.

As shown in FIGS. 41 and 46 in particular, the first openings 514 of the present embodiment overlap with the space between the first conductive portion 32A and the second conductive portion 32B in plan view. The first openings 514 are provided to facilitate the flow of a molten resin material between the upper region (on the z1 side in the thickness direction z) and the lower region (on the z2 side in the thickness direction z) around the main portion 51 (the first conductive member 5) when the molten resin material is injected in the process of forming the sealing resin 8.

As shown in FIG. 41 in particular, the first bonding portions 52 and the second bonding portions 53 are respectively connected to the main portion 51, and the first bonding portions 52 and the second bonding portions 53 are respectively arranged to correspond to the first semiconductor elements 10A. Specifically, the first bonding portions 52 are located on the x1 side in the first direction x from the main portion 51. The second bonding portions 53 are located on the x2 side in the first direction x from the main portion 51. As shown in FIG. 47, each of the first bonding portions 52 is bonded to the second obverse-surface electrode 12 of a corresponding first semiconductor element 10A via a conductive bonding member 59. Each of the second bonding portions 53 is bonded to the second conductive portion 32B via a conductive bonding member 59. The material of the conductive bonding members 59 is not particularly limited, and may be solder, metal paste, or sintered metal. In the present embodiment, each of the first bonding portions 52 includes two regions spaced apart from each other in the second direction y. The two regions are bonded to the second obverse-surface electrode 12 of a corresponding first semiconductor element 10A on the respective sides of the gate finger 121 of the second obverse-surface electrode 12 in the second direction y.

The second conductive member 6 electrically connects the second obverse-surface electrodes 12 (the source electrodes) of the second semiconductor elements 10B to the first terminal 41 and the second terminal 42. The second conductive member 6 is integrally formed with the first terminal 41 and the second terminal 42. The second conductive member 6 forms the path of the main circuit current that is switched by the second semiconductor elements 10B. As shown in FIG. 40, the second conductive member 6 includes a plurality of third bonding portions 61, a first path portion 64, a second path portion 65, a plurality of third path portions 66, and a fourth path portion 67. In the illustrated example, the second conductive member 6 further includes a first ramp portion 602 and a second ramp portion 603.

The third bonding portions 61 are bonded to the respective second semiconductor elements 10B. Each of the third bonding portions 61 is bonded to the second obverse-surface electrode 12 of a second semiconductor element 10B via a conductive bonding member 69. The material of the conductive bonding members 69 is not particularly limited, and may be solder, metal paste, or sintered metal. In the present embodiment, each of the third bonding portions 61 includes two flat sections 611 and two first inclined sections 612.

The two flat sections 611 are aligned in the second direction y. The two flat sections 611 are spaced apart from each other in the second direction y. The shape of each flat section 611 is not particularly limited, and is rectangular in the illustrated example. The two flat sections 611 are bonded to the second obverse-surface electrode 12 of a corresponding second semiconductor element 10B on the respective sides of the gate finger 121 of the second obverse-surface electrode 12 in the second direction y.

The two first inclined sections 612 are connected to the outer ends of the respective two flat sections 611 in the second direction y. In other words, the first inclined section 612 on the y1 side in the second direction y is connected to the y1-side end of the flat section 611 located on the y1 side in the second direction y. The first inclined section 612 located on the y2 side in the second direction y is connected to the y2-side end of the flat section 611 located on the y2 side in the second direction y. Each of the first inclined sections 612 is inclined toward the z1 side in the thickness direction z with an increasing distance from the flat section 611 in the second direction y.

The first path portion 64 is located between the third bonding portions 61 and the first terminal 41. In the illustrated example, the first path portion 64 is connected to the first terminal 41 via the first ramp portion 602. The first path portion 64 overlaps with the first conductive portion 32A in plan view. The first path portion 64 generally extends in the first direction x.

The first path portion 64 includes a first band-shaped section 641 and a first extended section 643. The first band-shaped section 641 is located on the x2 side in the first direction x from the first terminal 41 and is substantially parallel to the first obverse surface 301A. The first band-shaped section 641 generally extends in the first direction x. In the illustrated example, the first band-shaped section 641 has a recess 649. The recess 649 is a portion of the first band-shaped section 641 that is recessed toward the y1 side in the second direction y.

The first extended section 643 extends from the y1-side end of the first band-shaped section 641 in the second direction y toward the z2 side in the thickness direction z. The first extended section 643 is spaced apart from the first conductive portion 32A. In the illustrated example, the first extended section 643 extends in the thickness direction z and has a rectangular shape elongated in the first direction x. Note that the first path portion 64 may be configured without the first extended section 643.

The second path portion 65 is located between the third bonding portions 61 and the second terminal 42. In the illustrated example, the second path portion 65 is connected to the second terminal 42 via the second ramp portion 603. The second path portion 65 overlaps with the first conductive portion 32A in plan view. The second path portion 65 generally extends in the first direction x.

The second path portion 65 includes a second band-shaped section 651 and a second extended section 653. The second band-shaped section 651 is located on the x2 side in the first direction x from the second terminal 42 and is substantially parallel to the first obverse surface 301A. The second band-shaped section 651 generally extends in the first direction x. In the illustrated example, the second band-shaped section 651 has a recess 659. The recess 659 is a portion of the second band-shaped section 651 that is recessed toward the y2 side in the second direction y.

The second extended section 653 extends from the y2-side end of the second band-shaped section 651 in the second direction y toward the z2 side in the thickness direction z. The second extended section 653 is spaced apart from the first conductive portion 32A. In the illustrated example, the second extended section 653 extends in the thickness direction z and has a rectangular shape that is elongated in the first direction x. Note that the second path portion 65 may be configured without the second extended section 653.

In the description given below, other configurations of the first path portion 64 are presented according to variations and other embodiments. Such configurations may also apply to the second path portion 65 because the first path portion 64 and the second path portion 65 are symmetrical with respect to, for example, the centerline extending in the first direction x.

The third path portions 66 are individually connected to the third bonding portions 61. The third path portions 66 extend in the first direction x, and are spaced apart from each other in the second direction y. The number of third path portions 66 is not particularly limited. In the illustrated example, five third path portions 66 are provided. Each of the third path portions 66 is located either between two of the second semiconductor elements 10B in the second direction y or outside the second semiconductor elements 10B in the second direction y.

The two outermost third path portions 66 in the second direction y are formed with recesses 669. Each of the recesses 669 is recessed from the inner side toward the outer side in the second direction y. In the illustrated example, each of the two outermost third path portions 66 has one recess 669. In FIG. 38, the second conductive portion 32B is visible through the recesses 669.

In the present embodiment, each of the third bonding portions 61 is located between two third path portions 66 adjacent in the second direction y. Each of the third bonding portions 61 has two first inclined sections 612, one on the y1 side in the second direction y and the other on the y2 side in the second direction y. The first inclined section 612 on the y1 side is connected to one of the two adjacent third path portions 66 that is located on the y1 side in the second direction y. The first inclined section 612 on the y2 side is connected to one of the two adjacent third path portions 66 that is located on the y2 side in the second direction y.

The fourth path portion 67 is connected to the ends of the respective third path portions 66 on the x1 side in the first direction x. The fourth path portion 67 extends in the second direction y. The fourth path portion 67 is connected to the x2-side end of the first band-shaped section 641 of the first path portion 64 in the first direction x, and to the x2-side end of the second band-shaped section 651 of the second path portion 65 in the first direction x. In the illustrated example, the fourth path portion 67 is connected to the first path portion 64 at the end on the y1 side in the second direction y and to the second path portion 65 at the end on the y2 side in the second direction y.

The sealing resin 8 covers the first semiconductor elements 10A, the second semiconductor elements 10B, the support substrate 3 (except for the reverse surface 302), a part of each of the first terminal 41, the second terminal 42, the third terminals 43, and the fourth terminal 44, a part of each of the control terminals 45, the control terminal support 48, the first conductive member 5, the second conductive member 6, and the wires 71 to 74. The sealing resin 8 may be made of a black epoxy resin, for example. The sealing resin 8 may be formed by molding, for example. The size of the sealing resin 8 may have a dimension of about 35 mm to 60 mm in the first direction x, a dimension of about 35 mm to 50 mm in the second direction y, and a dimension of about 4 mm to 15 mm in the thickness direction z. These dimensions are measured at the largest portions in the respective directions. The sealing resin 8 has a resin obverse surface 81, a resin reverse surface 82, and resin side surfaces 831 to 834.

As shown in FIGS. 43, 45, and 51 in particular, the resin obverse surface 81 and the resin reverse surface 82 are spaced apart from each other in the thickness direction z. The resin obverse surface 81 faces the z1 side in the thickness direction z, and the resin reverse surface 82 faces the z2 side in the thickness direction z. The control terminals 45 (the first control terminals 46A to 46E and the second control terminals 47A to 47D) protrude from the resin obverse surface 81. As shown in FIG. 44, the resin reverse surface 82 has the shape of a frame surrounding the reverse surface 302 (the lower surface of the reverse-surface metal layer 33 of the main substrate 3 in plan view. The reverse surface 302 of the support substrate 3 is exposed from the resin reverse surface 82, and is flush with the resin reverse surface 82, for example. The resin side surfaces 831 to 834 are connected to both the resin obverse surface 81 and the resin reverse surface 82, and are located between the resin obverse surface 81 and the resin reverse surface 82 in the thickness direction z. As shown in FIG. 37 in particular, the resin side surface 831 and the resin side surface 832 are spaced apart from each other in the first direction x. The resin side surface 831 faces the x2 side in the first direction x, and the resin side surface 832 faces the x1 side in the first direction x. The two third terminals 43 protrude from the resin side surface 831, and the first terminal 41, the second terminal 42, and the fourth terminal 44 protrude from the resin side surface 832. As shown in FIG. 37 in particular, the resin side surface 833 and the resin side surface 834 are spaced apart from each other in the second direction y. The resin side surface 833 faces the y2 side in the second direction y, and the resin side surface 834 faces the y1 side in the second direction y.

As shown in FIG. 37, the resin side surface 832 has a plurality of recesses 832a. Each of the recesses 832a is recessed in the first direction x in plan view. The recesses 832a include one formed between the first terminal 41 and the fourth terminal 44, and one formed between the second terminal 42 and the fourth terminal 44 in plan view. The recesses 832a are provided to increase the creepage distance along the resin side surface 832 between the first terminal 41 and the fourth terminal 44, and also to increase the creepage distance along the resin side surface 832 between the second terminal 42 and the fourth terminal 44.

As shown in FIGS. 45 and 46 in particular, the sealing resin 8 includes a plurality of first protrusions 851, a plurality of second protrusions 852, and a resin cavity 86.

The first protrusions 851 protrude from the resin obverse surface 81 in the thickness direction z. The first protrusions 851 are located near the four corners of the sealing resin 8 in plan view. Each of the first protrusions 851 has a first protrusion end surface 851a at its end (the end on the z1 side in the thickness direction z). The first protrusion end surface 851a of each first protrusion 851 is substantially parallel to the resin obverse surface 81 and located in the same plane (x-y plane). Each of the first protrusions 851 has the shape of a hollow truncated cone with a bottom, for example. The first protrusions 851 serve as spacers when the semiconductor device A1 is mounted on, for example, a control circuit board of a device that operates with the power generated by the semiconductor device A1. Each of the first protrusions 851 has a recess 851b and an inner wall surface 851c of the recess 851b. Each of the first protrusions 851 is columnar, which is preferably a cylindrical column. The recess 851b has a cylindrical shape, preferably with the inner wall surface 851c defining a perfect circle in plan view.

The semiconductor device A1 may be mechanically fastened to the control circuit board or the like by screwing, for example. In such a case, each first protrusion 851 may be formed with an internal thread on the inner wall surface 851c of the recess 851b. For example, an insert nut may be inserted into the recess 851b of each first protrusion 851.

As shown in FIG. 46 in particular, the second protrusions 852 protrude from the resin obverse surface 81 in the thickness direction z. The second protrusions 852 overlap with the control terminals 45 in plan view. The metal pin 452 of each control terminal 45 protrudes from a second protrusion 852. Each of the second protrusions 852 has the shape of a truncated conc. Each of the second protrusions 852 covers the holder 451 and a portion of the metal pin 452 of a control terminal 45.

The following describes advantages of the present embodiment.

When the surface metal layer 32 mainly contains a first metal and the wire 74 mainly contains a second metal, direct bonding between the wire 74 and the surface metal layer 32 may cause an unintentional phenomenon. In the present embodiment, the third conductive component 38 is disposed between the surface metal layer 32 and the wire 74. The third conductive component 38 contains a third metal different from the first metal and the second metal. This prevents direct contact between an element made of the first metal and an element made of the second metal, and the occurrence of an intentional phenomenon can be avoided as a result.

Suppose that the first metal is copper (Cu) and the second metal is aluminum (Al). In this case, the Kirkendall phenomenon may occur when these metals are left under a high temperature. Thus, nickel (Ni) is selected for the third metal to avoid the Kirkendall phenomenon.

The third conductive component 38 may be divided into a core and a first layer 382. The first layer 382 may contain the third metal as a main component, and may be provided to be in contact with the wire 74. This is because in order to avoid the Kirkendall phenomenon, only the surface in contact with the wire 74 may be made of a material mainly containing the third metal. This reduces the cost of forming the third conductive component 38.

The third conductive component 38 is bonded to the surface metal layer 32 via the conductive bonding member 39. The third conductive component 38 includes the second layer that is in contact with the conductive bonding member 39 and mainly contains the third metal. This makes it possible to prevent the Kirkendall phenomenon between the third conductive component 38 and the conductive bonding member 39.

The control terminal support 48 includes the insulating layer 481, and further includes the first metal layer 482 and the second metal layer 483 on the respective sides of the insulating layer 481. The control terminal support 48 is located on the support substrate 3. In this example, the thickness T1 of the third conductive component 38 may be smaller than the thickness T2 of the control terminal support 48. This makes it possible to prevent other components from being caught on the third conductive component 38 during assembly.

The first terminal 41 and the second conductive member 6 are integrally formed. Unlike the configuration in which the first terminal 41 and the second conductive member 6 are bonded to each other, the semiconductor device A1 with this configuration can be manufactured without a bonding process. In addition, the semiconductor device A1 with this configuration can avoid a risk of cracking or delamination at a bonding portion during operation. Thus, the semiconductor device A1 can be manufactured with simplified processes and enhance operational reliability.

The second terminal 42 and the second conductive member 6 are integrally formed. Unlike the configuration in which the second terminal 42 and the second conductive member 6 are bonded to each other, the semiconductor device A1 with this configuration can be manufactured without a bonding process. In addition, the semiconductor device A1 with this configuration can avoid a risk of cracking or delamination at a bonding portion during operation. Thus, the semiconductor device A1 can be manufactured with simplified processes and enhance operational reliability.

The second conductive member 6 includes the first ramp portion 602 connected to the first terminal 41. This configuration increases the rigidity of the connection between the second conductive member 6 and the first terminal 41.

The second conductive member 6 includes the second ramp portion 603 connected to the second terminal 42. This configuration increases the rigidity of the connection between the second conductive member 6 and the second terminal 42.

Each of the third bonding portions 61 includes two flat sections 611 and two first inclined sections 612. The two first inclined sections 612 are connected to the outer ends of the two flat sections 611 in the second direction y. This means that the current flowing through each second obverse-surface electrode 12 flows to both sides in the second direction y through the flat sections 611 and the first inclined sections 612. This prevents concentration of electric current flowing through the second obverse-surface electrode 12 at one location.

The two flat sections 611 are spaced apart from each other in the second direction y. This ensures that the electric current flows through both of the two flat sections 611 and both of the two first inclined sections 612, which is effective for preventing current concentration.

The two flat sections 611 are spaced apart from each other. This allows the gate finger 121 of a second obverse-surface electrode 12 to be placed between the two flat sections 611.

Each of the third bonding portions 61 is provided between two third path portions 66 adjacent to each other in the second direction y. This enables the electric current flowing through the second obverse-surface electrode 12 of a second semiconductor element 10B to disperse into two third path portions 66.

The following describes a first variation of the fourth embodiment. The present variation relates to the third conductive component 38. As shown in FIG. 56, the first layer 382 of the present variation is locally formed only at the portion in contact with the wire 74. In other words, the first layer 382 is smaller than the core 381 as viewed in the z direction. Since the Kirkendall phenomenon occurs at the bonding portion between the wire 74 and the third conductive component 38, the first layer 382 may be formed only at the bonding portion.

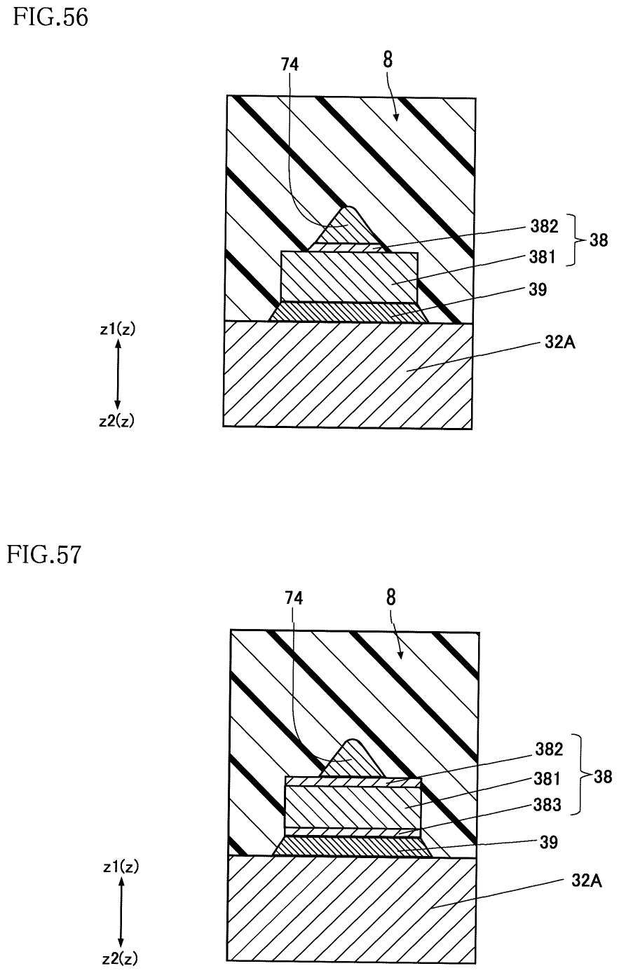

The following describes a second variation of the fourth embodiment. As shown in FIG. 57, the third conductive component 38 of the present variation further includes a second layer 383. The second layer 383 is disposed opposite from the first layer 382 with respect to the core 381, and is in contact with the conductive bonding member 39. In this case, the conductive bonding member 39 is not in direct contact with the core 381, thus preventing the Kirkendall phenomenon at this region.

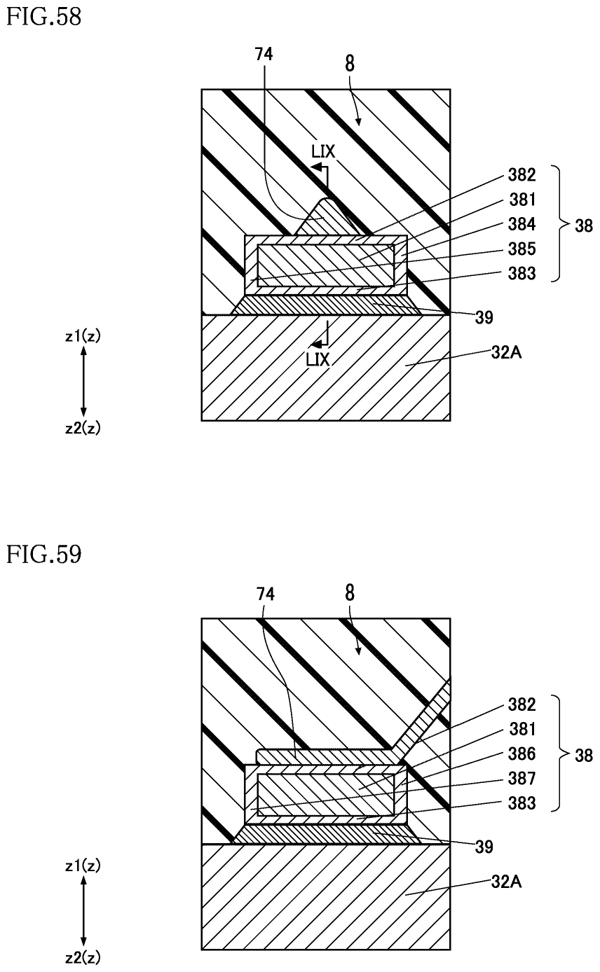

The following describes a third variation of the fourth embodiment. As shown in FIGS. 58 and 59, the entire surfaces of the core 381 may be plated for ease of manufacturing. In this case, the third conductive component 38 further includes a third layer 384, a fourth layer 385, a fifth layer 386, and a sixth layer 387. The third layer 384, the fourth layer 385, the fifth layer 386, and the sixth layer 387 respectively cover the four side surfaces of the core 381.

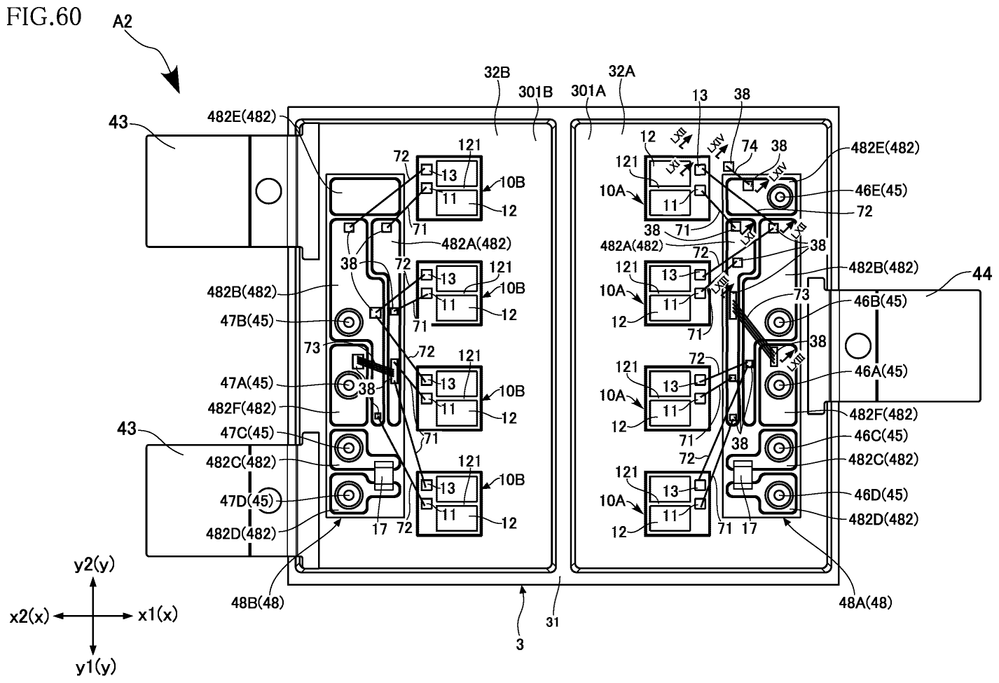

FIGS. 60 to 67 show other embodiments of the present disclosure. In these figures, elements that are identical or similar to those described in the above embodiments are indicated by the same reference numerals. In addition, the configurations of the elements in each variation and each embodiment can be combined as appropriate as long as the combination does not cause technical contradictions.

FIGS. 60 to 64 show the fifth embodiment of the present disclosure. A semiconductor device A2 of the present embodiment is different from the above examples in the arrangement of the third conductive component 38 and the number of third conductive components 38.

In the fifth embodiment, the control terminal support 48 corresponds to the first conductive component in the present disclosure, and each of the wires 71 to 74 corresponds to the second conductive component in the present disclosure. The wires 71 to 74 are bonded to a plurality of third conductive components 38. The third conductive components 38 are bonded to a plurality of control terminal supports 48 via conductive bonding members 39.

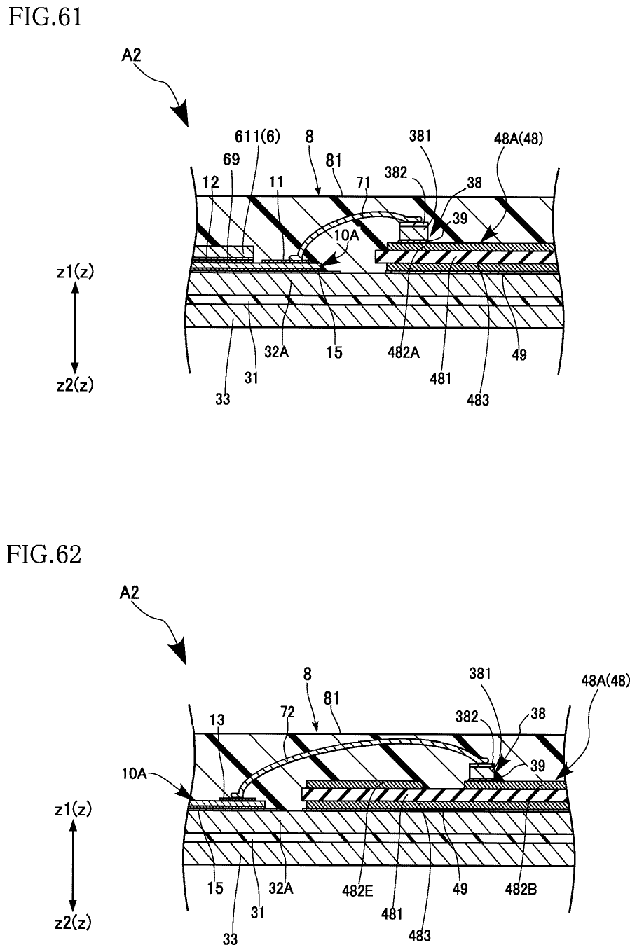

As shown in FIGS. 60 and 61, each of the wires 71 electrically connects a first obverse-surface electrode 11 and a first region 482A. In the present embodiment, each of the third conductive components 38 is disposed between a first region 482A and a wire 71. The first region 482A corresponds to the first conductive component in the present disclosure, and each of the wires 71 corresponds to the second conductive component. The core 381 of each of the third conductive components 38 is electrically bonded to a first region 482A by a conductive bonding member 39. The first layer 382 of each of the third conductive components 38 is directly bonded to a wire 71.

As shown in FIGS. 60 and 62, each of the wires 72 electrically connects a third obverse-surface electrode 13 and a second region 482B. In the present embodiment, each of the third conductive components 38 is disposed between a second region 482B and a wire 72. The second region 482B corresponds to the first conductive component in the present disclosure, and each of the wires 72 corresponds to the second conductive component. The core 381 of each of the third conductive components 38 is electrically bonded to a second region 482B by a conductive bonding member 39. The first layer 382 of each of the third conductive components 38 is directly bonded to a wire 72.

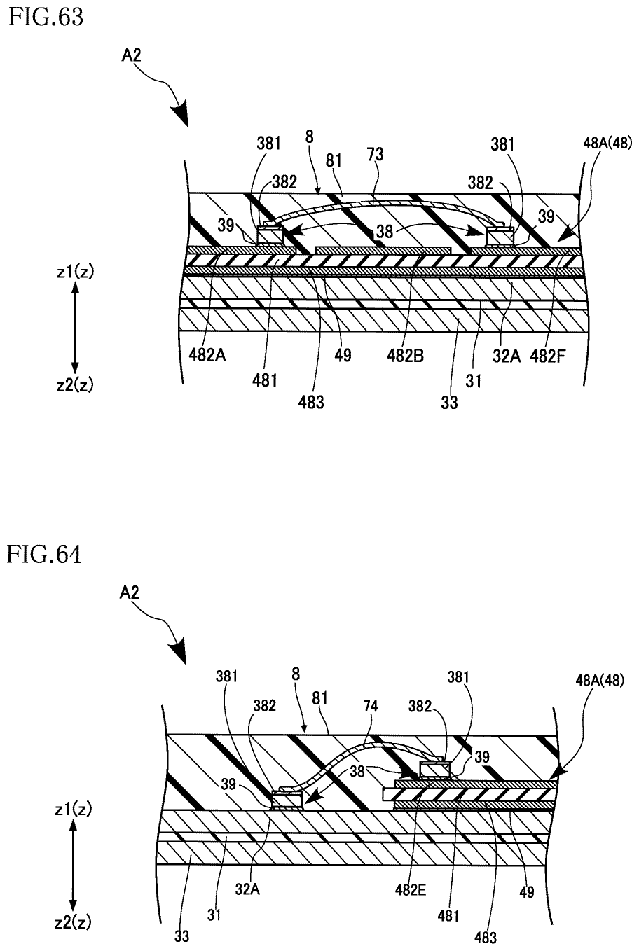

FIG. 63 shows two third conductive components 38. The wire 73 electrically connects the first region 482A and the sixth region 482F. In the present embodiment, one of the third conductive components 38 is disposed between the first region 482A and the wire 73, and the other third conductive component 38 is disposed between the sixth region 482F and the wire 73. Each of the first region 482A and the sixth region 482F corresponds to the first conductive component in the present disclosure, and the wire 73 corresponds to the second conductive component. The cores 381 of the third conductive components 38 are electrically bonded to the first region 482A and the sixth region 482F by conductive bonding members 39. The first layers 382 of the third conductive components 38 are directly bonded to the wire 73.

FIG. 64 shows two third conductive components 38. The wire 74 electrically connects the fifth region 482E and the surface metal layer 32. In the present embodiment, one of the third conductive components 38 is disposed between the fifth region 482E and the wire 74, and the other third conductive component 38 is disposed between the surface metal layer 32 and the wire 74. Each of the fifth region 482E and the surface metal layer 32 corresponds to the first conductive component in the present disclosure, and the wire 74 corresponds to the second conductive component. The cores 381 of the third conductive components 38 are electrically bonded to the fifth region 482E and the surface metal layer 32 by conductive bonding members 39. The first layer 382 of a third conductive component 38 is directly bonded to the wire 74.

According to the present embodiment, it is also possible to prevent the Kirkendall phenomenon that may occur between the control terminal supports 48 and the wires 71 to 74.

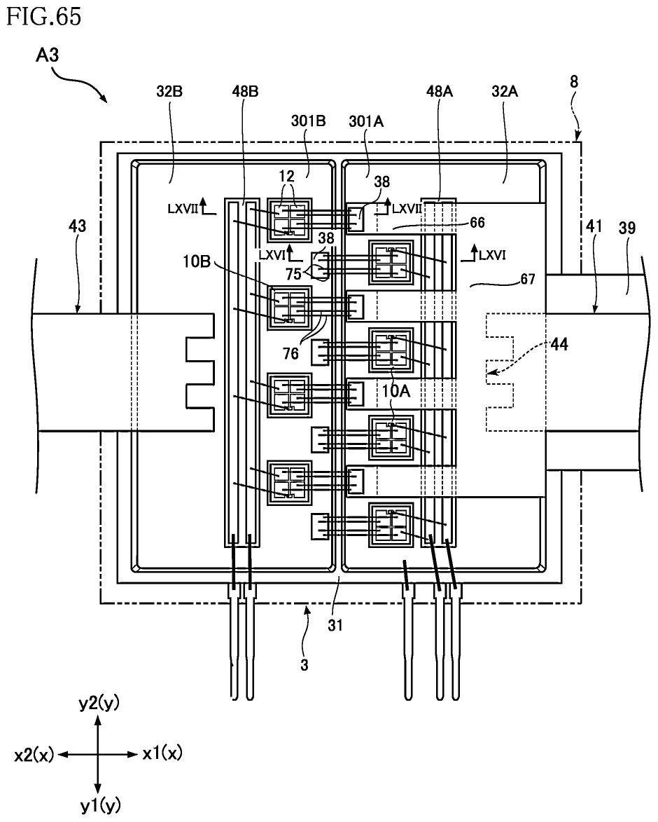

FIGS. 65 to 67 show a semiconductor device according to the sixth embodiment of the present disclosure. A semiconductor device A3 of the present embodiment is different from the above examples in the arrangement of the third conductive components 38 and the shape of the second conductive member 6. The semiconductor device A3 further includes wires 75 and 76. The respective numbers of wires 75 and 76 and the thickness of each of the wires 75 and 76 are not particularly limited. In order to provide a large current, however, it is preferable that the respective numbers of wires 75 and 76 be about four, and that the wires 75 and 76 be thicker than the wires 71 to 74.

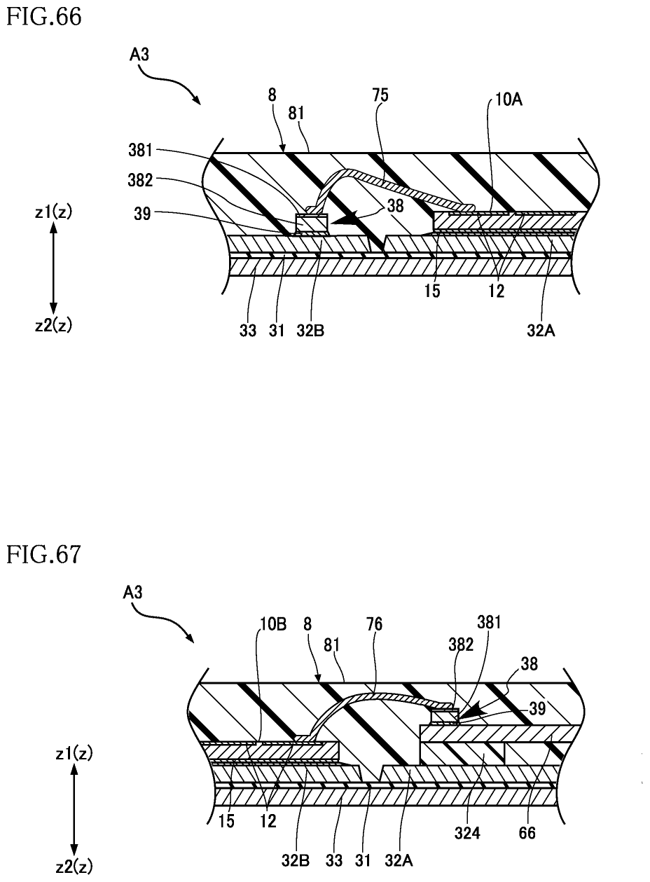

As shown in FIGS. 65 and 66, each of the wires 75 electrically connects the second conductive portion 32B and a first semiconductor element 10A. In the present embodiment, a third conductive component 38 is disposed between the second conductive portion 32B and the wire 75. The second conductive portion 32B corresponds to the first conductive component, and the wire 75 corresponds to the second conductive component. The core 381 is electrically bonded to the second conductive portion 32B by a conductive bonding member 39. The first layer 382 is directly bonded to the wire 75.

As shown in FIGS. 65 and 67, the shape of the second conductive member 6 is different from that in the fourth embodiment, and the length of the second conductive member 6 in the first direction x is shorter. Thus, each of the wires 76 electrically connects the second conductive member 6 and a second semiconductor element 10B. In the present embodiment, a third conductive component 38 is disposed between a third path portion 66 and the wire 76. An insulator 324 is provided between the third path portion 66 and the first conductive portion 32A. The insulator 324 is electrically insulative. The second conductive member 6 corresponds to the first conductive component in the present disclosure, and the wire 76 corresponds to the second conductive component in the present disclosure. The core 381 is electrically bonded to the second conductive member 6 by a conductive bonding member 39. The first layer 382 is directly bonded to the wire 76.

According to the present embodiment, it is also possible to prevent the Kirkendall phenomenon that may occur between the second conductive portion 32B and the wire 75 and between the second conductive member 6 and the wire 76.

The semiconductor device according to the present disclosure is not limited to the embodiments described above. Various design changes can be made to the specific configurations of the elements of the semiconductor device according to the present disclosure.

### Clause 1B.

A semiconductor device comprising:
a first conductive component containing a first metal;
a second conductive component containing a second metal; and
a third conductive component containing a third metal,
wherein the first metal, the second metal, and the third metal are different from each other, and
the third conductive component is disposed between the first conductive component and the second conductive component.

### Clause 2B.

The semiconductor device according to clause 1B, wherein the third conductive component includes a core and a first layer,
a main component of the core is the first metal,
a main component of the first layer is the third metal, and
the first layer is directly bonded to the second conductive component.

### Clause 3B.

The semiconductor device according to clause 2B, wherein the third conductive component further includes a second layer,
the second layer is located opposite from the first layer,
a main component of the second layer is the third metal, and
the second layer is electrically bonded to the first conductive component.

### Clause 4B.

The semiconductor device according to any of clauses 1B to 3B, wherein the first metal is Cu.

### Clause 5B.

The semiconductor device according to any of clauses 1B to 4B, wherein a main component of the first conductive component is the first metal.

### Clause 6B.

The semiconductor device according to any of clauses 1B to 5B, wherein the second metal is Al.

### Clause 7B.

The semiconductor device according to any of clauses 1B to 6B, wherein a main component of the second conductive component is the second metal.

### Clause 8B.

The semiconductor device according to any of clauses 1B to 7B, wherein the third metal is Ni.

### Clause 9B.

The semiconductor device according to any of clauses 1B to 8B, wherein a main component of the third conductive component is the third metal.

### Clause 10B.

The semiconductor device according to any of clauses 1B to 9B, wherein the first conductive component has a plate shape.

### Clause 11B.

The semiconductor device according to any of clauses 1B to 10B, wherein the second conductive component is a wire.

### Clause 12B.

The semiconductor device according to any of clauses 1B to 11B, wherein a conductive bonding member is provided between the first conductive component and the third conductive component.

### Clause 13B.

The semiconductor device according to any of clauses 1B to 12B, further comprising a support substrate including an insulating layer and conductive layers on respective surfaces of the insulating layer,
wherein one of the conductive layers is the first conductive component, and
a semiconductor element is electrically bonded to the first conductive component.

### Clause 14B.

The semiconductor device according to clause 13B, further comprising a control terminal support including an insulating layer and a first metal layer and a second metal layer on respective surfaces of the insulating layer,
wherein the control terminal support is located on the support substrate, and
a thickness of the third conductive component is smaller than a thickness of the control terminal support.

### Clause 15B.

The semiconductor device according to clause 13B or 14B, wherein the control terminal support is directly bonded to the second conductive component.

REFERENCE NUMERALS
<Numerals used in FIGS. 1 to 33>

| | | |
|---|---|---|
| A1, A11, A12, A13, A14, A2, A21, A22, A23, A24, | B1: Vehicle | |
| A3, A31: Semiconductor device | | |
| 3: Main substrate | 5: First conductive member | |
| 6: Second conductive member | 8: Sealing resin | |
| 10A: First semiconductor element | | |
| 10B: Second semiconductor element | | |
| 11: First obverse-surface electrode | | |
| 12: Second obverse-surface electrode | | |
| 13: Third obverse-surface electrode | | |
| 15: Reverse-surface electrode | | |
| 17: Thermistor | 19A: First conductive bonding member | |
| 19B: Second conductive bonding member | 31: Main insulating layer | |
| 32: First main metal layer | 32A: First conductive portion | |
| 32B: Second conductive portion | 33: Second main metal layer | |
| 41: First terminal | 42: Second terminal | |
| 43: Third terminal | 44: Fourth terminal | |
| 45, 46A, 46B, 47A, 47B, 47C, 47D: Control terminal | | |
| 46E: Control terminal (First control terminal) | | |
| 48: Control terminal support | | |
| 48A: First sub-substrate | 48B: Second sub-substrate | |
| 49: Conductive bonding member | 51: Main portion | |
| 52: First bonding portion | 53: Second bonding portion | |
| 59: Conductive bonding member | 61: Third bonding portion | |
| 64: First path portion | 65: Second path portion | |
| 66: Third path portion | 67: Fourth path portion | |
| 69: Conductive bonding member | 71, 72, 73: Wire | |
| 81: Resin obverse surface | 82: Resin reverse surface | |
| 91: On-board charger | 92: Storage battery | |
| 93: Drive system | 101: Element obverse surface | |
| 102: Element reverse surface | 301A: First obverse surface | |
| 301B: Second obverse surface | 302: Reverse surface | |
| 451: Holder | 452: Metal pin | |
| 481: Sub-insulating layer | 482: First sub-metal layer | |
| 482A, 482B, 482F: Region | 482E: Region (First region) | |
| 482D: Region (Second region) | 482C: Region (Third region) | |
| 483: Second sub-metal layer | 485: Connecting conductive portion | |
| 514: First opening | 602: First ramp portion | |
| 603: Second ramp portion | 611: Flat section | |
| 612: First inclined section | 641: First band-shaped section | |
| 643: First extended section | 651: Second band-shaped section | |
| 653: Second extended section | | |
| 831, 832, 833, 834: Resin side surface | | |
| 832a: Recess | 931: Inverter | |
| 932: Drive source | 4811: Opening | 4820: Base layer |
| 4821A, 4821B, 4821C, 4821D: Connecting portion | | |
| 4822A, 4822B, 4822C, 4822D: Terminal portion | | |
| 4825: Opening | 4829: Surface metal layer | 4831: Recess |
| 4839: Bonding portion | 48313: Recess | |
| x: First direction | y: Second direction | |
| z: Thickness direction | | |

<Numerals used in FIGS. 34 to 67>

| | |
|---|---|
| A1, A2, A3: Semiconductor device | |
| 3: Support substrate | 5: First conductive member |
| 6: Second conductive member | 8: Sealing resin |
| 10A: First semiconductor element | |
| 10B: Second semiconductor element | |
| 11: First obverse-surface electrode | |
| 12: Second obverse-surface electrode | |
| 13: Third obverse-surface electrode | |
| 15: Reverse-surface electrode | |
| 17: Thermistor | 19A: First conductive bonding member |
| 19B: Second conductive bonding member | 31: Insulating layer |
| 32: Surface metal layer | |
| 32A: First conductive portion (First conductive component) | |
| 32B: Second conductive portion | 33: Reverse-surface metal layer |
| 38: Third conductive component | 39: Conductive bonding member |
| 41: First terminal | 42: Second terminal |
| 43: Third terminal | 44: Fourth terminal |
| 45: Control terminal | 46A: First control terminal |
| 46B: First control terminal | 46C: First control terminal |
| 46D: First control terminal | 46E: First control terminal |
| 47A: Second control terminal | 47B: Second control terminal |
| 47C: Second control terminal | 47D: Second control terminal |
| 48: Control terminal support | 48A: First support portion |
| 48B: Second support portion | 49: Bonding member |
| 51: Main portion | 52: First bonding portion |
| 53: Second bonding portion | 59: Conductive bonding member |
| 61: Third bonding portion | 64: First path portion |
| 65: Second path portion | 66: Third path portion |
| 67: Fourth path portion | 69: Conductive bonding member |
| 71, 72, 73, 74, 75, 76: Wire (Second conductive component) | |
| 81: Resin obverse surface | 82: Resin reverse surface |
| 86: Resin cavity | 101: Element obverse surface |
| 102: Element reverse surface | 121: Gate finger |
| 301A: First obverse surface | 301B: Second obverse surface |
| 302: Reverse surface | 324: Insulator |
| 381: Core | 382: First layer |
| 383: Second layer | 384: Third layer |
| 385: Fourth layer | 386: Fifth layer |
| 387: Sixth layer | 451: Holder |
| 452: Metal pin | 459: Conductive bonding member |
| 481: Insulating layer | 482: First metal layer |
| 482A: First region | 482B: Second region |
| 482C: Third region | 482D: Fourth region |
| 482E: Fifth region | 482F: Sixth region |
| 483: Second metal layer | 514: First opening |
| 602: First ramp portion | 603: Second ramp portion |
| 611: Flat section | 612: First inclined section |
| 641: First band-shaped section | 643: First extended section |
| 649: Recess | 651: Second band-shaped section |
| 653: Second extended section | 659, 669: Recess |
| 831, 832, 833, 834: Resin side surface | 832a: Recess |
| 851: First protrusion | 851a: First protrusion end surface |
| 851b: Recess | 851c: Inner wall surface |
| 852: Second protrusion | T1, T2: Thickness |
| x: First direction | y: Second direction |
| z: Thickness direction | |

1. A semiconductor device comprising:
a main substrate including a first main metal layer;
a first semiconductor element supported by the main substrate;
a first sub-substrate supported by the main substrate; and
a sealing resin covering the first semiconductor element,
wherein the first sub-substrate includes a sub-insulating layer, and a first sub-metal layer and a second sub-metal layer that flank the sub-insulating layer in a thickness direction,
the second sub-metal layer is electrically bonded to the first main metal layer,
the first sub-metal layer includes a first region, and
the first sub-substrate further includes a connecting conductive portion that electrically connects the first region and the second sub-metal layer.

2. The semiconductor device according to claim 1, wherein the first semiconductor element is electrically bonded to the first main metal layer.

3. The semiconductor device according to claim 1, further comprising a first control terminal that is electrically connected to the first region and protrudes from the sealing resin.

4. The semiconductor device according to claim 3, wherein the first sub-metal layer further includes a second region spaced apart from the first region.

5. The semiconductor device according to claim 4, wherein the first control terminal is supported by the second region.

6. The semiconductor device according to claim 5, further comprising a first wire connected to the first region and the second region.

7. The semiconductor device according to claim 6, wherein the first sub-metal layer further includes a third region that is spaced apart from the first region and the second region and located between the first region and the second region.

8. The semiconductor device according to claim 6, wherein the first sub-metal layer includes a base layer and a surface metal layer.

9. The semiconductor device according to claim 8, wherein the base layer includes Cu.

10. The semiconductor device according to claim 9, wherein the surface metal layer contains Ni.

11. The semiconductor device according to claim 10, wherein the first sub-metal layer contains Cu.

12. The semiconductor device according to claim 11, wherein the first wire contains A1.

13. The semiconductor device according to claim 1, wherein the second sub-metal layer is electrically bonded to the first main metal layer by a conductive bonding member.

14. The semiconductor device according to claim 1, wherein the second sub-metal layer is electrically bonded to the first main metal layer by laser bonding.

15. The semiconductor device according to claim 14, wherein the second sub-metal layer has a bonding portion formed by laser bonding, and the second sub-metal layer has an opening surrounding the bonding portion as viewed in the thickness direction.

16. The semiconductor device according to claim 1, wherein the sub-insulating layer contains ceramic.

17. The semiconductor device according to claim 1, wherein the sub-insulating layer contains glass epoxy resin.

18. A vehicle comprising:
a drive source; and
the semiconductor device according to claim 1,
wherein the semiconductor device is electrically connected to the drive source.
